(19) United States
(12) Patent Application Publication
(10) Pub. No.: US 2024/0241443 A1
(43) Pub. Date: Jul. 18, 2024

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, AND METHOD FOR PRODUCING ELECTRONIC DEVICE

(71) Applicant: FUJIFILM Corporation, Tokyo (JP)

(72) Inventors: Eiji FUKUZAKI, Haibara-gun (JP); Shuhei YAMAGUCHI, Haibara-gun (JP); Tomoaki YOSHIOKA, Haibara-gun (JP); Taro MIYOSHI, Haibara-gun (JP)

(73) Assignee: FUJIFILM Corporation, Tokyo (JP)

(21) Appl. No.: 18/421,987

(22) Filed: Jan. 25, 2024

Related U.S. Application Data
(63) Continuation of application No. PCT/JP2022/028541, filed on Jul. 22, 2022.

(30) Foreign Application Priority Data
Jul. 30, 2021 (JP) 2021-126329

(51) Int. Cl. G03F 7/039; G03F 7/004

(52) U.S. Cl. CPC G03F 7/0392; G03F 7/0048

(57) ABSTRACT

The present invention provides an actinic ray-sensitive or radiation-sensitive resin composition containing a resin (P) having (A) a repeating unit having a group that is decomposed by the action of an acid to generate a carboxylic acid and represented by a specified general formula (a) and (B) a repeating unit having a group that is decomposed by irradiation with an actinic ray or a radiation to generate an acid and represented by a specified general formula (b), and a solvent including a solvent having a boiling point of 150° C. or more, a solvent having a boiling point of 150° C. or more being contained in 45 mass % or more with respect to the total amount of the solvent.

### CROSS REFERENCE TO RELATED APPLICATION

This is a continuation of International Application No. PCT/JP2022/028541 filed on Jul. 22, 2022, and claims priority from Japanese Patent Application No. 2021-126329 filed on Jul. 30, 2021, the entire disclosures of which are incorporated herein by reference.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, and a method for producing an electronic device.

### 2. Description of the Related Art

In fabrication processes for semiconductor devices such as ICs (Integrated Circuits) or LSIs (Large Scale Integrations), microprocessing by lithography using resist compositions has been performed. In recent years, with an increase in the degree of integration of integrated circuits, formation of ultrafine patterns in the submicron range or the quarter micron range has come to be in demand. With this, there is a trend for exposure wavelengths toward shorter wavelengths from the g-line to the i-line further to the KrF excimer laser beam; currently, exposure apparatuses using, as light sources, the ArF excimer laser having a wavelength of 193 nm have been developed. In addition, as a technique of further increasing the resolving power, a technique in which the space between a projection lens and a sample is filled with a liquid having a high refractive index (hereafter, also referred to as “immersion liquid”), what is called, the immersion method is being developed.

In addition, currently, lithography using, instead of excimer laser beams, an electron beam (EB), X-rays, extreme ultraviolet rays (EUV), or the like is also being developed. With this, chemical amplification resist compositions that are effectively sensitive to various actinic rays or radiations have been developed.

For example, JP2010-256856A describes an actinic ray-sensitive or radiation-sensitive resin composition containing a resin (P) containing (A) a repeating unit containing a group that is decomposed upon irradiation with an actinic ray or a radiation to generate an acid, (B) a repeating unit containing a group that is decomposed by the action of an acid to generate a carboxylic acid, and (C) a repeating unit containing a carbon-carbon unsaturated bond and a solvent having a boiling point of 150° C. or less.

In addition, JP2011-53364A describes an actinic ray-sensitive or radiation-sensitive resin composition containing a resin (P) including at least one repeating unit (A) that is decomposed upon irradiation with an actinic ray or a radiation to generate an acid and represented by any one of specified general formulas and a repeating unit (B) having at least an aromatic ring group.

### SUMMARY OF THE INVENTION

In recent years, the size of patterns has been reduced; in order to form such patterns, further improvements in various performances of actinic ray-sensitive or radiation-sensitive resin compositions have been in demand.

The related art described in JP2010-256856A and JP2011-53364A still has room for further improvements in resolution and pattern profiles.

Accordingly, an object of the present invention is to provide an actinic ray-sensitive or radiation-sensitive resin composition that has high resolution and can provide an excellent pattern profile in the formation of an ultrafine pattern (having, in particular, a line width or a space width of 20 nm or less), and an actinic ray-sensitive or radiation-sensitive film, a pattern forming method, and a method for producing an electronic device that use the composition.

The inventors of the present invention performed thorough studies and, as a result, have found that the above-described object is achieved by using an actinic ray-sensitive or radiation-sensitive resin composition including a resin containing a repeating unit having a specified structure in which a carboxyl group bonded to an aromatic ring group is protected with a group that is decomposed to leave by the action of an acid (leaving group) and a repeating unit having a specified structure having a group that generates an acid upon irradiation with an actinic ray or a radiation, and 45 mass % or more of a solvent having a boiling point of 150° C. or more relative to the total solvent amount.

Specifically, the inventors of the present invention have found that the above-described object can be achieved by employing the following features.

[1]

An actinic ray-sensitive or radiation-sensitive resin composition including a resin (P) having repeating units (A) and (B) below, and a solvent including a solvent having a boiling point of 150° C. or more,
wherein, relative to a total amount of the solvent, a content of the solvent having a boiling point of 150° C. or more is 45 mass % or more,
(A) a repeating unit having a group that is decomposed by an action of an acid to generate a carboxylic acid and represented by a general formula (a) below,
(B) a repeating unit having a group that is decomposed upon irradiation with an actinic ray or a radiation to generate an acid and represented by a general formula (b) below,

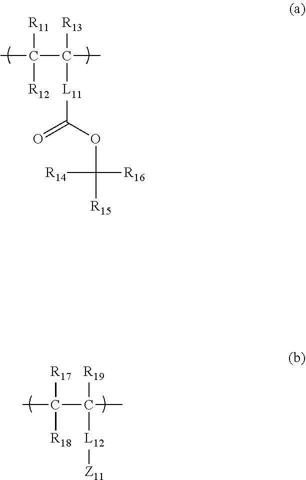

in the general formula (a),
R₁₁ to R₁₃ each independently represent a hydrogen atom, an organic group, or a halogen atom,
L₁₁ represents a divalent aromatic ring group,
R₁₄ to R₁₆ each independently represent a hydrogen atom, an alkyl group, a cycloalkyl group, an aryl group, an alkenyl group, or an alkynyl group, two among R₁₄ to R₁₆ may be linked together to form a ring,
when R₁₄ is a hydrogen atom, at least one of R₁₅ or R₁₆ represents an alkenyl group,
when R₁₄ and R₁₅ are methyl groups and two among R₁₄ to R₁₆ are not linked together,
R₁₆ represents a substituent other than a methyl group and an ethyl group,
in the general formula (b),
R₁₇ to R₁₉ each independently represent a hydrogen atom, an organic group, or a halogen atom,
L₁₂ represents a single bond, an alkylene group, an alkenylene group, an alkynylene group, a divalent aliphatic hydrocarbon ring group, a divalent aromatic ring group, or a group that is a combination of a plurality of these, and
Z₁₁ represents a moiety that is turned into a sulfonic acid group, an imidic acid group, or a methide acid group upon irradiation with an actinic ray or a radiation.
   [2]

The actinic ray-sensitive or radiation-sensitive resin composition according to [1],
wherein the repeating unit (B) is a repeating unit represented by any one of general formulas (b-1) to (b-4) below:

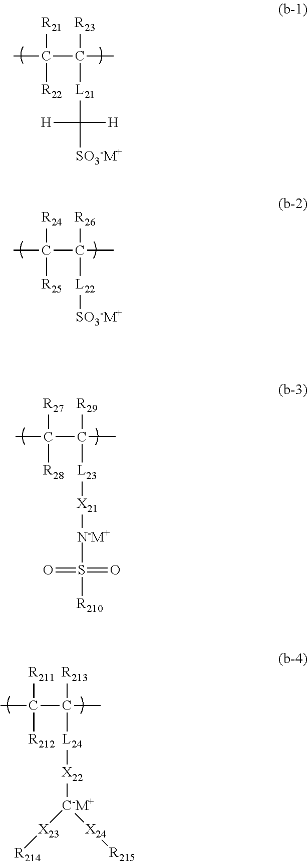

in the general formula (b-2),
R₂₄ to R₂₆ each independently represent a hydrogen atom, an alkyl group, a cycloalkyl group, an aryl group, an aralkyl group, or an alkenyl group,
L₂₂ represents a single bond, an alkylene group, an alkenylene group, an alkynylene group, a divalent aliphatic hydrocarbon ring group, a divalent aromatic ring group, or a group that is a combination of a plurality of these;
in the general formula (b-3),
R₂₇ to R₂₉ each independently represent a hydrogen atom, an alkyl group, a cycloalkyl group, an aryl group, an aralkyl group, or an alkenyl group,
L₂₃ represents a single bond, an alkylene group, an alkenylene group, an alkynylene group, a divalent aliphatic hydrocarbon ring group, a divalent aromatic ring group, or a group that is a combination of a plurality of these,
X₂₁ represents —CO— or —SO₂—,
R₂₁₀ represents a substituent;
in the general formula (b-4),
R₂₁₁ to R₂₁₃ each independently represent a hydrogen atom, an alkyl group, a cycloalkyl group, an aryl group, an aralkyl group, or an alkenyl group,
L₂₄ represents a single bond, an alkylene group, an alkenylene group, an alkynylene group, a divalent aliphatic hydrocarbon ring group, a divalent aromatic ring group, or a group that is a combination of a plurality of these,
X₂₂ to X₂₄ each independently represent —CO— or —SO₂—,
R₂₁₄ and R₂₁₅ each independently represent a substituent; and
M⁺ represents an organic onium ion.
   [3]

The actinic ray-sensitive or radiation-sensitive resin composition according to [2], wherein L₂₁ to L₂₄ in the general formulas (b-1) to (b-4) each independently represent a single bond or a divalent aromatic ring group.

[4]

The actinic ray-sensitive or radiation-sensitive resin composition according to [2] or [3], wherein the repeating unit (B) is a repeating unit represented by the general formula (b-2).

[5]

The actinic ray-sensitive or radiation-sensitive resin composition according to [4], wherein L₂₂ in the general formula (b-2) is a phenylene group.

[6]

The actinic ray-sensitive or radiation-sensitive resin composition according to any one of [1] to [5], wherein L₁₁ in the repeating unit (A) is a phenylene group.

[7]

The actinic ray-sensitive or radiation-sensitive resin composition according to any one of [1] to [6], wherein a total number of carbon atoms included in R₁₄ to R₁₆ in the repeating unit (A) is 5 to 9.

[8]

The actinic ray-sensitive or radiation-sensitive resin composition according to any one of [1] to [7], wherein R₁₄ to R₁₆ in the repeating unit (A) each independently represent an alkyl group or an alkenyl group, two among R₁₄ to R₁₆ may be linked together to form a ring, and when R₁₄ and R₁₅ are methyl groups and two among R₁₄ to R₁₆ are not linked together, R₁₆ represents a substituent other than a methyl group and an ethyl group.

[9]

The actinic ray-sensitive or radiation-sensitive resin composition according to any one of [1] to [8], wherein a content of the repeating unit (A) is 25 mol % to 55 mol % relative to all repeating units of the resin (P).

[10]

The actinic ray-sensitive or radiation-sensitive resin composition according to any one of [1] to [9], wherein the resin (P) further includes a repeating unit (C) represented by a general formula (c) below:

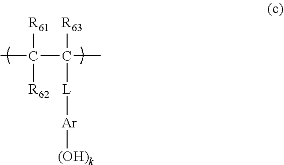

in the general formula (c),
R₆₁ to R₆₃ each independently represent a hydrogen atom, an organic group, or a halogen atom, with the proviso that R₆₂ may be bonded to Ar to form a ring, and in this case, R₆₂ represents a single bond or an alkylene group,
L represents a single bond or a divalent linking group,
Ar represents a (k+1) valent aromatic ring group, and when Ar is bonded to R₆₂ to form a ring, Ar represents a (k+2) valent aromatic ring group, and
k represents an integer of 1 to 5.
   [11]

The actinic ray-sensitive or radiation-sensitive resin composition according to any one of [1] to [10], wherein, relative to the total amount of the solvent, the content of the solvent having a boiling point of 150° C. or more is 90 mass % or more.

[12]

The actinic ray-sensitive or radiation-sensitive resin composition according to any one of [1] to [11], wherein the solvent having a boiling point of 150° C. or more contains a solvent having a hydroxyl group.

[13]

An actinic ray-sensitive or radiation-sensitive film formed from the actinic ray-sensitive or radiation-sensitive resin composition according to any one of [1] to [12].

[14]

A pattern forming method including an actinic ray-sensitive or radiation-sensitive film forming step of forming an actinic ray-sensitive or radiation-sensitive film from the actinic ray-sensitive or radiation-sensitive resin composition according to any one of [1] to [12]; an exposure step of exposing the actinic ray-sensitive or radiation-sensitive film; and a development step of developing the exposed actinic ray-sensitive or radiation-sensitive film using a developer.

[15]

A method for producing an electronic device, the method including the pattern forming method according to [14].

The present invention can provide an actinic ray-sensitive or radiation-sensitive resin composition that has high resolution and can provide an excellent pattern profile in the formation of an ultrafine pattern (having, in particular, a line width or a space width of 20 nm or less), and an actinic ray-sensitive or radiation-sensitive film, a pattern forming method, and a method for producing an electronic device that use the composition.

### DESCRIPTION OF THE PREFERRED EMBODIMENTS

Hereinafter, the present invention will be described in detail.

In the following descriptions, features may be described on the basis of representative embodiments of the present invention; however, the present invention is not limited to such embodiments.

In this Specification, “actinic ray” or “radiation” means, for example, a line spectrum of a mercury lamp, far ultraviolet rays represented by excimer lasers, extreme ultraviolet rays (EUV: Extreme Ultraviolet), X-rays, soft X-rays, an electron beam (EB: Electron Beam), or the like. In this Specification, “light” means an actinic ray or a radiation. In this Specification, “exposure” includes not only exposure using a line spectrum of a mercury lamp, far ultraviolet rays represented by excimer lasers, extreme ultraviolet rays, X-rays, EUV, or the like, but also drawing using a corpuscular beam such as an electron beam or an ion beam, unless otherwise specified.

In this Specification, “a value ‘to’ another value” is used to mean that it includes the value and the other value as the lower limit value and the upper limit value.

In this Specification, (meth)acrylate represents at least one of acrylate or methacrylate. (Meth)acrylic acid represents at least one of acrylic acid or methacrylic acid.

In this Specification, for resins, the weight-average molecular weight (Mw), the number-average molecular weight (Mn), and the dispersity (also referred to as molecular weight distribution) (Mw/Mn) are defined as polystyrene-equivalent values measured, using a GPC (Gel Permeation Chromatography) apparatus (HLC-8120GPC, manufactured by Tosoh Corporation), by GPC measurement (solvent: tetrahydrofuran, flow rate (sample injection amount): 10 μL, column: TSK gel Multipore HXL-M manufactured by Tosoh Corporation, column temperature: 40° C., flow rate: 1.0 mL/min, detector: differential refractive index detector (Refractive Index Detector)).

In this Specification, for the wording of groups (atomic groups), wording without referring to substituted or unsubstituted encompasses groups not having a substituent and groups having a substituent. For example, “alkyl groups” encompasses not only alkyl groups not having a substituent (unsubstituted alkyl groups), but also alkyl groups having a substituent (substituted alkyl groups). In this Specification, “organic group” refers to a group including at least one carbon atom.

In this Specification, the bonding directions of divalent groups described are not limited unless otherwise specified. For example, in a compound represented by a formula “X—Y-Z” where Y is —COO⁻, Y may be —CO—O— or —O—CO—. In other words, the compound may be “X—CO—O—Z” or “X—O—CO—Z”.

In this Specification, the acid dissociation constant (pKa) represents pKa in an aqueous solution, specifically, a value determined using the following Software package 1, on the basis of the Hammett's substituent constant and the database of values in publicly known documents, by calculation. All the values of pKa described in this Specification are values determined by calculation using this software package.
Software package 1: Advanced Chemistry Development (ACD/Labs) Software V8.14 for Solaris (1994-2007 ACD/Labs)

Alternatively, pKa can be determined by a molecular orbital calculation method. Specifically, this method may be a calculation method of calculating H+dissociation free energy in an aqueous solution based on a thermodynamic cycle. The H+dissociation free energy can be calculated by a method such as DFT (density functional theory); however, the calculation method is not limited thereto and various other methods have been reported in documents and the like. Note that there are a plurality of pieces of software for performing DFT, such as Gaussian 16.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density functional theory) using Gaussian 16 is employed.

In this Specification, pKa refers to “pKa in an aqueous solution” as described above, but when pKa in an aqueous solution cannot be determined, “pKa in a dimethyl sulfoxide (DMSO) solution” is employed.

### Actinic Ray-Sensitive or Radiation-Sensitive Resin Composition

An actinic ray-sensitive or radiation-sensitive resin composition according to the present invention (hereinafter, also referred to as “composition of the present invention”) contains:
a resin (P) having repeating units (A) and (B) below and a solvent including a solvent having a boiling point of 150° C. or more,
wherein, relative to a total amount of the solvent, a content of the solvent having a boiling point of 150° C. or more is 45 mass % or more,
(A) a repeating unit having a group that is decomposed by the action of an acid to generate a carboxylic acid and represented by a general formula (a) below,
(B) a repeating unit having a group that is decomposed upon irradiation with an actinic ray or a radiation to generate an acid and represented by a general formula (b) below,

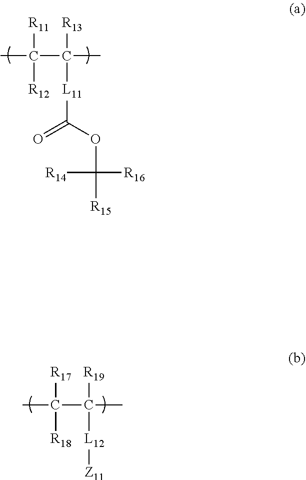

in the general formula (a),
R₁₁ to R₁₃ each independently represent a hydrogen atom, an organic group, or a halogen atom,
L₁₁ represents a divalent aromatic ring group,
R₁₄ to R₁₆ each independently represent a hydrogen atom, an alkyl group, a cycloalkyl group, an aryl group, an alkenyl group, or an alkynyl group, two among R₁₄ to R₁₆ may be linked together to form a ring,
when R₁₄ is a hydrogen atom, at least one of R₁₅ or R₁₆ represents an alkenyl group,
when R₁₄ and R₁₅ are methyl groups, and two among R₁₄ to R₁₆ are not linked together, R₁₆ represents a substituent other than a methyl group and an ethyl group,
in the general formula (b),
R₁₇ to R₁₉ each independently represent a hydrogen atom, an organic group, or a halogen atom,
L₁₂ represents a single bond, an alkylene group, an alkenylene group, an alkynylene group, a divalent aliphatic hydrocarbon ring group, a divalent aromatic ring group, or a group that is a combination of a plurality of these, and
Z₁₁ represents a moiety that is turned into a sulfonic acid group, an imidic acid group, or a methide acid group upon irradiation with an actinic ray or a radiation.

The present invention has such features and hence can provide, in the formation of an ultrafine pattern (having, in particular, a line width or a space width of 20 nm or less), high resolution and an excellent pattern profile.

The reason for this has not been clarified, but is inferred as follows.

The resin (P) of the present invention has (B) a repeating unit having a group that is decomposed upon irradiation with an actinic ray or a radiation to generate an acid and represented by the general formula (b). The repeating unit (B) has a group that is decomposed upon irradiation with an actinic ray or a radiation to generate an acid, and the acid generated by decomposition upon irradiation with an actinic ray or a radiation generally reacts with the acid decomposable group of the resin. The resin (P) has such an acid in the repeating unit (B), and the acid is bonded to the main chain of the repeating unit (B). Thus, diffusion of the acid generated in the exposed regions to the unexposed regions is suppressed, which inferentially results in improved resolution.

In the resin (P) in the present invention, the group represented by —COO(R₁₄)(R₁₅)(R₁₆) in the acid decomposable group is bonded to the main chain of the resin via a divalent aromatic ring group serving as L₁₁ and being a rigid group, and hence, compared with a case where the group is bonded to the main chain of the resin not via such a linking group or via a linking group having a flexible structure, diffusion of the acid generated in the exposed regions to the unexposed regions is suppressed, which is expected to result in improved resolution.

Because of the feature “when R₁₄ and R₁₅ are methyl groups and two among R₁₄ to R₁₆ are not linked together, R₁₆ represents a substituent other than a methyl group and an ethyl group”, the compound that leaves from —COO(R₁₄)(R₁₅)(R₁₆) by the action of an acid and is derived from R₁₄, R₁₅, and R₁₆ is a compound having a relatively large size. Such a feature results in stabilization of the reaction intermediate generated by the leaving reaction, and hence the decomposition reaction in —COO(R₁₄)(R₁₅)(R₁₆) by an acid easily proceeds.

Therefore, in the composition of the present invention, the decomposition reaction of the resin by an acid tends to occur with certainty in the exposed regions and the generated acid is less likely to diffuse to the unexposed regions, which inferentially results in great contribution to improvements in resolution and pattern profile.

In addition, the inventors of the present invention performed thorough studies and, as a result, have found that the probability of evaporation of a solvent in the formation of an actinic ray-sensitive or radiation-sensitive film from a composition considerably relates to the performance of the resultant film.

On the basis of such findings, the composition of the present invention is defined such that it contains a solvent and, relative to the total amount of the solvent, the content of a solvent having a boiling point of 150° C. or more is set to 45 mass % or more. Thus, the content of the solvent having a boiling point of 150° C. or more relative to the total amount of the solvent is set to such a predetermined amount, so that the evaporation of the solvent tends to proceed slowly in the process of forming the film, and fine bubbles are less likely to be formed in the film inferentially.

The evaporation of the solvent in the film formation tends to proceed slowly, which inferentially results in suppression of the tendency in which, for example, evaporation of the solvent in the surface portion of the film excessively precedes evaporation of the solvent in the deep portion of the film, and the solvent content in the film becomes non-uniform in the film forming process. That is, in the film forming process, the solvent content in the film tends to be more uniform and, as a result, a film in which the components of the composition are extremely uniformly present is likely to be formed inferentially.

Therefore, use of the composition of the present invention easily provides formation of an actinic ray-sensitive or radiation-sensitive film in which the components of the composition are extremely uniformly present, so that, in the formation of an ultrafine pattern (having, in particular, a line width or a space width of 20 nm or less), the desired reaction in exposed regions can be caused to proceed with higher accuracy, and high resolution and an excellent pattern profile are achieved inferentially.

The actinic ray-sensitive or radiation-sensitive resin composition of the present invention (also referred to as the composition of the present invention) is preferably a resist composition, and may be a positive resist composition or a negative resist composition. The resist composition may be a resist composition for alkaline development or a resist composition for organic solvent development. In particular, the resist composition is preferably a positive resist composition and a resist composition for alkaline development.

Further, the composition of the present invention is preferably a chemical amplification resist composition, and more preferably a chemical amplification positive resist composition. (P) resin having repeating units (A) and (B)

The resin having the repeating units (A) and (B) (also referred to as “resin (P)”) will be described.
(A) a repeating unit having a group that is decomposed by the action of an acid to generate a carboxylic acid and represented by a general formula (a)
(B) a repeating unit having a group that is decomposed upon irradiation with an actinic ray or a radiation to generate an acid and represented by a general formula (b)

The resin (P) preferably has a repeating unit having a group that is decomposed by the action of an acid to generate an acid to provide increased polarity (hereinafter, also referred to as “acid decomposable group”), and is preferably a resin having a repeating unit having an acid decomposable group (hereinafter, also referred to as “acid decomposable resin”).

The resin (P) is a resin containing a repeating unit (a) having a group that is decomposed by the action of an acid to generate a carboxylic acid to provide increased polarity and represented by the general formula (a) and is an acid decomposable resin.

The resin (P) is preferably a resin whose solubility in a developer is changed by the action of an acid.

The resin whose solubility in a developer is changed by the action of an acid may be a resin whose solubility in a developer is increased by the action of an acid or may be a resin whose solubility in a developer is decreased by the action of an acid.

The resin (P) has a group that is decomposed by the action of an acid to generate a carboxylic acid, so that, in a pattern forming method of the present invention, typically, when the developer is an alkali developer, a positive-type pattern is suitably formed, or when the developer is an organic-based developer, a negative-type pattern is suitably formed.

Repeating unit (A)

The repeating unit (A) is a repeating unit having a group that is decomposed by the action of an acid to generate a carboxylic acid and represented by a general formula (a) below.

The repeating unit (A) is also referred to as “repeating unit having an acid decomposable group”.

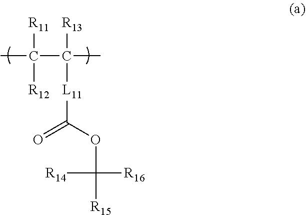

In the general formula (a),
R₁₁ to R₁₃ each independently represent a hydrogen atom, an organic group, or a halogen atom,
L₁₁ represents a divalent aromatic ring group,
R₁₄ to R₁₆ each independently represent a hydrogen atom, an alkyl group, a cycloalkyl group, an aryl group, an alkenyl group, or an alkynyl group; two among R₁₄ to R₁₆ may be linked together to form a ring; when R₁₄ is a hydrogen atom, at least one of R₁₅ or R₁₆ represents an alkenyl group; when R₁₄ and R₁₅ are methyl groups, and two among R₁₄ to R₁₆ are not linked together, R₁₆ represents a substituent other than a methyl group and an ethyl group.

In the general formula (a), R₁₁ to R₁₃ each independently represent a hydrogen atom, an organic group, or a halogen atom.

Examples of the organic group represented by R₁₁ to R₁₃ include an alkyl group and a cycloalkyl group.

The alkyl group may be linear or branched. The number of carbon atoms of the alkyl group is not particularly limited, but is preferably 1 to 10, more preferably 1 to 3. The cycloalkyl group may be monocyclic or polycyclic. The number of carbon atoms of the cycloalkyl group is not particularly limited, but is preferably 3 to 8.

Examples of the halogen atoms represented by R₁₁ to R₁₃ include a fluorine atom, a chlorine atom, a bromine atom, and an iodine atom.

In the general formula (a), R₁₁ to R₁₃ are each independently preferably a hydrogen atom or an alkyl group, more preferably R₁ and R₁₂ are hydrogen atoms, and R₁₃ is a hydrogen atom or a methyl group, and still more preferably R₁₁ to R₁₃ are hydrogen atoms.

In the general formula (a), Lu represents a divalent aromatic ring group. Examples of the divalent aromatic ring group represented by Lu include an arylene group and a heteroarylene group.

The arylene group serving as L₁₁ may be monocyclic or polycyclic, and examples thereof include an arylene group having 6 to 15 carbon atoms, and specific preferred examples thereof include a phenylene group, a naphthylene group, and an anthrylene group. The heteroarylene group serving as L₁₁ may be monocyclic or polycyclic, and examples thereof include a heteroarylene group having 2 to 15 carbon atoms and having a 5- to 10-membered ring; specific examples thereof include a group provided by removing any one of hydrogen atoms from a furyl group, a thienyl group, a thiazolyl group, a pyrrolyl group, an oxazolyl group, a pyridyl group, a benzofuranyl group, a benzothienyl group, a quinolinyl group, a carbazolyl group, or the like.

The divalent aromatic ring group represented by Lu may further have a substituent, and examples thereof include halogen atoms.

L₁₁ is preferably an arylene group, and more preferably a phenylene group.

R₁₄ to R₁₆ each independently represent a hydrogen atom, an alkyl group, a cycloalkyl group, an aryl group, an alkenyl group, or an alkynyl group. R₁₄ to R₁₆ may be linked together to form a ring. When R₁₄ is a hydrogen atom, at least one of R₁₅ or R₁₆ represents an alkenyl group. When R₁₄ and R₁₅ are methyl groups, and two among R₁₄ to R₁₆ are not linked together, R₁₆ represents a substituent other than a methyl group and an ethyl group.

Examples of the alkyl groups represented by R₁₄ to R₁₆ include an alkyl group that may be linear or branched and has 1 to 8 carbon atoms, and preferred are alkyl groups having 1 to 4 carbon atoms such as a methyl group, an ethyl group, an n-propyl group, an isopropyl group, an n-butyl group, an isobutyl group, and a t-butyl group.

Examples of the cycloalkyl groups represented by R₁₄ to R₁₆ include a monocyclic or polycyclic cycloalkyl group having 3 to 10 carbon atoms, preferred is a monocyclic cycloalkyl group having 4 to 8 carbon atoms, and preferred is a cyclopentyl group or a cyclohexyl group.

Examples of the aryl groups represented by R₁₄ to R₁₆ include an aryl group having 6 to 15 carbon atoms such as a phenyl group and a naphthyl group.

Examples of the alkenyl groups represented by R₁₄ to R₁₆ include an alkenyl group having 2 to 4 carbon atoms, and preferred are alkenyl groups having 2 to 4 carbon atoms such as a vinyl group, a 1-methylvinyl group, a 1-propenyl group, an allyl group, and a 2-methyl-1-propenyl group.

Examples of the alkynyl groups represented by R₁₄ to R₁₆ include an alkynyl group having 2 to 4 carbon atoms.

When R₁₄ to R₁₆ are linked together to form a ring, two among R₁₄ to R₁₆ are preferably bonded together to form a cycloalkyl group or a cycloalkenyl group.

Examples of the cycloalkyl group formed by bonding together two among R₁₄ to R₁₆ include a monocyclic or polycyclic cycloalkyl group having 3 to 10 carbon atoms; preferred are monocyclic cycloalkyl groups such as a cyclopentyl group and a cyclohexyl group and, in addition, preferred are polycyclic cycloalkyl groups such as a norbornyl group, a tetracyclodecanyl group, a tetracyclododecanyl group, and an adamantyl group. Of these, preferred is a monocyclic cycloalkyl group having 5 to 6 carbon atoms.

Examples of the cycloalkenyl group formed by bonding together two among R₁₄ to R₁₆ include monocyclic or polycyclic cycloalkenyl groups having 4 to 8 carbon atoms, and, of these, preferred is a monocyclic cycloalkenyl group having 5 to 6 carbon atoms.

The substituents represented by R₁₄ to R₁₆ may be further substituted with an organic group. The number of heteroatoms included in the organic group is preferably 0 to 1. In a case where each group of the substituents represented by R₁₄ to R₁₆ is substituted with an organic group, examples of the organic group include an alkyl group (having 1 to 4 carbon atoms) and an alkoxy group (having 1 to 4 carbon atoms). One of methylene groups in the substituents represented by R₁₄ to R₁₆ may be replaced by a group having a heteroatom such as a carbonyl group.

In the cycloalkyl group and cycloalkenyl group formed by bonding together two among R₁₄ to R₁₆, for example, one of the methylene groups constituting the ring may be replaced by a heteroatom such as an oxygen atom or a sulfur atom, or a group having a heteroatom such as a carbonyl group.

The total number of heteroatoms included in R₁₄ to R₁₆ is more preferably 0 to 1.

When R₁₄ and R₁₅ are methyl groups, and two among R₁₄ to R₁₆ are not linked together,
R₁₆ represents a substituent other than a methyl group and an ethyl group. When R₁₄ and R₁₅ are methyl groups, two among R₁₄ to R₁₆ are not linked together, and R₁₆ represents a methyl group or an ethyl group, the reactivity of the deprotection reaction of the acid decomposable group in the resin (P) by the acid generated by the repeating unit (B) described later may not be sufficiently provided.

The total number of carbon atoms included in R₁₄ to R₁₆ is more preferably 5 or more from the viewpoint of ensuring reactivity with the acid generated by the repeating unit (B). The total number of carbon atoms included in R₁₄ to R₁₆ is not particularly limited, but is preferably 9 or less, and more preferably 7 or less. When the total number of carbon atoms is set to 9 or less, the leaving product having left from the resin (P) by the acid generated by the repeating unit (B) described later is less likely to remain in the actinic ray-sensitive or radiation-sensitive film, which results in further improvement in the resolving power. The total number of carbon atoms included in R₁₄ to R₁₆ is preferably 5 to 9, and more preferably 5 to 7.

In the repeating unit (A), R₁₄ to R₁₆ preferably each independently represent an alkyl group or an alkenyl group. Two among R₁₄ to R₁₆ may be linked together to form a ring. When R₁₄ and R₁₅ are methyl groups, and two among R₁₄ to R₁₆ are not linked together, R₁₆ represents a substituent other than a methyl group and an ethyl group.

For R₁₄ to R₁₆, for example, in a preferred embodiment, R₁₄ is an alkyl group or an alkenyl group, R₁₅ and R₁₆ are bonded together to form a cyclopentyl group or a cyclohexyl group; in a more preferred embodiment, R₁₄ is an alkyl group or an alkenyl group having 1 to 3 carbon atoms, and R₁₅ and R₁₆ are bonded together to form a cyclopentyl group.

In another preferred embodiment of R₁₄ to R₁₆, R₁₄ and R₁₅ are preferably alkyl groups having 1 to 4 carbon atoms and R₁₆ is preferably an alkenyl group having 2 to 3 carbon atoms.

The repeating unit represented by the general formula (a) is preferably a repeating unit represented by the following general formula (a-1).

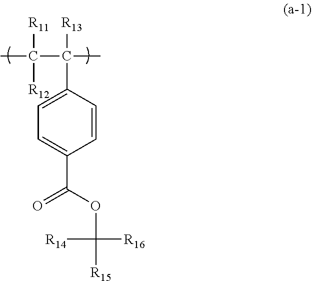

In the general formula (a-1), R₁₁ to R₁₃ each independently represent a hydrogen atom, an organic group, or a halogen atom. R₁₄ to R₁₆ each independently represent a hydrogen atom, an alkyl group, a cycloalkyl group, an aryl group, an alkenyl group, or an alkynyl group. Two among R₁₄ to R₁₆ may be linked together to form a ring. When R₁₄ is a hydrogen atom, at least one of R₁₅ or R₁₆ represents an alkenyl group. When R₁₄ and R₁₅ are methyl groups, and two among R₁₄ to R₁₆ are not linked together, R₁₆ represents a substituent other than a methyl group and an ethyl group.

R₁₁ to R₁₃ in the general formula (a-1) have the same meanings and preferred examples as R₁1 to R₁₃ in the above-described general formula (a).

R₁₄ to R₁₆ in the general formula (a-1) have the same meanings and preferred examples as R₁₄ to R₁₆ in the above-described general formula (a).

Specific examples of the repeating unit (A) will be described below; however, the present invention is not limited thereto.

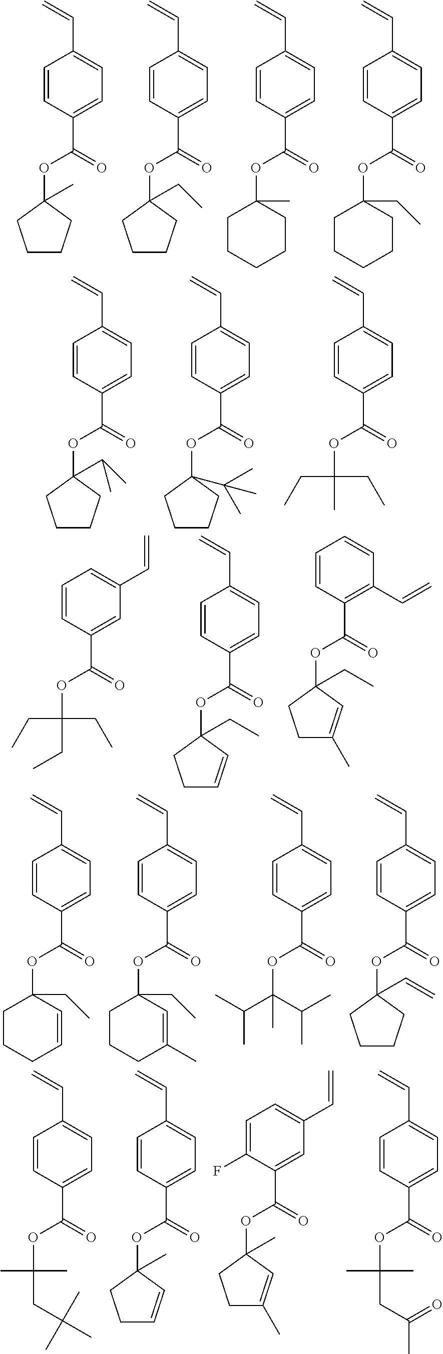

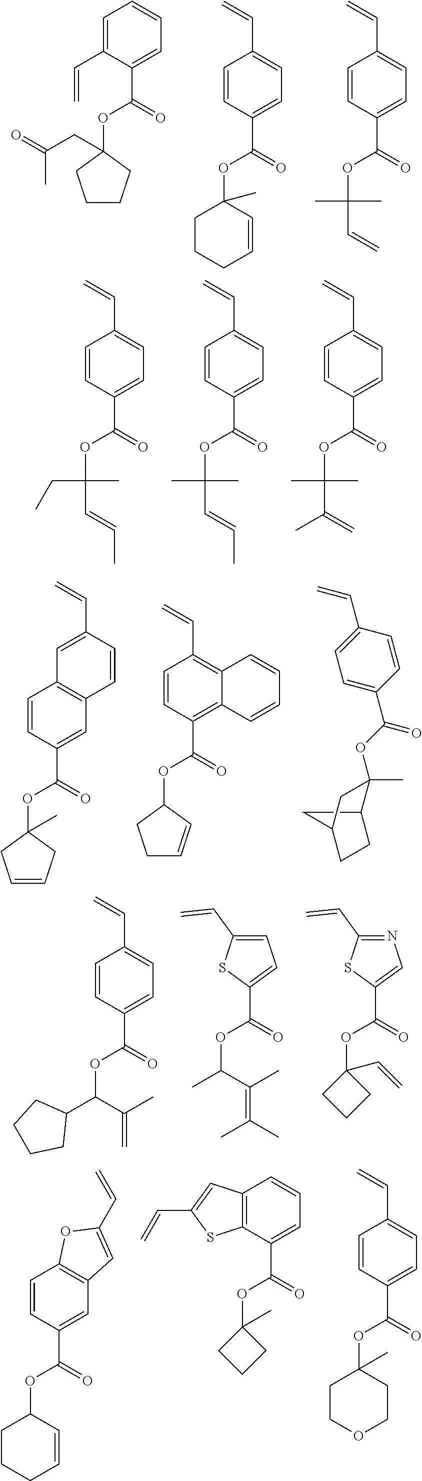

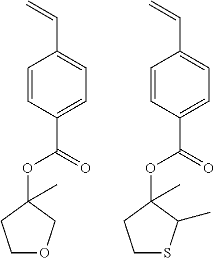

The resin (P) may include a single repeating unit (A) species alone, or may include two or more repeating unit (A) species in combination.

The content of the repeating unit (A) included in the resin (P) (in the case where a plurality of repeating units (A) are present, the total content thereof) is, relative to all the repeating units of the resin (P), preferably 15 mol % to 70 mol %, more preferably 25 mol % to 55 mol %, still more preferably 25 mol % to 40 mol %.

### Repeating Unit (B)

The repeating unit (B) is a repeating unit having a group that is decomposed upon irradiation with an actinic ray or a radiation to generate an acid and represented by the following general formula (b).

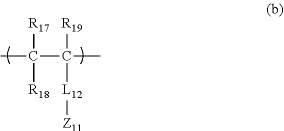

In the general formula (b),
R₁₇ to R₁₉ each independently represent a hydrogen atom, an organic group, or a halogen atom,
L₁₂ represents a single bond, an alkylene group, an alkenylene group, an alkynylene group, a divalent aliphatic hydrocarbon ring group, a divalent aromatic ring group, or a group that is a combination of a plurality of these, and
Z₁₁ represents a moiety that is turned into a sulfonic acid group, an imidic acid group, or a methide acid group upon irradiation with an actinic ray or a radiation.

Examples of the organic groups represented by R₁₇ to R₁₉ include alkyl groups, cycloalkyl groups, aryl groups, aralkyl groups, alkenyl groups, a cyano group, and alkoxycarbonyl groups.

Such an alkyl group may be linear or branched. The number of carbon atoms of the alkyl group is not particularly limited, but is preferably 1 to 10, and more preferably 1 to 3.

Such a cycloalkyl group may be monocyclic or polycyclic. The number of carbon atoms of the cycloalkyl group is not particularly limited, but is preferably 3 to 8.

Such an aryl group is preferably a monocyclic or polycyclic aryl group having 6 to 14 carbon atoms, and specific examples thereof include a phenyl group and a naphthyl group.

Such an aralkyl group is preferably an aralkyl group having 7 to 10 carbon atoms, and specific examples thereof include a benzyl group and a phenethyl group.

Examples of such an alkenyl group include an alkenyl group having 2 to 5 carbon atoms, and preferred are alkenyl groups having 2 to 4 carbon atoms such as a vinyl group, a 1-methylvinyl group, a 1-propenyl group, an allyl group, and a 2-methyl-1-propenyl group.

Such an alkynyl group is, for example, an alkynyl group having 2 to 4 carbon atoms.

The alkyl group in such an alkoxycarbonyl group may be linear or branched. The number of carbon atoms of the alkyl group is not particularly limited, but is preferably 1 to 10, and more preferably 1 to 3.

Examples of the halogen atoms represented by R₁₇ to R₁₉ include a fluorine atom, a chlorine atom, a bromine atom, and an iodine atom.

In the general formula (b), R₁₇ to R₁₉ are each independently preferably a hydrogen atom or an alkyl group, more preferably R₁₇ and R₁₈ are hydrogen atoms and R₁₉ is a hydrogen atom or a methyl group, and still more preferably R₁₇ to R₁₉ are hydrogen atoms.

Examples of the alkylene group represented by L₁₂ include an alkylene group that may be linear or branched and 1 to 8 carbon atoms, preferably an alkylene group having 1 to 6 carbon atoms, and more preferably an alkylene group having 1 to 4 carbon atoms.

Examples of the alkenylene group represented by L₁₂ include an alkenylene group having 2 to 8 carbon atoms, preferably an alkenylene group having 2 to 6 carbon atoms, and more preferably an alkenylene group having 2 to 4 carbon atoms.

Examples of the alkynylene group represented by L₁₂ include an alkynylene group having 2 to 8 carbon atoms, preferably an alkynylene group having 2 to 6 carbon atoms, and more preferably an alkynylene group having 2 to 4 carbon atoms.

Examples of the divalent aliphatic hydrocarbon ring group represented by L₁₂ include a cycloalkylene group and a cycloalkenylene group.

The cycloalkylene group may be monocyclic or polycyclic, and examples thereof include a cycloalkylene group having 3 to 10 carbon atoms, and preferred is a cycloalkylene group having 3 to 6 carbon atoms.

The cycloalkenylene group may be monocyclic or polycyclic, and examples thereof include a cycloalkenylene group having 3 to 10 carbon atoms, and preferred is a cycloalkenylene group having 3 to 6 carbon atoms.

Examples of the divalent aromatic ring group represented by L₁₂ include an arylene group and a heteroarylene group.

Examples of the arylene group serving as L₁₂ include an arylene group having 6 to 15 carbon atoms, and specific preferred examples thereof include a phenylene group, a naphthylene group, and an anthrylene group.

Examples of the heteroarylene group serving as L₁₂ include a heteroarylene group having 2 to 15 carbon atoms and having a 5- to 10-membered ring; specific examples thereof include a group provided by removing any one of hydrogen atoms from a furyl group, a thienyl group, a thiazolyl group, a pyrrolyl group, an oxazolyl group, a pyridyl group, a benzofuranyl group, a benzothienyl group, a quinolinyl group, a carbazolyl group, or the like.

The alkylene group, alkenylene group, divalent aliphatic hydrocarbon ring group, and divalent aromatic ring group represented by L₁₂ may further have a substituent, and examples thereof include an alkyl group and a halogen atom.

In the general formula (b), L₁₂ is preferably a single bond, an alkylene group, a divalent aromatic ring group, or a group that is a combination of a plurality of these, and more preferably a single bond or a divalent aromatic ring group.

The sulfonic acid group represented by Z₁₁ and provided upon irradiation with an actinic ray or a radiation is not particularly limited, but is preferably a group represented by a formula (B1) below.

The imidic acid group represented by Z₁ and provided upon irradiation with an actinic ray or a radiation is not particularly limited, but is preferably a group represented by a formula (B2) below.

The methide acid group represented by Z₁₁ and provided upon irradiation with an actinic ray or a radiation is not particularly limited, but is preferably a group represented by a formula (B3) below.

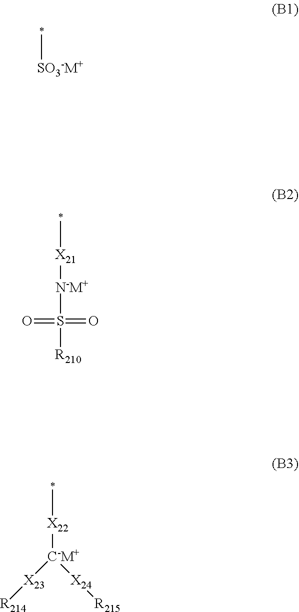

In the formula (B1) to the formula (B3),
X₂₁ represents —CO— or —SO₂—,
R₂₁₀ represents a substituent,
X₂₂ to X₂₄ each independently represent —CO— or —SO₂—,
R₂₁₄ and R₂₁₅ each independently represent a substituent, M⁺ represents an organic onium ion, and
represents a bonding site.

The group represented by the formula (B1) corresponds to a corresponding group in a repeating unit represented by a general formula (b-1) or a general formula (b-2) described later.

The group represented by the formula (B2) corresponds to a corresponding group in a repeating unit represented by a general formula (b-3) described later.

The group represented by the formula (B3) corresponds to a corresponding group in a repeating unit represented by a general formula (b-4) described later.

The groups in the groups represented by the formulas (B1) to (B3) will be individually described later.

The repeating unit (B) is preferably a repeating unit represented by any one of the following general formulas (b-1) to (b-4).

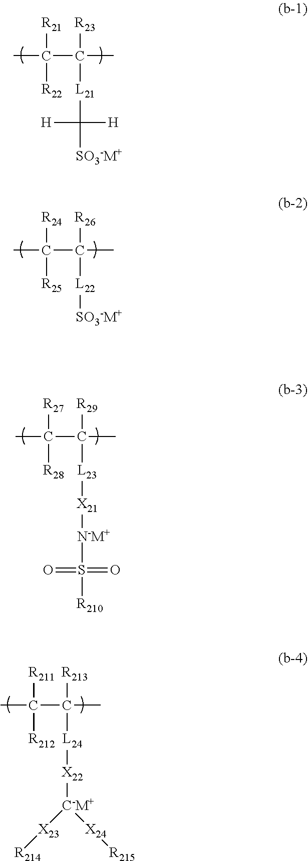

In the general formula (b-1),
R₂₁ to R₂₃ each independently represent a hydrogen atom, an alkyl group, a cycloalkyl group, a halogen atom, a cyano group, or an alkoxycarbonyl group,
L₂₁ represents a single bond, an alkylene group, an alkenylene group, an alkynylene group, a divalent aliphatic hydrocarbon ring group, a divalent aromatic ring group, or a group that is a combination of a plurality of these;
in the general formula (b-2),
R₂₄ to R₂₆ each independently represent a hydrogen atom, an alkyl group, a cycloalkyl group, an aryl group, an aralkyl group, or an alkenyl group,
L₂₂ represents a single bond, an alkylene group, an alkenylene group, an alkynylene group, a divalent aliphatic hydrocarbon ring group, a divalent aromatic ring group, or a group that is a combination of a plurality of these;
in the general formula (b-3),
R₂₇ to R₂₉ each independently represent a hydrogen atom, an alkyl group, a cycloalkyl group, an aryl group, an aralkyl group, or an alkenyl group,
L₂₃ represents a single bond, an alkylene group, an alkenylene group, an alkynylene group, a divalent aliphatic hydrocarbon ring group, a divalent aromatic ring group, or a group that is a combination of a plurality of these,
X₂₁ represents —CO— or —SO₂—,
R₂₁₀ represents a substituent;
in the general formula (b-4),
R₂₁₁ to R₂₁₃ each independently represent a hydrogen atom, an alkyl group, a cycloalkyl group, an aryl group, an aralkyl group, or an alkenyl group,
L₂₄ represents a single bond, an alkylene group, an alkenylene group, an alkynylene group, a divalent aliphatic hydrocarbon ring group, a divalent aromatic ring group, or a group that is a combination of a plurality of these,
X₂₂ to X₂₄ each independently represent —CO— or —SO₂—,
R₂₁₄ and R₂₁₅ each independently represent a substituent; and M⁺ represents an organic onium ion.

Examples of the alkyl groups represented by R₂₁ to R₂₃ include an alkyl group that may be linear or branched and has 1 to 8 carbon atoms, and preferred are alkyl groups having 1 to 4 carbon atoms such as a methyl group, an ethyl group, an n-propyl group, an isopropyl group, an n-butyl group, an isobutyl group, and a t-butyl group.

Examples of the cycloalkyl groups represented by R₂₁ to R₂₃ include a monocyclic or polycyclic cycloalkyl group having 3 to 10 carbon atoms; preferred are monocyclic cycloalkyl groups having 4 to 6 carbon atoms and preferred are a cyclopentyl group and a cyclohexyl group.

Examples of the halogen atoms represented by R₂₁ to R₂₃ include a fluorine atom, a chlorine atom, a bromine atom, and an iodine atom.

In the alkoxycarbonyl groups represented by R₂₁ to R₂₃, the alkyl groups may be linear or branched. The number of carbon atoms of such an alkyl group is not particularly limited, but is preferably 1 to 10, more preferably 1 to 3.

R₂₁ to R₂₃ preferably each independently represent a hydrogen atom or an alkyl group.

Examples of the alkylene group represented by L₂₁ include an alkylene group that may be linear or branched and has 1 to 8 carbon atoms; preferred is an alkylene group having 1 to 6 carbon atoms, and more preferred is an alkylene group having 1 to 4 carbon atoms. Examples of the alkenylene group represented by L₂₁ include an alkenylene group having 2 to 8 carbon atoms; preferred is an alkenylene group having 2 to 6 carbon atoms, and more preferred is an alkenylene group having 2 to 4 carbon atoms.

Examples of the alkynylene group represented by L₂₁ include an alkynylene group having 2 to 8 carbon atoms; preferred is an alkynylene group having 2 to 6 carbon atoms, and more preferred is an alkynylene group having 2 to 4 carbon atoms.

Examples of the divalent aliphatic hydrocarbon ring group represented by L₂₁ include a cycloalkylene group and a cycloalkenylene group.

The cycloalkylene group may be monocyclic or polycyclic, and examples thereof include a cycloalkylene group having 3 to 10 carbon atoms, and preferred is a cycloalkylene group having 3 to 6 carbon atoms.

The cycloalkenylene group may be monocyclic or polycyclic, and examples thereof include a cycloalkenylene group having 3 to 10 carbon atoms, and preferred is a cycloalkenylene group having 3 to 6 carbon atoms.

Examples of the divalent aromatic ring group represented by L₂₁ include an arylene group and a heteroarylene group.

Examples of the arylene group serving as L₂₁ include an arylene group having 6 to 15 carbon atoms, and specific preferred examples thereof include a phenylene group, a naphthylene group, and an anthrylene group.

Examples of the heteroarylene group serving as L₂₁ include a heteroarylene group having 2 to 15 carbon atoms and having a 5- to 10-membered ring; specific examples thereof include a group provided by removing any one of hydrogen atoms from a furyl group, a thienyl group, a thiazolyl group, a pyrrolyl group, an oxazolyl group, a pyridyl group, a benzofuranyl group, a benzothienyl group, a quinolinyl group, a carbazolyl group, or the like.

The alkylene group, alkenylene group, alkynylene group, divalent aliphatic hydrocarbon ring group, or divalent aromatic ring group represented by L₂₁ may further have a substituent, and examples thereof include an alkyl group and a halogen atom.

In the general formula (b-1), L₂₁ is preferably a single bond, an alkylene group, a divalent aromatic ring group, or a group that is a combination of a plurality of these, and more preferably a single bond or a divalent aromatic ring group.

Examples of the alkyl groups represented by R₂₄ to R₂₆ include the same as those described for the alkyl groups represented by R₂₁ to R₂₃ and preferred ranges thereof are also the same.

Examples of the cycloalkyl groups represented by R₂₄ to R₂₆ include the same as those described for the cycloalkyl groups represented by R₂₁ to R₂₃ and preferred ranges thereof are also the same.

The aryl groups represented by R₂₄ to R₂₆ are preferably monocyclic or polycyclic aryl groups having 6 to 14 carbon atoms, and specific examples thereof include a phenyl group and a naphthyl group.

The aralkyl groups represented by R₂₄ to R₂₆ are preferably aralkyl groups having 7 to 10 carbon atoms, and specific examples thereof include a benzyl group and a phenethyl group.

Examples of the alkenyl groups represented by R₂₄ to R₂₆ include an alkenyl group having 2 to 5 carbon atoms, and preferred are alkenyl groups having 2 to 4 carbon atoms such as a vinyl group, a 1-methylvinyl group, a 1-propenyl group, an allyl group, and a 2-methyl-1-propenyl group.

R₂₄ to R₂₆ are each independently preferably a hydrogen atom or an alkyl group.

Examples of the alkylene group, alkenylene group, alkynylene group, divalent aliphatic hydrocarbon ring group, and divalent aromatic ring group represented by L₂₂ are respectively the same as those described for the alkylene group, alkenylene group, alkynylene group, divalent aliphatic hydrocarbon ring group, and divalent aromatic ring group represented by L₂₁, and preferred ranges thereof are also the same.

The alkylene group, alkenylene group, alkynylene group, divalent aliphatic hydrocarbon ring group, and divalent aromatic ring group represented by L₂₂ may further have a substituent, and examples thereof include an alkyl group and a halogen atom.

In the general formula (b-2), L₂₂ is preferably a single bond, an alkylene group, a divalent aromatic ring group, or a group that is a combination of a plurality of these, and more preferably a single bond or a divalent aromatic ring group.

Examples of the alkyl groups represented by R₂₇ to R₂₉ include the same as those described for the alkyl groups represented by R₂₁ to R₂₃ and preferred ranges thereof are also the same.

Examples of the cycloalkyl groups represented by R₂₇ to R₂₉ include the same as those described for the cycloalkyl groups represented by R₂₁ to R₂₃ and preferred ranges thereof are also the same.

Examples of the aryl groups represented by R₂₇ to R₂₉ include the same as those described for the aryl groups represented by R₂₄ to R₂₆ and preferred ranges thereof are also the same.

Examples of the aralkyl groups represented by R₂₇ to R₂₉ include the same as those described for the aralkyl groups represented by R₂₄ to R₂₆ and preferred ranges thereof are also the same.

Examples of the alkenyl groups represented by R₂₇ to R₂₉ include the same as those described for the alkenyl groups represented by R₂₄ to R₂₆ and preferred ranges thereof are also the same.

R₂₇ to R₂₉ preferably each independently represent a hydrogen atom or an alkyl group.

Examples of the alkylene group, alkenylene group, alkynylene group, divalent aliphatic hydrocarbon ring group, and divalent aromatic ring group represented by L₂₃ are respectively the same as those described for the alkylene group, alkenylene group, alkynylene group, divalent aliphatic hydrocarbon ring group, and divalent aromatic ring group represented by L₂₁, and preferred ranges thereof are also the same.

The alkylene group, alkenylene group, alkynylene group, divalent aliphatic hydrocarbon ring group, and divalent aromatic ring group represented by L₂₃ may further have a substituent, and examples thereof include an alkyl group and a halogen atom.

In the general formula (b-3), L₂₃ is preferably a single bond, an alkylene group, a divalent aromatic ring group, or a group that is a combination of a plurality of these, and more preferably a single bond or a divalent aromatic ring group.

The substituent represented by R₂₁₀ is not particularly limited, and examples thereof include an alkyl group, an aryl group, and a heteroaryl group.

Examples of the alkyl group include an alkyl group that may be linear or branched and has 1 to 8 carbon atoms, and preferred are an alkyl group having 1 to 4 carbon atoms such as a methyl group, an ethyl group, an n-propyl group, an isopropyl group, an n-butyl group, an isobutyl group, and a t-butyl group.

The aryl group is preferably a monocyclic or polycyclic aryl group having 6 to 14 carbon atoms, and specific examples thereof include a phenyl group and a naphthyl group.

The heteroaryl group may be monocyclic or polycyclic, and examples thereof include a heteroaryl group having 2 to 15 carbon atoms and having a 5- to 10-membered ring; specific examples thereof include a furyl group, a thienyl group, a thiazolyl group, a pyrrolyl group, an oxazolyl group, a pyridyl group, a benzofuranyl group, a benzothienyl group, a quinolinyl group, and a carbazolyl group.

The alkyl group, the aryl group, and the heteroaryl group may have a substituent. The substituent is not particularly limited, and examples thereof include alkyl groups and halogen atoms, and preferred is a fluorine atom.

Examples of the alkyl groups represented by R₂₁₁ to R₂₁₃ include the same as those described for the alkyl groups represented by R₂₁ to R₂₃ and preferred ranges thereof are also the same.

Examples of the cycloalkyl groups represented by R₂₁₁ to R₂₁₃ include the same as those described for the cycloalkyl groups represented by R₂₁ to R₂₃ and preferred ranges thereof are also the same.

Examples of the aryl groups represented by R₂₁₁ to R₂₁₃ include the same as those described for the aryl groups represented by R₂₄ to R₂₆ and preferred ranges thereof are also the same.

Examples of the aralkyl groups represented by R₂₁₁ to R₂₁₃ include the same as those described for the aralkyl groups represented by R₂₄ to R₂₆ and preferred ranges thereof are also the same.

Examples of the alkenyl groups represented by R₂₁₁ to R₂₁₃ include the same as those described for the alkenyl groups represented by R₂₄ to R₂₆ and preferred ranges thereof are also the same.

R₂₁₁ to R₂₁₃ preferably each independently represent a hydrogen atom or an alkyl group.

Examples of the alkylene group, alkenylene group, alkynylene group, divalent aliphatic hydrocarbon ring group, and divalent aromatic ring group represented by L₂₄ are respectively the same as those described for the alkylene group, alkenylene group, alkynylene group, divalent aliphatic hydrocarbon ring group, and divalent aromatic ring group represented by L₂₁, and preferred ranges thereof are also the same.

The alkylene group, alkenylene group, alkynylene group, divalent aliphatic hydrocarbon ring group, and divalent aromatic ring group represented by L₂₄ may further have a substituent, and examples thereof include an alkyl group and a halogen atom.

In the general formula (b-4), L₂₄ is preferably a single bond, an alkylene group, a divalent aromatic ring group, or a group that is a combination of a plurality of these, and more preferably a single bond or a divalent aromatic ring group.

X₂₃ and X₂₄ preferably represent —SO₂-.

The substituents represented by R₂₁₄ and R₂₁₅ are not particularly limited, and examples thereof include an alkyl group, an aryl group, and a heteroaryl group.

Examples of the alkyl group include an alkyl group that may be linear or branched and has 1 to 8 carbon atoms, and preferred are alkyl groups having 1 to 4 carbon atoms such as a methyl group, an ethyl group, an n-propyl group, an isopropyl group, an n-butyl group, an isobutyl group, and a t-butyl group.

The aryl group is preferably a monocyclic or polycyclic aryl group having 6 to 14 carbon atoms, and specific examples thereof include a phenyl group and a naphthyl group.

The heteroaryl group may be monocyclic or polycyclic, and examples thereof include a heteroaryl group having 2 to 15 carbon atoms and having a 5- to 10-membered ring; and specific examples thereof include a furyl group, a thienyl group, a thiazolyl group, a pyrrolyl group, an oxazolyl group, a pyridyl group, a benzofuranyl group, a benzothienyl group, a quinolinyl group, and a carbazolyl group.

The alkyl group, the aryl group, and the heteroaryl group may have a substituent. The substituent is not particularly limited; examples thereof include alkyl groups and halogen atoms, and preferred is a fluorine atom.

The organic onium ion represented by M⁺is not particularly limited, but preferred are organic onium cations, and preferred is a cation represented by the following general formula (ZIA) or general formula (ZIIA).

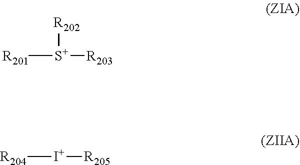

In the general formula (ZIA),
R₂₀₁, R₂₀₂, and R₂₀₃ each independently represent an organic group.

For the organic groups serving as R₂₀₁, R₂₀₂, and R₂₀₃, the number of carbon atoms is generally 1 to 30, and preferably 1 to 20.

Two among R₂₀₁ to R₂₀₃ may be bonded together to form a ring structure, and the ring may include an oxygen atom, a sulfur atom, an ester bond, an amide bond,-N(R 301)-, or a carbonyl group. R₃₀₁ represents a hydrogen atom, an alkylsulfonyl group, or a haloalkylsulfonyl group. Examples of the group formed by bonding together two among R₂₀₁ to R₂₀₃ include an alkylene group (such as a butylene group or a pentylene group), —CH₂—CH₂—O—CH₂—CH₂—, and —CH₂—CH₂—N(R₃₀₁)-CH₂—CH₂-.

Preferred examples of the cation represented by the general formula (ZIA) include a cation (ZI-11), a cation (ZI-12), a cation (cation (ZI-13)) represented by a general formula (ZI-13), and a cation (cation (ZI-14)) represented by a general formula (ZI-14), which will be described later.

First, the cation (ZI-11) will be described.

The cation (ZI-11) is a cation in which at least one of R₂₀₁ to R₂₀₃ in the general formula (ZIA) is an aryl group, that is, an arylsulfonium cation.

In the arylsulfonium cation, all of R₂₀₁ to R₂₀₃ may be aryl groups, or one or more of R₂₀₁ to R₂₀₃ may be aryl groups and the other may be an alkyl group or a cycloalkyl group.

Examples of the arylsulfonium cation include triarylsulfonium cations, diarylalkylsulfonium cations, aryldialkylsulfonium cations, diarylcycloalkylsulfonium cations, and aryldicycloalkylsulfonium cations.

The aryl group included in the arylsulfonium cation is preferably a phenyl group or a naphthyl group, and more preferably a phenyl group. The aryl group may be an aryl group having a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. When the arylsulfonium cation has two or more aryl groups, the two or more aryl groups may be the same or different.

The alkyl group or cycloalkyl group that the arylsulfonium cation optionally has is preferably a linear alkyl group having 1 to 15 carbon atoms, a branched alkyl group having 3 to 15 carbon atoms, or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, and a cyclohexyl group.

The aryl groups, the alkyl groups, and the cycloalkyl groups serving as R₂₀₁ to R₂₀₃ may each independently have, as a substituent, an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, a lactone ring group, a sultone ring group, or a phenylthio group.

Examples of the lactone ring group include a group provided by removing a hydrogen atom from the structure represented by any one of general formulas (LC1-1) to (LC1-21) described later.

Examples of the sultone ring group include a group provided by removing a hydrogen atom from the structure represented by any one of general formulas (SL1-1) to (SL1-3) described later.

Hereinafter, the cation (ZI-12) will be described.

The cation (ZI-12) is a compound in which R₂₀₁ to R₂₀₃ in the formula (ZIA) each independently represent an organic group not having an aromatic ring. This aromatic ring encompasses aromatic rings including a heteroatom.

The organic groups not having an aromatic ring and serving as R₂₀₁ to R₂₀₃ generally have 1 to 30 carbon atoms, and preferably have 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably a linear or branched 2-oxoalkyl group.

Preferred examples of the alkyl groups and the cycloalkyl groups serving as R₂₀₁ to R₂₀₃ include linear alkyl groups having 1 to 10 carbon atoms, branched alkyl groups having 3 to 10 carbon atoms (for example, a methyl group, an ethyl group, a propyl group, a butyl group, and a pentyl group), and cycloalkyl groups having 3 to 10 carbon atoms (for example, a cyclopentyl group, a cyclohexyl group, and a norbornyl group).

R₂₀₁ to R₂₀₃ may be further substituted with a halogen atom, an alkoxy group (having, for example, 1 to 5 carbon atoms), a hydroxyl group, a cyano group, or a nitro group.

Hereinafter, the cation (ZI-13) will be described.

The cation (ZI-13) is represented by the following general formula (ZI-13).

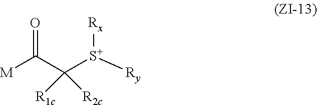

In the general formula (ZI-13), M represents an alkyl group, a cycloalkyl group, or an aryl group, and in the case of having a ring structure, the ring structure may include at least one of an oxygen atom, a sulfur atom, an ester bond, an amide bond, or a carbon-carbon double bond. R_{1c} and R_{2c} each independently represent a hydrogen atom, an alkyl group, a cycloalkyl group, a halogen atom, a cyano group, or an aryl group. R_{1c} and R_{2c} may be bonded together to form a ring. Rₓ and R_{y} each independently represent an alkyl group, a cycloalkyl group, or an alkenyl group. Rₓ and R_{y} may be bonded together to form a ring. At least two selected from the group consisting of M, R_{1c}, and R₂, may be bonded together to form a ring structure, and the ring structure may include a carbon-carbon double bond.

In the general formula (ZI-13), the alkyl group and the cycloalkyl group represented by M are preferably a linear alkyl group having 1 to 15 carbon atoms (preferably 1 to 10 carbon atoms), a branched alkyl group having 3 to 15 carbon atoms (preferably 3 to 10 carbon atoms), or a cycloalkyl group having 3 to 15 carbon atoms (preferably 1 to 10 carbon atoms), and specific examples thereof include a methyl group, an ethyl group, a propyl group, an n-butyl group, a sec-butyl group, a t-butyl group, a cyclopropyl group, a cyclobutyl group, a cyclohexyl group, and a norbornyl group.

The aryl group represented by M is preferably a phenyl group or a naphthyl group, and more preferably a phenyl group. The aryl group may be an aryl group having a heterocyclic structure having an oxygen atom, a sulfur atom, or the like. Examples of the heterocyclic structure include a furan ring, a thiophene ring, a benzofuran ring, and a benzothiophene ring.

M above may further have a substituent. In this case, examples of M include a benzyl group.

Note that, when M has a cyclic structure, the cyclic structure may include at least one of an oxygen atom, a sulfur atom, an ester bond, an amide bond, or a carbon-carbon double bond.

Examples of the alkyl groups, the cycloalkyl groups, and the aryl groups represented by R_{1c} and R_{2c} are the same as those of M described above, and preferred examples thereof are also the same. R_{1c} and R_{2c} may be bonded together to form a ring.

Examples of the halogen atoms represented by R_{1c} and R_{2c} include a fluorine atom, a chlorine atom, a bromine atom, and an iodine atom.

Examples of the alkyl groups and the cycloalkyl groups represented by Rₓ and R_{y} are the same as those of M described above, and preferred examples thereof are also the same.

The alkenyl groups represented by Rₓ and R_{y} are preferably an allyl group or a vinyl group.

Rₓ and R_{y} above may further have a substituent. In this case, examples of Rₓ and R_{y} include 2-oxoalkyl groups and alkoxycarbonylalkyl groups.

Examples of the 2-oxoalkyl groups represented by Rₓ and R_{y} include those having 1 to 15 carbon atoms (preferably 1 to 10 carbon atoms), and specific examples thereof include a 2-oxopropyl group and a 2-oxobutyl group.

Examples of the alkoxycarbonylalkyl groups represented by Rₓ and R_{y} include those having 1 to 15 carbon atoms (preferably 1 to 10 carbon atoms). Rₓ and R_{y} may be bonded together to form a ring.

The ring structure formed by linking together Rₓ and R_{y} may include an oxygen atom, a sulfur atom, an ester bond, an amide bond, or a carbon-carbon double bond.

In the general formula (ZI-13), M and R_{1c} may be bonded together to form a ring structure, and the formed ring structure may include a carbon-carbon double bond.

In particular, the cation (ZI-13) is preferably a cation (ZI-13A).

The cation (ZI-13A) is a phenacylsulfonium cation represented by the following general formula (ZI-13A).

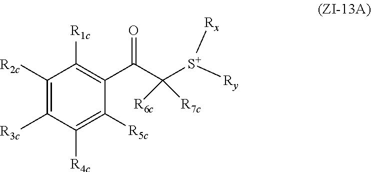

In the general formula (ZI-13A), R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} have the same meanings as the above-described R_{1c} and R_{2c} in the general formula (ZI-13), and preferred examples thereof are also the same.

Rₓ and R_{y} have the same meanings as the above-described Rₓ and R_{y} in the general formula (ZI-13), and preferred examples thereof are also the same.

Any two or more among R_{1c} to R_{5c} and Rₓ and R_{y} may be bonded together to form ring structures, and the ring structures may each independently include an oxygen atom, a sulfur atom, an ester bond, an amide bond, or a carbon-carbon double bond. R_{5c} and R_{6c}, and R_{5c} and Rₓ may be bonded together to form ring structures, and the ring structures may each independently include a carbon-carbon double bond. R_{6c} and R_{7c} may be bonded together to form a ring structure.

Examples of the ring structures include aromatic or non-aromatic hydrocarbon rings, aromatic or non-aromatic heterocycles, and polycyclic fused rings that are combinations of two or more of these rings. Examples of the ring structures include 3- to 10-membered rings, preferred are 4- to 8-membered rings, and more preferred are 5- or 6-membered rings.

Examples of the groups formed by bonding together any two or more among R_{1c} to R_{5c}, R_{6c} and R_{7c}, and Rₓ and R_{y} include a butylene group and a pentylene group.

The groups formed by bonding together R₅ and R_{6c}, and R_{5c} and Rₓ are preferably single bonds or alkylene groups. Examples of the alkylene groups include a methylene group and an ethylene group.

Hereinafter, the cation (ZI-14) will be described.

The cation (ZI-14) is represented by the following general formula (ZI-14).

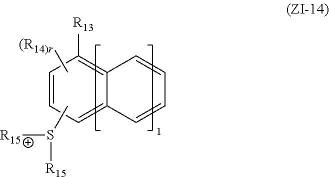

In the general formula (ZI-14),
1 represents an integer of 0 to 2; and
r represents an integer of 0 to 8.
R₁₃ represents a hydrogen atom, a fluorine atom, a hydroxyl group, an alkyl group, a cycloalkyl group, an alkoxy group, an alkoxycarbonyl group, or a group having a monocyclic or polycyclic cycloalkyl skeleton. These groups may have a substituent.

When a plurality of R₁₄'s are present, R₁₄'s each independently represent an alkyl group, a cycloalkyl group, an alkoxy group, an alkylsulfonyl group, a cycloalkylsulfonyl group, an alkylcarbonyl group, an alkoxycarbonyl group, or an alkoxy group having a monocyclic or polycyclic cycloalkyl skeleton. These groups may have a substituent.

R₁₅'s each independently represent an alkyl group, a cycloalkyl group, or a naphthyl group. These groups may have a substituent. Two R₁₅'s may be bonded together to form a ring. When two R₁₅'s are bonded together to form a ring, the ring skeleton may include a heteroatom such as an oxygen atom or a nitrogen atom. In an example, two R₁₅'s are preferably alkylene groups and bonded together to form a ring structure.

In the general formula (ZI-14), the alkyl groups of R₃, R₁₄, and R₁₅ are linear or branched. Such an alkyl group preferably has 1 to 10 carbon atoms. The alkyl group is more preferably a methyl group, an ethyl group, an n-butyl group, a t-butyl group, or the like.

Hereinafter, the general formula (ZIIA) will be described.

In the general formula (ZIIA), R₂₀₄ and R₂₀₅ each independently represent an aryl group, an alkyl group, or a cycloalkyl group.

For R²⁰⁴ and R²⁰⁵, the aryl group is preferably a phenyl group or a naphthyl group, more preferably a phenyl group. For R₂₀₄ and R₂₀₅, the aryl group may be an aryl group having a heterocyclic structure having an oxygen atom, a nitrogen atom, a sulfur atom, or the like. Examples of the skeleton of the aryl group having a heterocyclic structure include pyrrole, furan, thiophene, indole, benzofuran, and benzothiophene.

For R₂₀₄ and R₂₀₅, the alkyl group and the cycloalkyl group are preferably a linear alkyl group having 1 to 10 carbon atoms or a branched alkyl group having 3 to 10 carbon atoms (for example, a methyl group, an ethyl group, a propyl group, a butyl group, and a pentyl group), or a cycloalkyl group having 3 to 10 carbon atoms (for example, a cyclopentyl group, a cyclohexyl group, and a norbornyl group).

For R₂₀₄ and R₂₀₅, the aryl group, the alkyl group, and the cycloalkyl group may each independently have a substituent. Examples of substituents that the aryl groups, the alkyl groups, and the cycloalkyl groups of R₂₀₄ to R₂₀₇ may have include alkyl groups (for example, having 1 to 15 carbon atoms), cycloalkyl groups (for example, having 3 to 15 carbon atoms), aryl groups (for example, having 6 to 15 carbon atoms), alkoxy groups (for example, having 1 to 15 carbon atoms), halogen atoms, a hydroxyl group, lactone ring groups, sultone ring groups, and a phenylthio group.

Examples of the lactone ring groups include a group provided by removing a hydrogen atom from the structure represented by any one of general formulas (LC1-1) to (LC1-21) described later.

Examples of the sultone ring groups include a group provided by removing a hydrogen atom from the structure represented by any one of general formulas (SL1-1) to (SL1-3) described later.

Preferred examples of the organic onium cation represented by M⁺in the general formulas (b-1) to (b-4) will be described below; however, the present invention is not limited thereto. Me represents a methyl group, and Bu represents an n-butyl group.

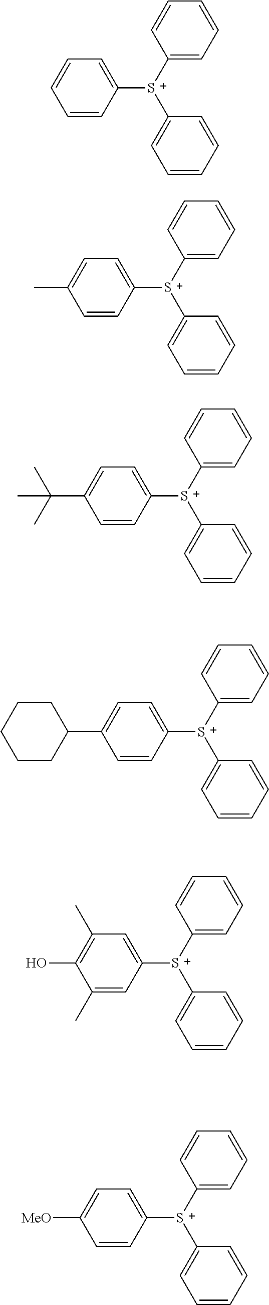

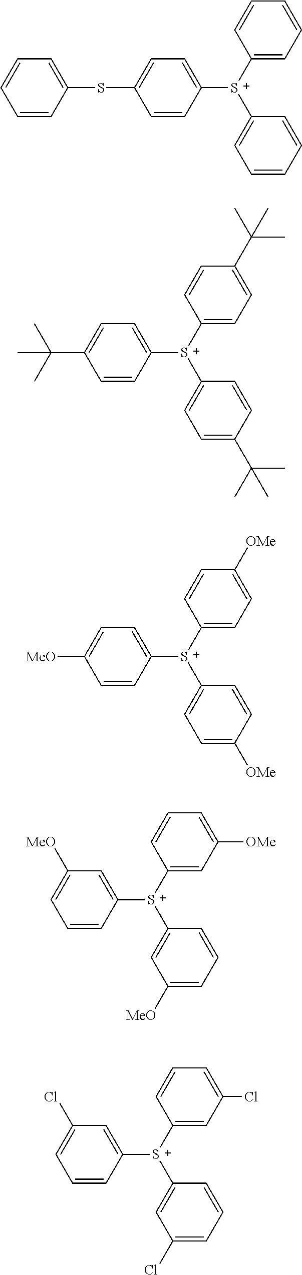

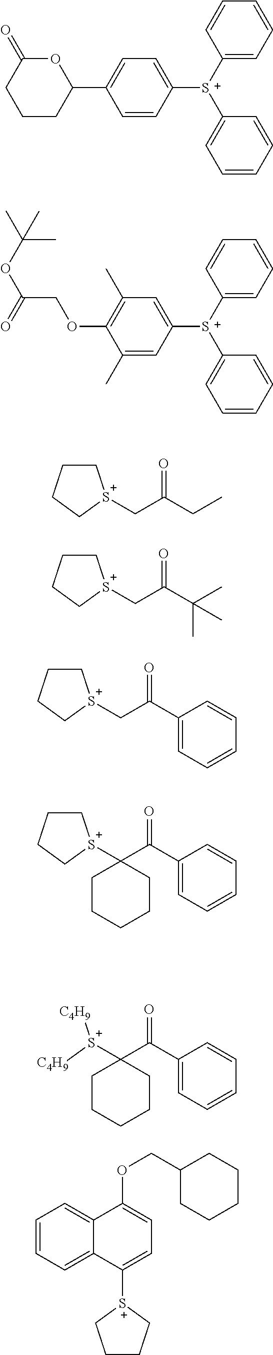

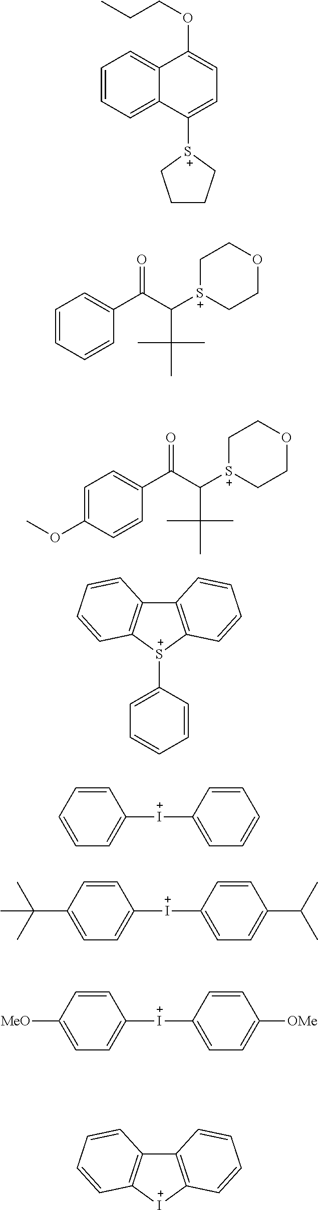

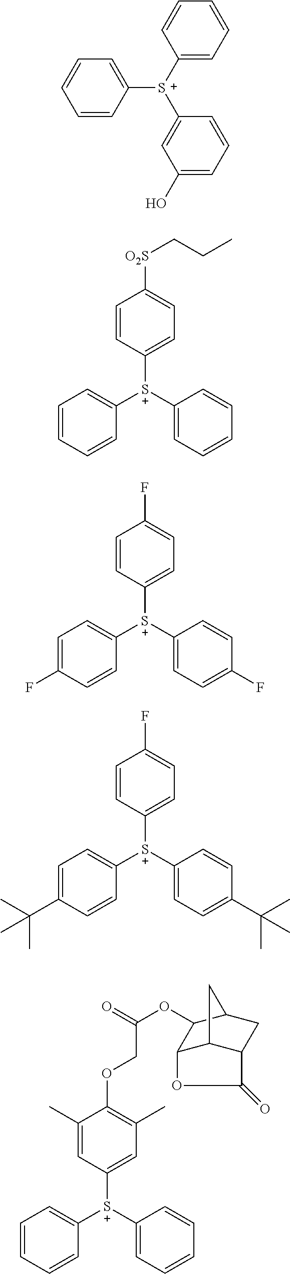

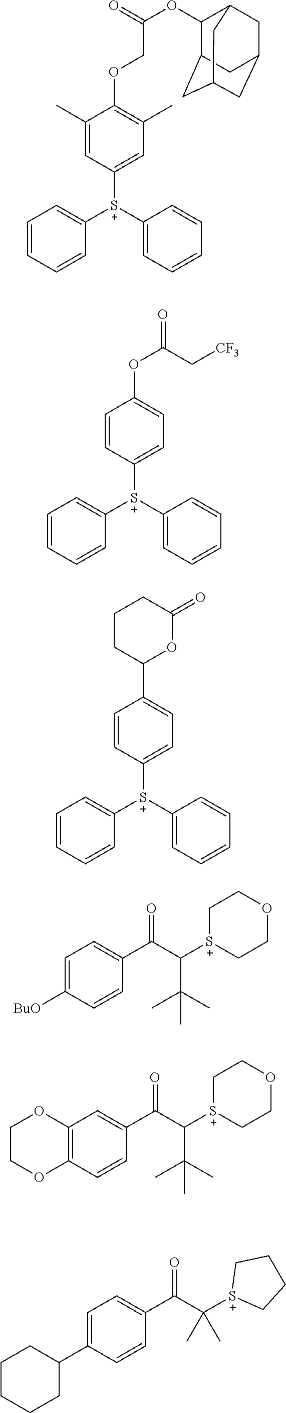

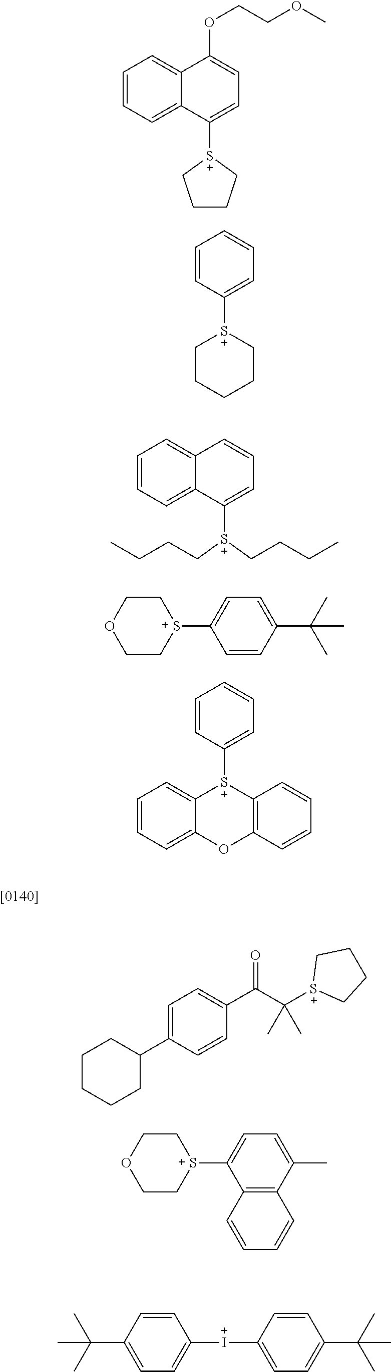

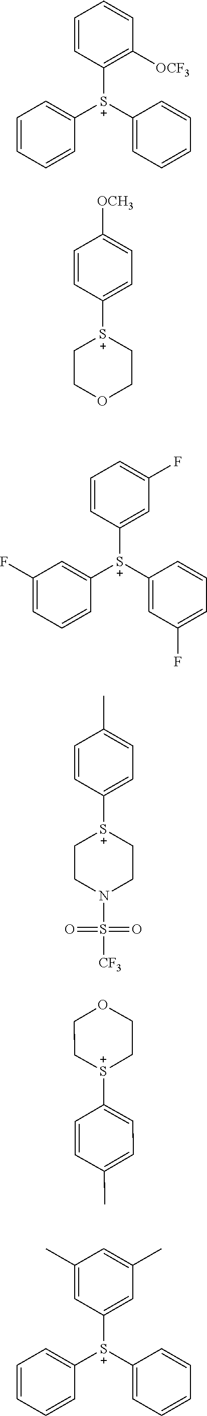

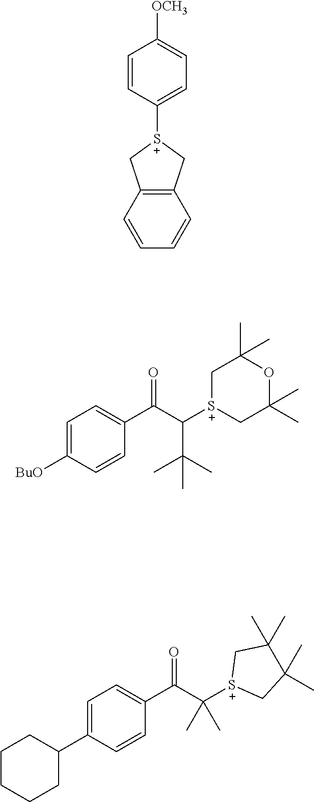

L₂₁ to L₂₄ in the general formulas (b-1) to (b-4) each independently preferably represent a single bond, a divalent aliphatic hydrocarbon ring group, or a divalent aromatic ring group, and more preferably represent a single bond or a divalent aromatic ring group. When L₂₁ to L₂₄ each independently represent a single bond or a divalent aromatic ring group, the distance from the main chain in each general formula becomes short to provide a rigid structure. This suppresses diffusibility of, to unexposed regions, the acid generated upon irradiation with an actinic ray or a radiation, to further improve the resolution, which is preferred.

The repeating unit (B) is preferably a repeating unit represented by any one of the general formulas (b-2) to (b-4), more preferably a repeating unit represented by the general formula (b-2) or (b-3), and still more preferably a repeating unit represented by the general formula (b-2).

L₂₂ in the general formula (b-2) is preferably a phenylene group.

Specific examples of the repeating unit (B) will be described below, but the present invention is not limited thereto. Bu represents an n-butyl group.

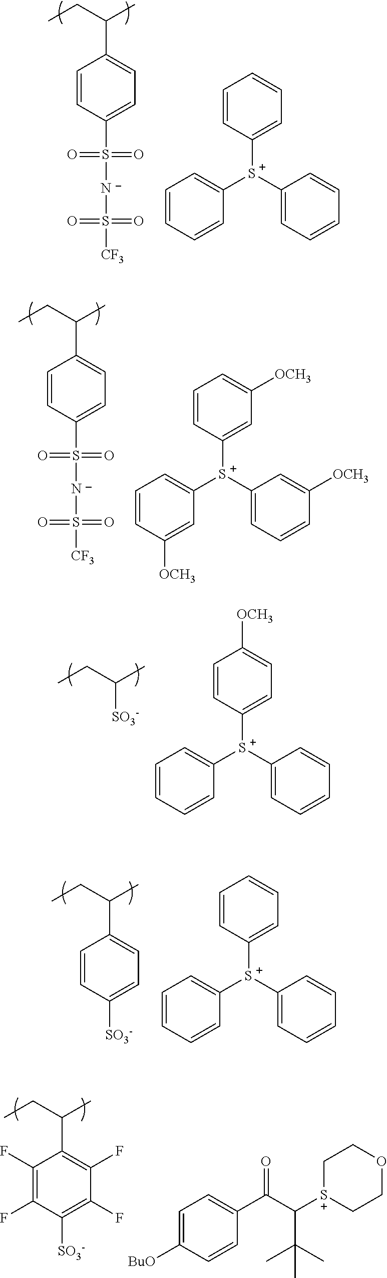

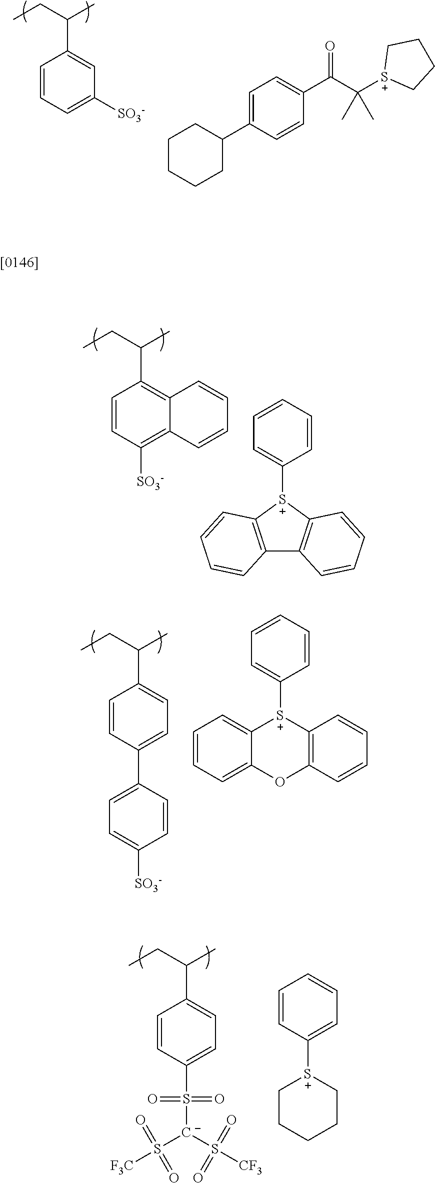

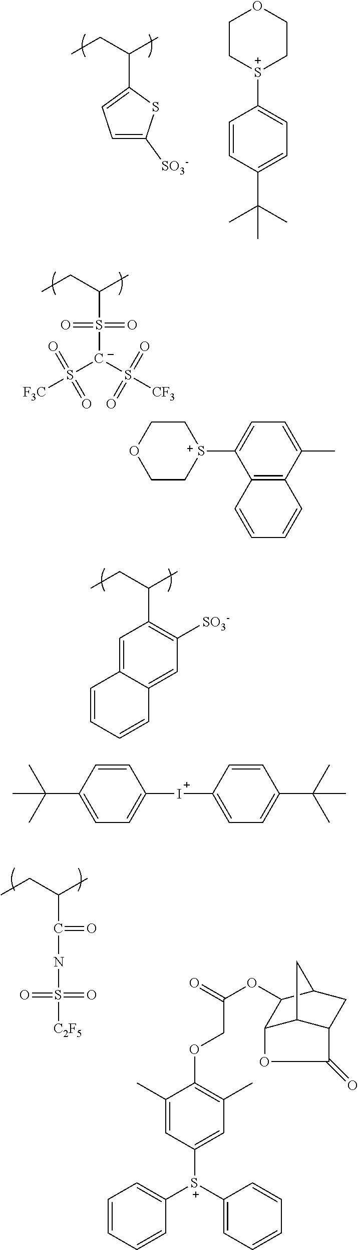

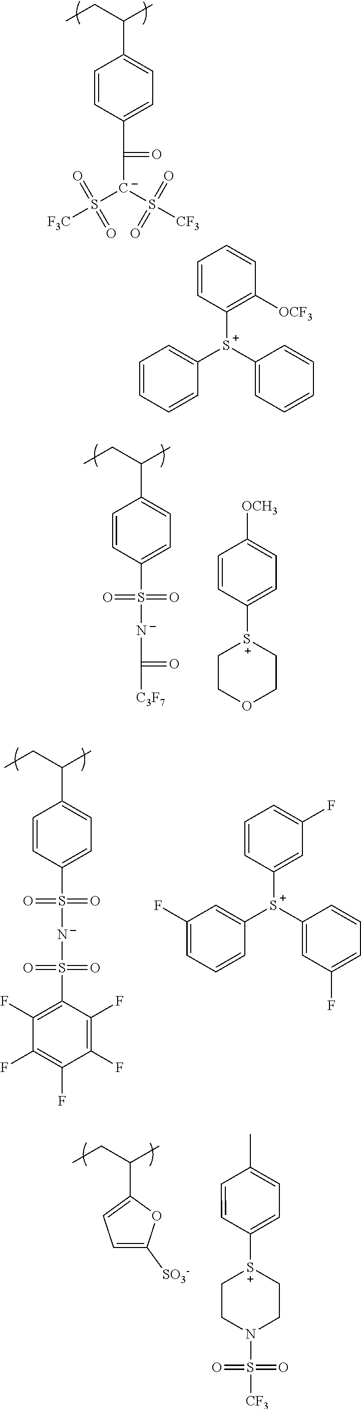

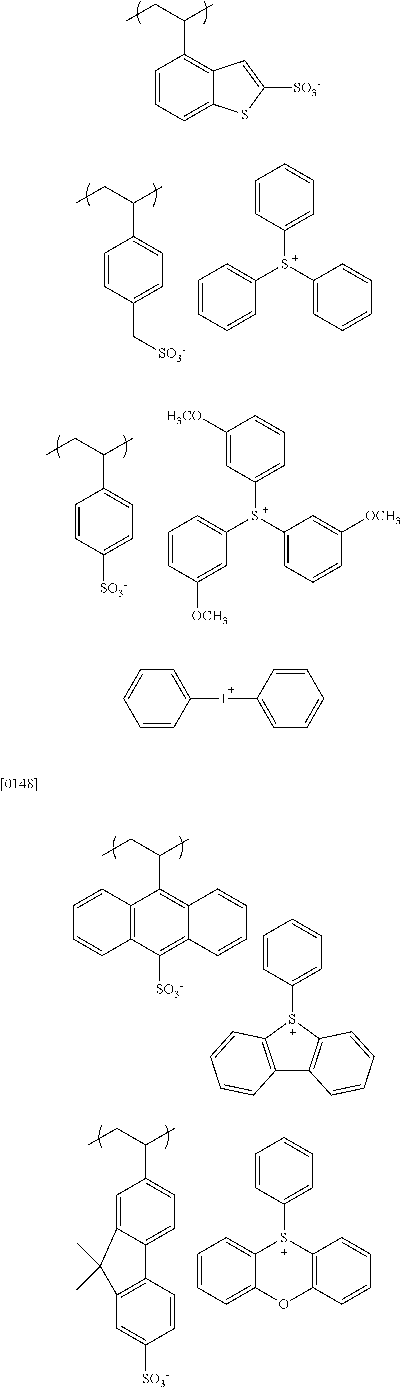

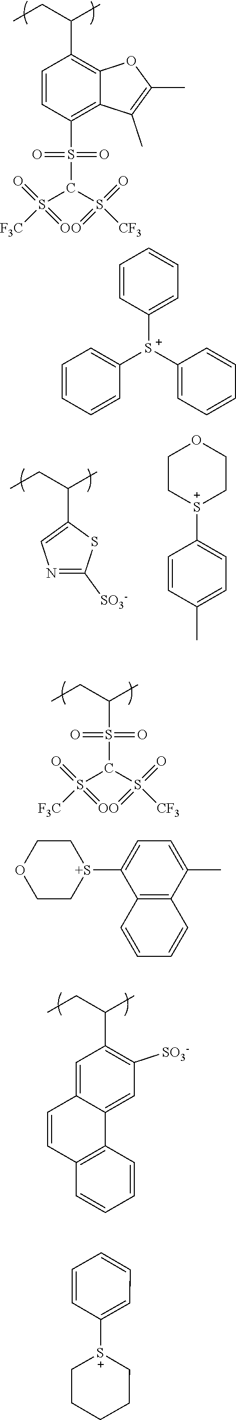

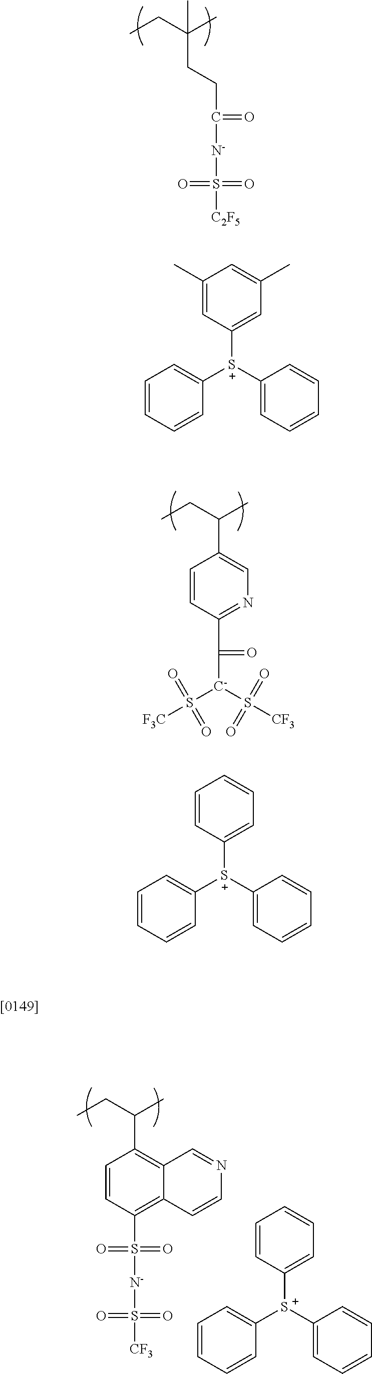

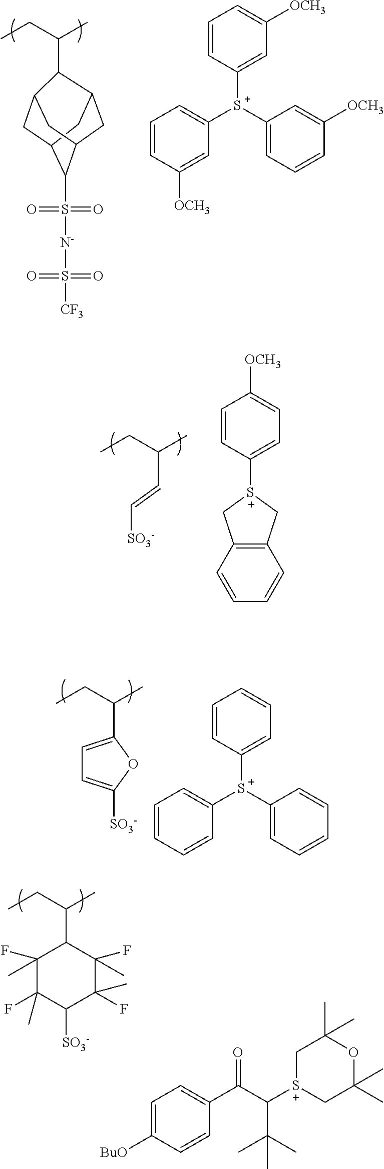

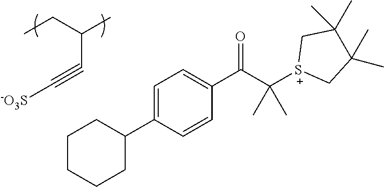

The resin (P) may include a single repeating unit (B) species alone, or may include two or more repeating unit (B) species in combination.

The content of the repeating unit (B) included in the resin (P) (in the case where a plurality of repeating units (B) are present, the total content thereof) is, relative to all the repeating units of the resin (P), preferably 1 mol % to 20 mol %, more preferably 2 mol % to 15 mol %, still more preferably 4 mol % to 15 mol %.

The resin (P) may contain a repeating unit other than the repeating unit (A) and the repeating unit (B) as long as advantages of the present invention are not impaired. Repeating unit having acid decomposable group other than repeating unit (A)

As the repeating unit having an acid decomposable group other than the repeating unit (A), a publicly known repeating unit can be appropriately used. Preferred examples include publicly known repeating units having an acid decomposable group in resins disclosed in paragraphs [0055] to [0191] of US2016/0274458A1, paragraphs [0035] to [0085] of US2015/0004544A1, and paragraphs [0045] to [0090] of US2016/0147150A1.

The content of the repeating unit having an acid decomposable group included in the resin (P) (in the case where a plurality of repeating units having an acid decomposable group are present, the total content thereof) is, relative to all the repeating units of the resin (P), preferably 10 to 90 mol %, more preferably 20 to 60 mol %, and still more preferably 30 to 50 mol %.

### Repeating Unit Having Acid Group

The resin (P) may have a repeating unit having an acid group.

The acid group is preferably an acid group having an acid dissociation constant (pKa) of 13 or less.

The acid group is particularly preferably a phenolic hydroxyl group.

The resin (P) preferably further has, in addition to the repeating unit (a) and the repeating unit (b), a repeating unit having a phenolic hydroxyl group.

The repeating unit having an acid group is preferably a repeating unit represented by a formula (B).

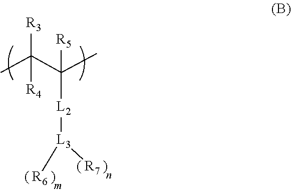

R₁₃ represents a hydrogen atom or a monovalent organic group.

The monovalent organic group is preferably a group represented by-L₄-R₈. L₄ represents a single bond or an ester group. Examples of R₅ include an alkyl group, a cycloalkyl group, an aryl group, and a group that is a combination of these.

R₄ and R₅ each independently represent a hydrogen atom, a halogen atom, or an alkyl group.

Examples of the halogen atom include a fluorine atom, a chlorine atom, a bromine atom, and an iodine atom.

L₁₂ represents a single bond or an ester group.

L₃ represents an (n+m+1) valent aromatic hydrocarbon ring group or an (n+m+1) valent alicyclic hydrocarbon ring group. Examples of the aromatic hydrocarbon ring group include a benzene ring group and a naphthalene ring group. The alicyclic hydrocarbon ring group may be monocyclic or polycyclic, and examples thereof include a cycloalkyl ring group.

R₆ represents a hydroxyl group or a fluorinated alcohol group (preferably a hexafluoroisopropanol group). Note that when R₆ is a hydroxyl group, L₃ is preferably an (n+m+1) valent aromatic hydrocarbon ring group.

R₇ represents a halogen atom. Examples of the halogen atom include a fluorine atom, a chlorine atom, a bromine atom, and an iodine atom.
m represents an integer of 1 or more. m is preferably an integer of 1 to 3, and preferably an integer of 1 to 2.
n represents 0 or an integer of 1 or more. n is preferably an integer of 1 to 4.

Note that (n+m+1) is preferably an integer of 1 to 5.

The repeating unit having an acid group is also preferably a repeating unit represented by a general formula (c) below (repeating unit (C)).

The resin (P) preferably further includes the repeating unit (C) represented by the following general formula (c).

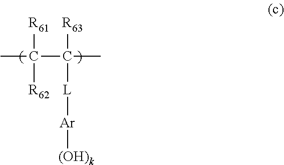

In the general formula (c), R₆₁ to R₆₃ represent a hydrogen atom, an organic group, or a halogen atom. However, R₆₂ may be bonded to Ar to form a ring and, in this case, R₆₂ represents a single bond or an alkylene group. L represents a single bond or a divalent linking group. Ar represents a (k+1) valent aromatic ring group and, when Ar is bonded to R₆₂ to form a ring, Ar represents a (k+2) valent aromatic ring group. k represents an integer of 1 to 5.

In the general formula (c), R₆₁ to R₆₃ represent a hydrogen atom, an organic group, or a halogen atom.

Examples of the organic groups represented by R₆₁ to R₆3 include alkyl groups, cycloalkyl groups, a cyano group, and alkoxycarbonyl groups.

The alkyl groups represented by R₆₁ to R₆₃ are preferably alkyl groups having 20 or less carbon atoms such as a methyl group, an ethyl group, a propyl group, an isopropyl group, an n-butyl group, a sec-butyl group, a hexyl group, a 2-ethylhexyl group, an octyl group, and a dodecyl group, more preferably alkyl groups having 8 or less carbon atoms, and still more preferably alkyl groups having 3 or less carbon atoms.

The cycloalkyl groups represented by R₆₁ to R₆3 may be monocyclic or polycyclic. Of these, preferred are monocyclic cycloalkyl groups having 3 to 8 carbon atoms, such as a cyclopropyl group, a cyclopentyl group, and a cyclohexyl group.

The alkyl groups included in the alkoxycarbonyl groups represented by R₆₁ to R₆₃ are preferably the same as the above-described alkyl groups in R₆₁ to R₆₃.

In the case where R₆₂ is bonded to Ar to form a ring, the alkylene group of R₆₂ is preferably a group provided by removing any one hydrogen atom from the above-described alkyl groups of R₆₁ to R₆₃.

Examples of the halogen atoms represented by R₆₁ to R₆₃ include a fluorine atom, a chlorine atom, a bromine atom, and an iodine atom, and preferred is a fluorine atom.

Preferred examples of substituents for the above-described groups include alkyl groups, cycloalkyl groups, aryl groups, an amino group, an amide group, a ureido group, a urethane group, a hydroxyl group, a carboxyl group, halogen atoms, alkoxy groups, a thioether group, acyl groups, acyloxy groups, alkoxycarbonyl groups, a cyano group, and a nitro group. Such a substituent preferably has 8 or less carbon atoms.

In the general formula (c), Ar represents a (k+1) valent aromatic ring group. In a case where k is 1, the divalent aromatic ring group may have a substituent, and preferred examples thereof include arylene groups having 6 to 18 carbon atoms such as a phenylene group, a tolylene group, a naphthylene group, and an anthracenylene group, and aromatic ring groups including a heterocycle such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring.

In a case where k is an integer of 2 or more, specific examples of the (k+1) valent aromatic ring group include a group provided by removing any (k−1) hydrogen atoms from the above-described specific examples of the divalent aromatic ring group.

The (k+1) valent aromatic ring group may further have a substituent.

Examples of the substituent that the (k+1) valent aromatic ring group may have include halogen atoms, alkyl groups, cycloalkyl groups, aryl groups, alkenyl groups, aralkyl groups, alkoxy groups, alkylcarbonyloxy groups, alkylsulfonyloxy groups, alkyloxycarbonyl groups, and aryloxycarbonyl groups.

Ar is preferably an aromatic ring group having 6 to 18 carbon atoms, and more preferably a benzene ring group, a naphthalene ring group, or a biphenylene ring group.

The repeating unit represented by the general formula (c) preferably includes a hydroxystyrene structure. That is, Ar is preferably a benzene ring group, and more preferably a divalent benzene ring group (phenylene group).

In the general formula (c), L represents a single bond or a divalent linking group.

Examples of the divalent linking group represented by L include *—X₄-L₄-**.

In the above-described formula, X₄ represents a single bond, —COO⁻, or —CONR₆₄—, and R₆₄ represents a hydrogen atom or an alkyl group.

L₄ represents a single bond or an alkylene group.

* is a direct bond to a carbon atom of the main chain in the general formula (c), and ** is a direct bond to Ar.

In-CONR₆₄—(R₆₄ represents a hydrogen atom or an alkyl group) represented by X₄, examples of the alkyl group of R₆₄ include alkyl groups having 20 or less carbon atoms such as a methyl group, an ethyl group, a propyl group, an isopropyl group, an n-butyl group, a sec-butyl group, a hexyl group, a 2-ethylhexyl group, an octyl group, and a dodecyl group, and preferred are alkyl groups having 8 or less carbon atoms.

X₄ is preferably a single bond, —COO⁻, or —CONH—, and more preferably a single bond or —COO—.

The alkylene group in L₄ is preferably an alkylene group having 1 to 8 carbon atoms such as a methylene group, an ethylene group, a propylene group, a butylene group, a hexylene group, or an octylene group.

L is preferably a single bond, —COO⁻, or —CONH—, and more preferably a single bond.

In the general formula (c), k represents an integer of 1 to 5.
k is preferably an integer of 1 to 3, more preferably 1 or 2, and still more preferably 1.

The repeating unit having an acid group is preferably a repeating unit represented by the following general formula (1).

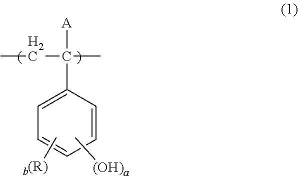

In the general formula (1),

A represents a hydrogen atom, an alkyl group, a cycloalkyl group, a halogen atom, or a cyano group.

R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group; when there are a plurality of R's, they may be the same or different. When there are a plurality of R's, they may together form a ring. R is preferably a hydrogen atom.
a represents an integer of 1 to 3.
b represents an integer of 0 to (3-a).

Specific examples of the repeating unit having an acid group will be described below; however, the present invention is not limited thereto. In the formulas, a represents an integer of 1 to 3.

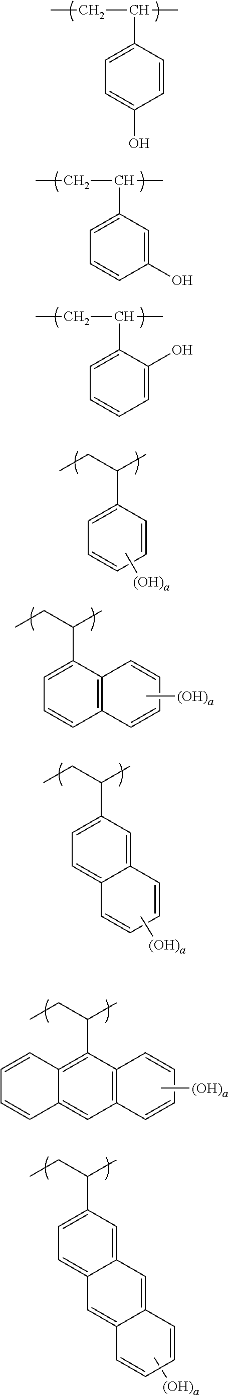

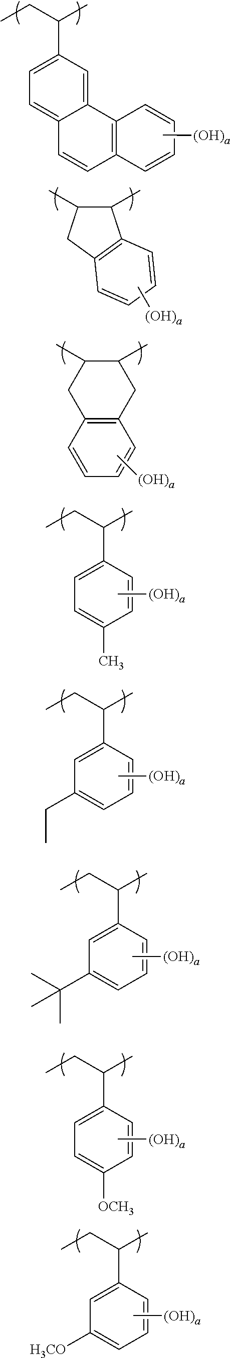

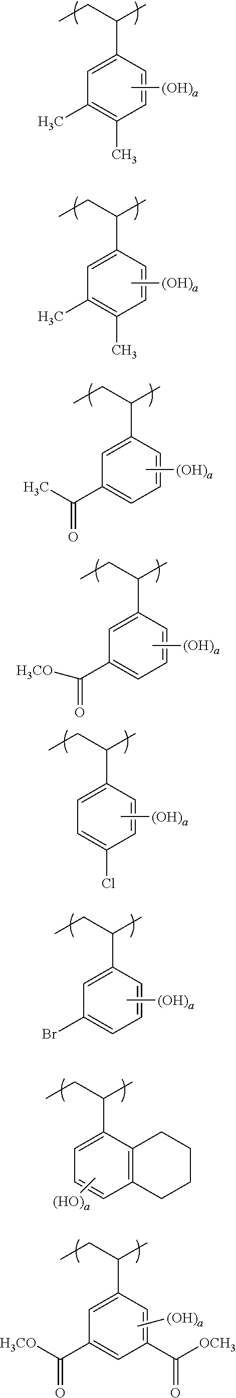

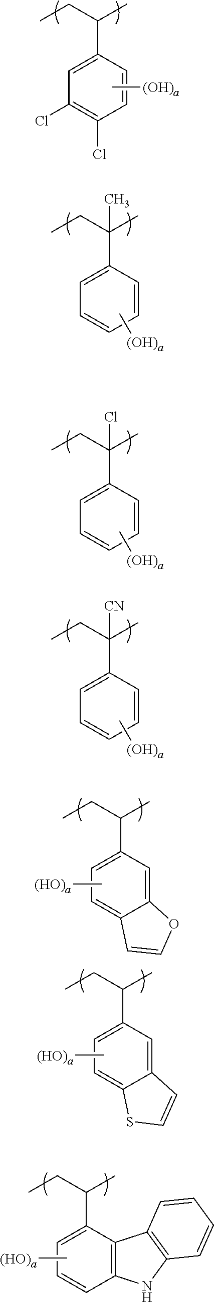

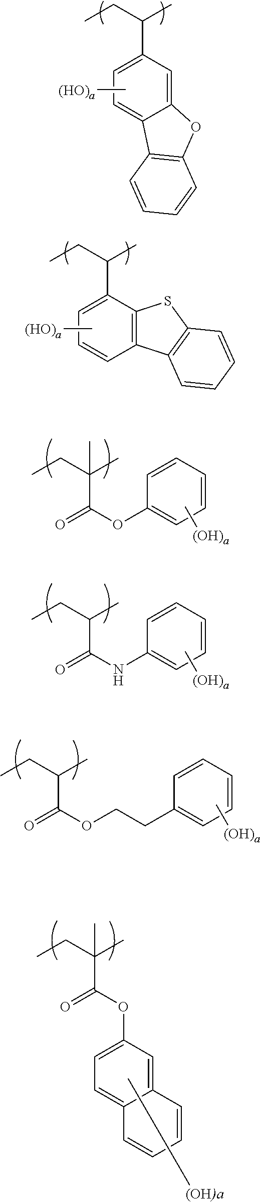

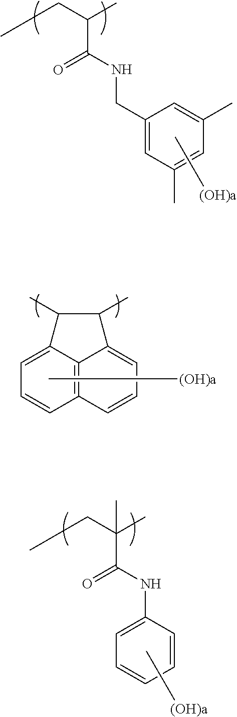

Note that, of the above-described repeating units, preferred are the following specific repeating units. In the formulas, R represents a hydrogen atom or a methyl group, and a represents 2 or 3.

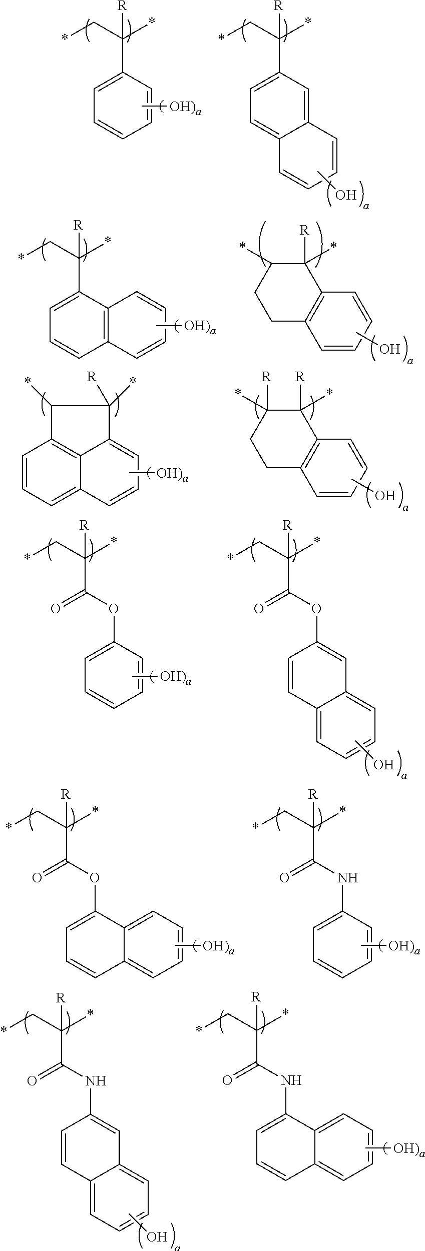

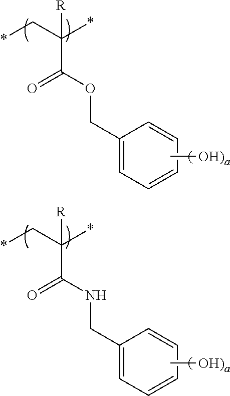

The content of the repeating unit having an acid group relative to all the repeating units in the resin (P) is preferably 10 to 80 mol %, more preferably 15 to 75 mol %, and still more preferably 20 to 70 mol %.

Repeating unit having lactone group or sultone group

The resin (P) may further have a repeating unit having a lactone group or a sultone group.

The lactone group or the sultone group may be any group as long as it has a lactone structure or a sultone structure, but is preferably a group having a 5- to 7-membered lactone structure or a 5- to 7-membered sultone structure, and more preferably a group in which a 5- to 7-membered lactone structure is fused with another ring structure to form a bicyclo structure or a spiro structure, or a group in which a 5- to 7-membered sultone structure is fused with another ring structure to form a bicyclo structure or a spiro structure. The repeating unit more preferably has a group having a lactone structure represented by any one of the following general formulas (LC1-1) to (LC1-21) or a group having a sultone structure represented by any one of the following general formulas (SL1-1) to (SL1-3). A group having a lactone structure or a sultone structure may be directly bonded to the main chain. Preferred structures are groups represented by the general formula (LC1-1), the general formula (LC1-4), the general formula (LC1-5), the general formula (LC1-6), the general formula (LC1-13), or the general formula (LC1-14).

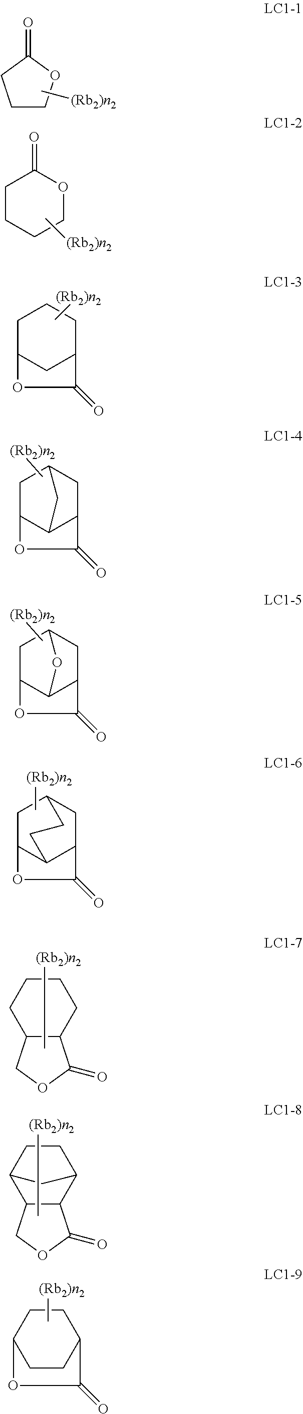

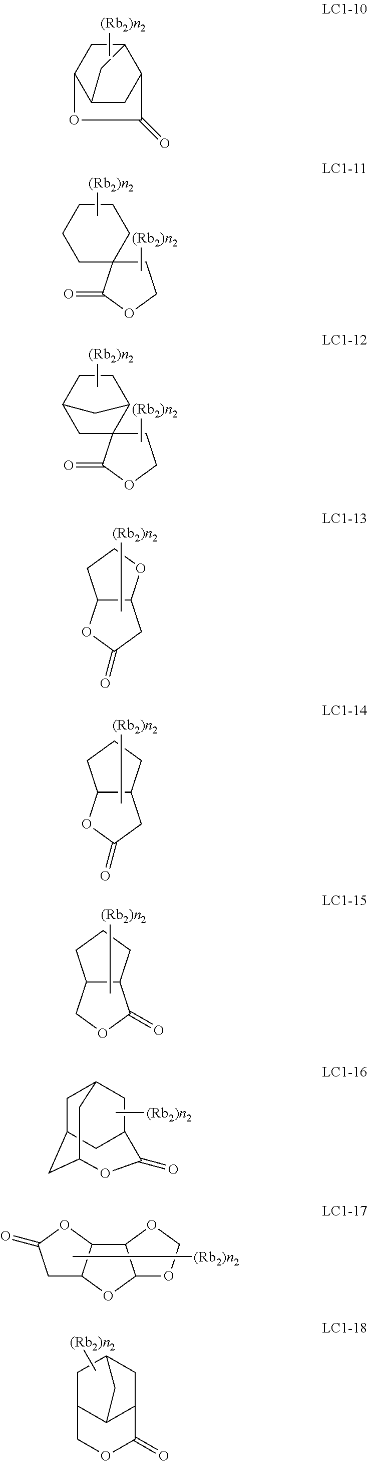

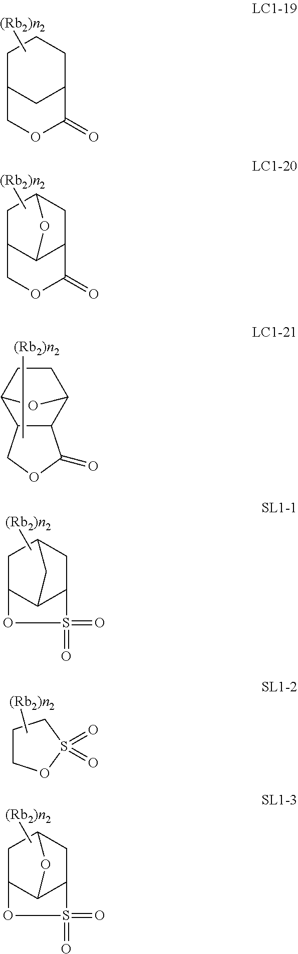

The lactone structure moiety or the sultone structure moiety may have a substituent (Rb₂). Preferred examples of the substituent (Rb₂) include alkyl groups having 1 to 8 carbon atoms, cycloalkyl groups having 4 to 7 carbon atoms, alkoxy groups having 1 to 8 carbon atoms, alkoxycarbonyl groups having 1 to 8 carbon atoms, a carboxyl group, halogen atoms, a hydroxyl group, a cyano group, and acid decomposable groups. n2 represents an integer of 0 to 4. When n2 is 2 or more, the plurality of Rb₂'s present may be different, or the plurality of Rb₂'s present may be linked together to form a ring.

Examples of the repeating unit having a group having a lactone structure or a sultone structure include a repeating unit represented by the following general formula (AI).

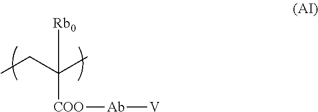

In the general formula (AI), Rbₒ represents a hydrogen atom, a halogen atom, or an alkyl group having 1 to 4 carbon atoms.

Preferred examples of the substituent that the alkyl group of Rbₒ may have include a hydroxyl group and halogen atoms.

Examples of the halogen atom of Rb₀ include a fluorine atom, a chlorine atom, a bromine atom, and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent group that is a combination of these. Of these, preferred are a single bond and a linking group represented by-Ab₁-CO₂-. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group having a lactone structure or a sultone structure.

The group having a lactone structure or a sultone structure and serving as V is preferably a group represented by any one of the general formulas (LC1-1) to (LC1-21) and the general formulas (SL1-1) to (SL1-3).

The repeating unit having a group having a lactone structure or a sultone structure ordinarily has optical isomers, and any one of the optical isomers may be used. One of the optical isomers may be used alone, or a plurality of optical isomers may be used in admixture. In the case of mainly using one of the optical isomers, its optical purity (ee) is preferably 90 or more, and more preferably 95 or more.

Specific examples of the repeating unit having a group having a lactone structure or a sultone structure will be described below; however, the present invention is not limited thereto. Note that, in the formulas, Rₓ represents H, CH₃, CH₂OH, or CF₃.

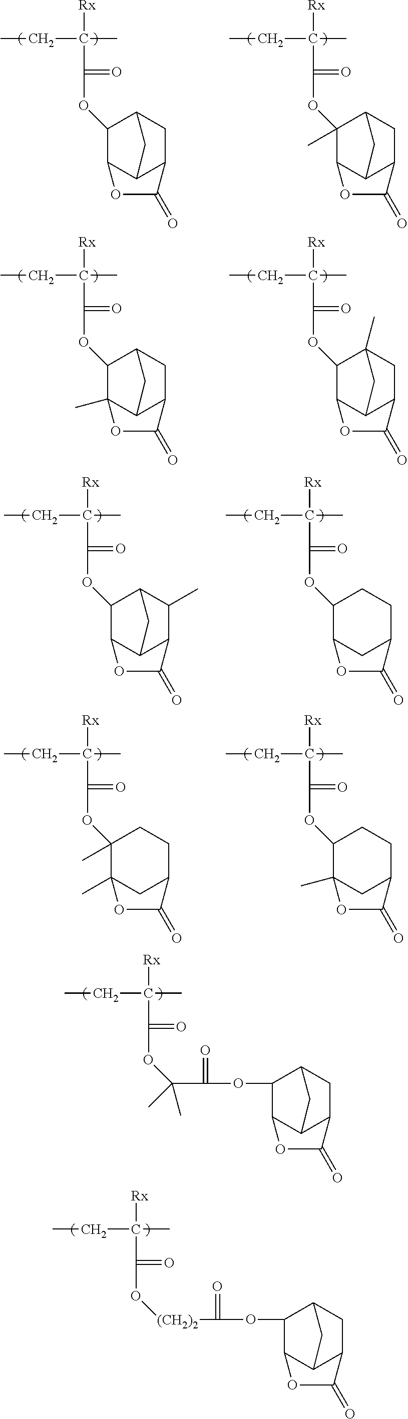

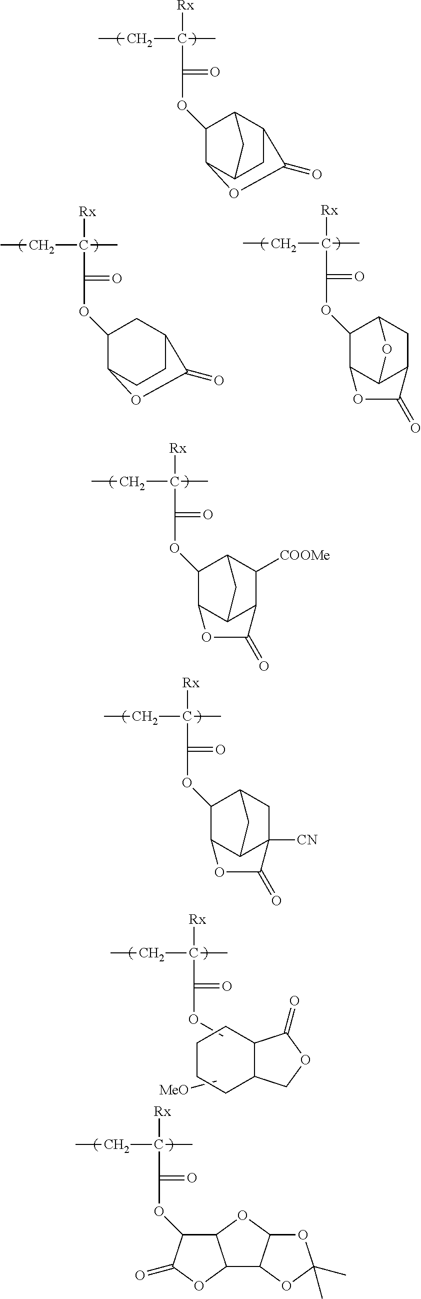

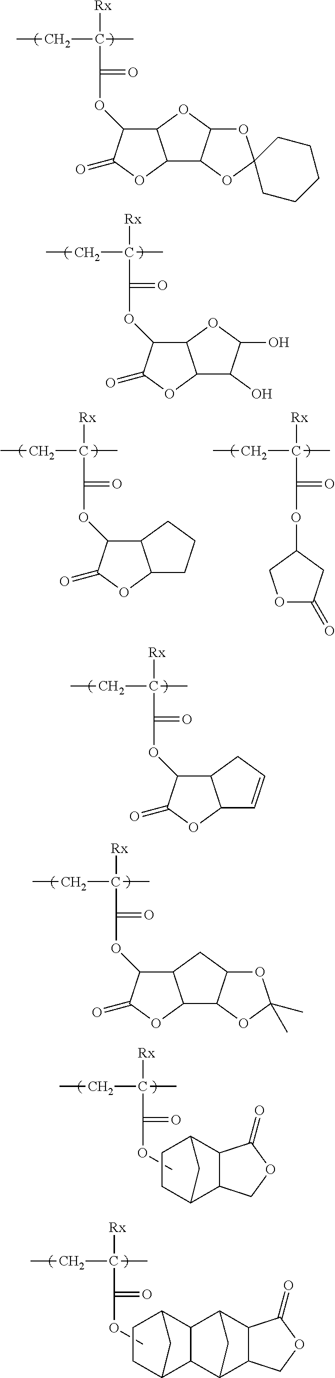

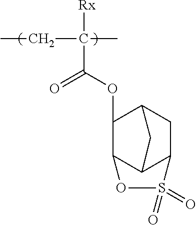

The content of the repeating unit having a lactone group or a sultone group is, relative to all the repeating units in the resin (P), preferably 1 to 60 mol %, more preferably 5 to 50 mol %, and still more preferably 10% to 40 mol %.

### Repeating Unit Having Fluorine Atom or Iodine Atom

The resin (P) may have a repeating unit having a fluorine atom or an iodine atom.

Examples of the repeating unit having a fluorine atom or an iodine atom include the repeating units described in paragraphs 0080 to 0081 of JP2019-045864A.

### Repeating Unit Having Photoacid Generation Group

The resin (P) may have, as a repeating unit other than the repeating unit (B), a repeating unit having a group that generates an acid upon irradiation with a radiation.

Examples of the repeating unit having a fluorine atom or an iodine atom include the repeating units described in paragraphs 0092 to 0096 of JP2019-045864A.

Repeating unit having alkali-soluble group

The resin (P) may have a repeating unit having an alkali-soluble group.

Examples of the alkali-soluble group include a carboxyl group, a sulfonamide group, a sulfonylimide group, a bissulfonylimide group, and aliphatic alcohols substituted with an electron-withdrawing group at the α-position (for example, a hexafluoroisopropanol group), and preferred is a carboxyl group. The resin (P) that has a repeating unit having an alkali-soluble group provides increased resolution in the contact-hole applications.

Examples of the repeating unit having an alkali-soluble group include repeating units in which an alkali-soluble group is directly bonded to the main chain of the resin, such as repeating units derived from acrylic acid and methacrylic acid, and repeating units in which an alkali-soluble group is bonded to the main chain of the resin via a linking group. Note that the linking group may have a monocyclic or polycyclic cyclic hydrocarbon structure.

The repeating unit having an alkali-soluble group is preferably a repeating unit derived from acrylic acid or methacrylic acid.

### Repeating Unit not Having Acid Decomposable Group or Polar Group

The resin (P) may further have a repeating unit not having an acid decomposable group or a polar group. The repeating unit not having an acid decomposable group or a polar group preferably has an alicyclic hydrocarbon structure.

Examples of the repeating unit not having an acid decomposable group or a polar group include the repeating units described in paragraphs 0236 to 0237 of US2016/0026083A and the repeating units described in paragraph 0433 of US2016/0070167A.

The resin (P) may have, in addition to the above-described repeating structural units, various repeating units in accordance with, for example, a purpose of controlling dry etching resistance, suitability for the standard developer, adhesiveness to the substrate, resist profiles, resolving power, heat resistance, sensitivity, or the like.

The resin (P) can be synthesized in accordance with standard procedures (for example, radical polymerization). Examples of the general synthesis method include (1) a batch polymerization method in which a monomer species and an initiator are dissolved in a solvent and heated to perform polymerization, and (2) a dropping polymerization method in which a solution containing a monomer species and an initiator is added dropwise for 1 to 10 hours to perform addition to a heated solvent.

The resin (P) preferably has a weight-average molecular weight (Mw) of 1,000 to 200,000, more preferably 2,000 to 30,000, and still more preferably 3,000 to 25,000. The dispersity (Mw/Mn) is ordinarily 1.0 to 3.0, preferably 1.0 to 2.6, more preferably 1.0 to 2.0, and still more preferably 1.1 to 2.0.

For the resin (P), one species may be used alone, or two or more species may be used in combination.

In the composition of the present invention, the content of the resin (P) is, relative to the total solid content, preferably 50 mass % or more, more preferably 70 mass % or more, still more preferably 80 mass % or more, and particularly preferably 90 mass % or more. The upper limit is not particularly limited, and may be, for example, less than 100 mass %.

The total solid content means, except for the solvent, the other components. Compound that generates acid upon irradiation with actinic ray or radiation

The composition of the present invention may contain, as a component different from the resin (P), a compound that generates an acid upon irradiation with an actinic ray or a radiation (also referred to as a “photoacid generator”) as long as advantages of the present invention are not impaired.

The photoacid generator is a compound that generates an acid upon irradiation with an actinic ray or a radiation.

The photoacid generator is preferably a compound that generates an organic acid upon irradiation with an actinic ray or a radiation. Examples thereof include a sulfonium salt compound, an iodonium salt compound, a diazonium salt compound, a phosphonium salt compound, an imide sulfonate compound, an oxime sulfonate compound, a diazodisulfone compound, a disulfone compound, and an o-nitrobenzyl sulfonate compound.

As the photoacid generator, a publicly known compound that generates an acid upon irradiation with an actinic ray or a radiation can be appropriately selected and used alone or as a mixture thereof. For example, publicly known compounds disclosed in paragraphs [0125] to [0319] of US2016/0070167A1, paragraphs [0086] to [0094] of US2015/0004544A1, paragraphs [0323] of US2016/0237190A1, and paragraphs [0328] to [0350] of JP5548473B can be suitably used.

### Acid Diffusion Control Agent

The composition of the present invention preferably contains an acid diffusion control agent. The acid diffusion control agent acts as a quencher that traps an acid generated from a photoacid generator or the like upon exposure and suppresses the reaction of the acid decomposable resin in the unexposed regions due to an excess of the generated acid.

For the acid diffusion control agent, for example, a basic compound (DA), a basic compound (DB) that undergoes reduction or loss of the basicity upon irradiation with an actinic ray or a radiation, an onium salt (DC) that serves as a weak acid relative to the acid generator, a low molecular weight compound (DD) having a nitrogen atom and having a group that leaves by the action of an acid, or an onium salt compound (DE) having a nitrogen atom in the cationic moiety can be used as the acid diffusion control agent. In the composition of the present invention, a publicly known acid diffusion control agent can be appropriately used. For example, publicly known compounds disclosed in paragraphs [0627] to [0664] of US2016/0070167A1, paragraphs [0095] to [0187] of US2015/0004544A1, paragraphs [0403] to [0423] of US2016/0237190A1, and paragraphs [0259] to [0328] of US2016/0274458A1 can be suitably used as the acid diffusion control agent.

As the basic compound (DA), compounds having structures represented by the following general formulas (A) to (E) are preferred.

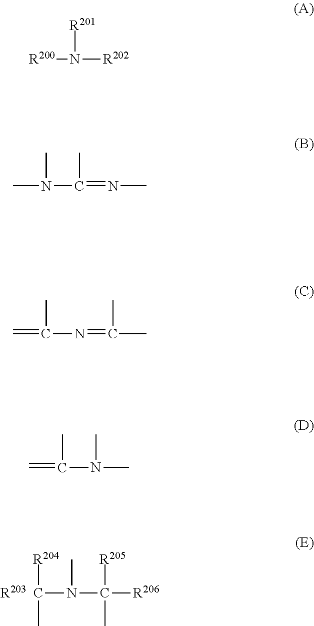

In the general formulas (A) and (E),
R²⁰⁰, R²⁰¹, and R²⁰² may be the same or different, and each independently represent a hydrogen atom, an alkyl group (preferably having 1 to 20 carbon atoms), a cycloalkyl group (preferably having 3 to 20 carbon atoms), or an aryl group (having 6 to 20 carbon atoms); R²⁰¹ and R²⁰² may be bonded together to form a ring; and
R²⁰³, R²⁰⁴, R²⁰⁵, and R²⁰⁶ may be the same or different, and each independently represent an alkyl group having 1 to 20 carbon atoms.

The alkyl groups in the general formulas (A) and (E) may have a substituent or may be unsubstituted.

For such an alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl groups in the general formulas (A) and (E) are more preferably unsubstituted.

The basic compound (DA) is preferably thiazole, benzothiazole, oxazole, benzoxazole, guanidine, aminopyrrolidine, pyrazole, pyrazoline, piperazine, aminomorpholine, aminoalkylmorpholine, piperidine, or a compound having such a structure, and more preferably, for example, a compound having a thiazole structure, a benzothiazole structure, an oxazole structure, a benzoxazole structure, an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, or an aniline derivative having a hydroxyl group and/or an ether bond.

The basic compound (DB) that undergoes reduction or loss of the basicity upon irradiation with an actinic ray or a radiation (hereinafter, also referred to as “compound (DB)”) is a compound that has a proton acceptor functional group and is decomposed upon irradiation with an actinic ray or a radiation to undergo reduction or loss of the proton acceptor property or change from the proton acceptor property to acidity.

The proton acceptor functional group is a group that electrostatically interacts with a proton or a functional group having an electron, and means, for example, a functional group having a macrocyclic structure such as cyclic polyether, or a functional group having a nitrogen atom having an unshared electron pair that does not contribute to π-conjugation. The nitrogen atom having an unshared electron pair that does not contribute to π-conjugation is, for example, nitrogen atoms having partial structures represented by the following formulas.

[symbol]

### Unshared Electron Pair

Preferred examples of the partial structure of the proton acceptor functional group include crown ether structures, azacrown ether structures, primary to tertiary amine structures, a pyridine structure, an imidazole structure, and a pyrazine structure.

The compound (DB) is decomposed upon irradiation with an actinic ray or a radiation to generate a compound that has undergone reduction or loss of the proton acceptor property or change from the proton acceptor property to acidity. The phrase “reduction or loss of the proton acceptor property or change from the proton acceptor property to acidity” is a change in the proton acceptor property caused by the addition of a proton to the proton acceptor functional group, and specifically means that, when a proton adduct is generated from the compound (DB) having a proton acceptor functional group and a proton, the equilibrium constant in the chemical equilibrium decreases.

The proton acceptor property can be confirmed by pH measurement.

The compound generated as a result of decomposition of the compound (DB) upon irradiation with an actinic ray or a radiation has an acid dissociation constant pKa that preferably satisfies pKa <−1, more preferably satisfies −13<pKa <−1, and still more preferably satisfies −13<pKa <−3.

In the composition of the present invention, the onium salt (DC) that serves as a weak acid relative to the photoacid generator can be used as an acid diffusion control agent.

In such a case of using a mixture of the photoacid generator and the onium salt that generates an acid that is weak relative to the acid generated from the photoacid generator, when the acid generated from the photoacid generator upon irradiation with an actinic ray or a radiation collides with the onium salt having an unreacted weak acid anion, the weak acid is released by salt exchange to generate an onium salt having a strong acid anion. In this process, the strong acid is exchanged with the weak acid having a lower catalytic activity, so that the acid is apparently deactivated and the acid diffusion can be controlled.

As the onium salt that serves as a weak acid relative to the photoacid generator, preferred are compounds represented by the following general formulas (d1-1) to (d1-3).

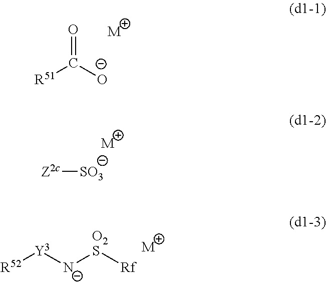

In the formulas, R⁵¹ is a hydrocarbon group that may have a substituent, Z^{2c} is a hydrocarbon group that may have a substituent and has 1 to 30 carbon atoms (with the proviso that the carbon atom adjacent to S is not substituted with fluorine atoms), R⁵² is an organic group, Y³ is a linear, branched, or cyclic alkylene group or an arylene group, Rf is a hydrocarbon group including a fluorine atom, and M⁺'s are each independently an ammonium cation, a sulfonium cation, or an iodonium cation.

Preferred examples of the sulfonium cation or the iodonium cation represented by M⁺include the sulfonium cation exemplified in the general formula (ZI) and the iodonium cation exemplified in the general formula (ZII).

The onium salt (DC) that serves as a weak acid relative to the photoacid generator may be a compound (hereinafter, also referred to as “compound (DCA)”) that has a cationic moiety and an anionic moiety in the same molecule and in which the cationic moiety and the anionic moiety are linked together via a covalent bond.

The compound (DCA) is preferably a compound represented by any one of the following general formulas (C-1) to (C-3).

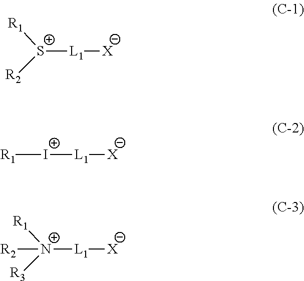

In the general formulas (C-1) to (C-3),
R₁, R₂, and R₁₃ each independently represent a substituent having 1 or more carbon atoms.
L₁ represents a divalent linking group or a single bond that links together the cationic moiety and the anionic moiety.
—X⁻ represents an anionic moiety selected from the group consisting of —COO⁻, —SO₃⁻, —SO₂⁻, and —N—R₄. R₄ represents a monovalent substituent having, at the linking site to the adjacent N atom, at least one of a carbonyl group (-C(═O)-), a sulfonyl group (-S(═O)₂-), or a sulfinyl group (-S(═O)-).

R₁, R₂, R₃, R₄, and Li may be bonded together to form a ring structure. In the general formula (C-3), two among R₁ to R₁₃ may collectively represent a single divalent substituent, and may be bonded to the N atom via a double bond.

For R₁ to R₃, examples of the substituent having 1 or more carbon atoms include alkyl groups, cycloalkyl groups, aryl groups, alkyloxycarbonyl groups, cycloalkyloxycarbonyl groups, aryloxycarbonyl groups, alkylaminocarbonyl groups, cycloalkylaminocarbonyl groups, and arylaminocarbonyl groups. Preferred are alkyl groups, cycloalkyl groups, and aryl groups.

Examples of Li serving as a divalent linking group include linear or branched alkylene groups, cycloalkylene groups, arylene groups, a carbonyl group, an ether bond, an ester bond, an amide bond, a urethane bond, a urea bond, and groups that are combinations of two or more of these. Li is preferably an alkylene group, an arylene group, an ether bond, an ester bond, or a group that is a combination of two or more of these.

The low molecular weight compound (DD) having a nitrogen atom and having a group that leaves by the action of an acid (hereinafter, also referred to as “compound (DD)”) is preferably an amine derivative having, on the nitrogen atom, a group that leaves by the action of an acid.

The group that leaves by the action of an acid is preferably an acetal group, a carbonate group, a carbamate group, a tertiary ester group, a tertiary hydroxyl group, or a hemiaminal ether group, and more preferably a carbamate group or a hemiaminal ether group.

The molecular weight of the compound (DD) is preferably 100 to 1,000, more preferably 100 to 700, and still more preferably 100 to 500.

The compound (DD) may have, on the nitrogen atom, a carbamate group having a protecting group. The protecting group constituting the carbamate group is represented by the following general formula (d-1).

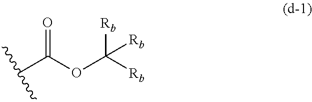

In the general formula (d-1),
Rb's each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). Rb's may be bonded together to form a ring.

The alkyl groups, the cycloalkyl groups, the aryl groups, and the aralkyl groups represented by Rb's may each independently be substituted with a functional group such as a hydroxyl group, a cyano group, an amino group, a pyrrolidino group, a piperidino group, a morpholino group, or an oxo group, an alkoxy group, or a halogen atom. The same applies to the alkoxyalkyl groups represented by Rb's.

Rb is preferably a linear or branched alkyl group, a cycloalkyl group, or an aryl group, and more preferably a linear or branched alkyl group or a cycloalkyl group.

Examples of the ring formed by linking together two Rb's include alicyclic hydrocarbons, aromatic hydrocarbons, heterocyclic hydrocarbons, and derivatives of the foregoing.

Specific examples of the structure of the group represented by the general formula (d-1) include, but are not limited to, the structures disclosed in paragraph [0466] of US2012/0135348A1.

The compound (DD) preferably has a structure represented by the following general formula (6).

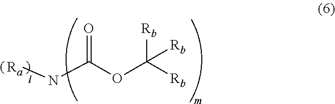

In the general formula (6),
1 represents an integer of 0 to 2, m represents an integer of 1 to 3, and 1+m=3 is satisfied.
Ra represents a hydrogen atom, an alkyl group, a cycloalkyl group, an aryl group, or an aralkyl group. When 1 is 2, two Ra's may be the same or different, and two Ra's may be linked together to form a heterocycle together with the nitrogen atom in the formula. The heterocycle may include a heteroatom other than the nitrogen atom in the formula.

Rb has the same definition as Rb in the above-described general formula (d-1), and preferred examples thereof are also the same.

In the general formula (6), the alkyl group, the cycloalkyl group, the aryl group, and the aralkyl group serving as Ra may each independently be substituted with the same groups as the groups described above as the groups with which the alkyl group, the cycloalkyl group, the aryl group, and the aralkyl group serving as Rb's may be substituted.

For Ra above, specific examples of the alkyl group, the cycloalkyl group, the aryl group, and the aralkyl group (these groups may be substituted with the above-described groups) include the same groups as the specific examples described above for Rb.

Particularly preferred, specific examples of the compound (DD) in the present invention include, but are not limited to, the compounds disclosed in paragraph [0475] of US2012/0135348A1.

The onium salt compound (DE) having a nitrogen atom in the cationic moiety (hereinafter, also referred to as “compound (DE)”) is preferably a compound having a basic moiety including a nitrogen atom in the cationic moiety. The basic moiety is preferably an amino group, and more preferably an aliphatic amino group. Still more preferably, all of the atoms adjacent to the nitrogen atom in the basic moiety are hydrogen atoms or carbon atoms. From the viewpoint of improving basicity, an electron-withdrawing functional group (a carbonyl group, a sulfonyl group, a cyano group, a halogen atom, or the like) is preferably not directly bonded to the nitrogen atom.

Specific preferred examples of the compound (DE) include, but are not limited to, the compounds disclosed in paragraph [0203] of US2015/0309408A1.

Preferred examples of the acid diffusion control agent will be described below; however, the present invention is not limited thereto. Me represents a methyl group.

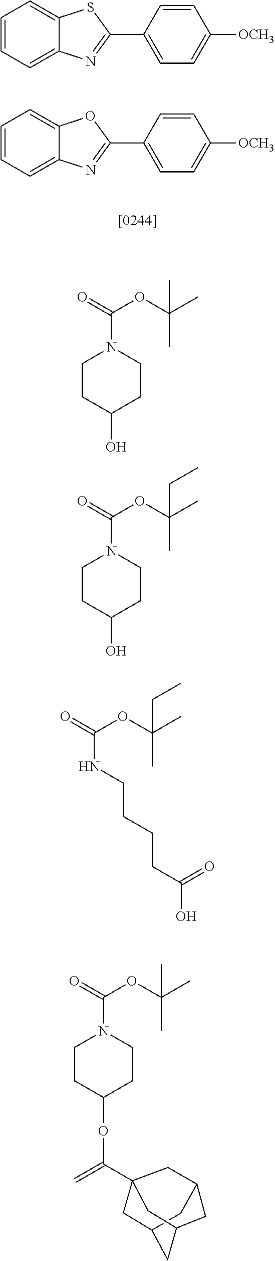

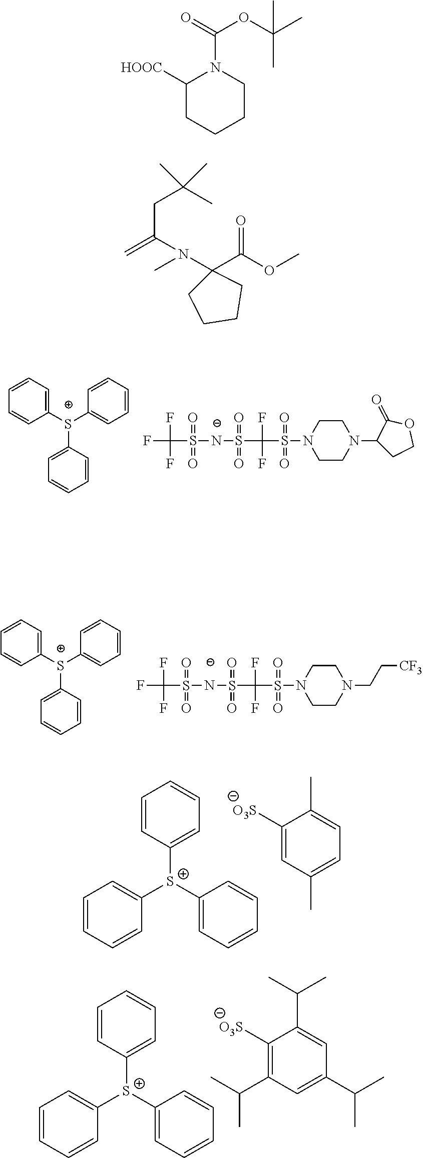

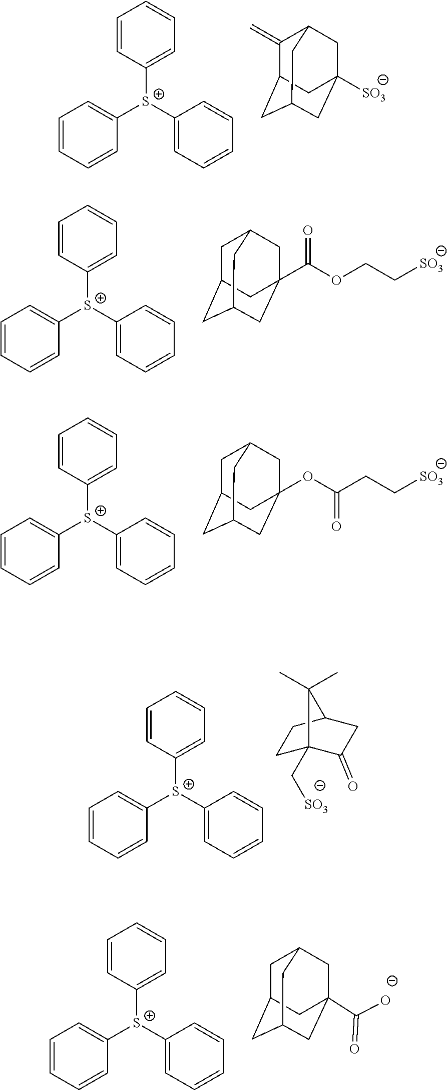

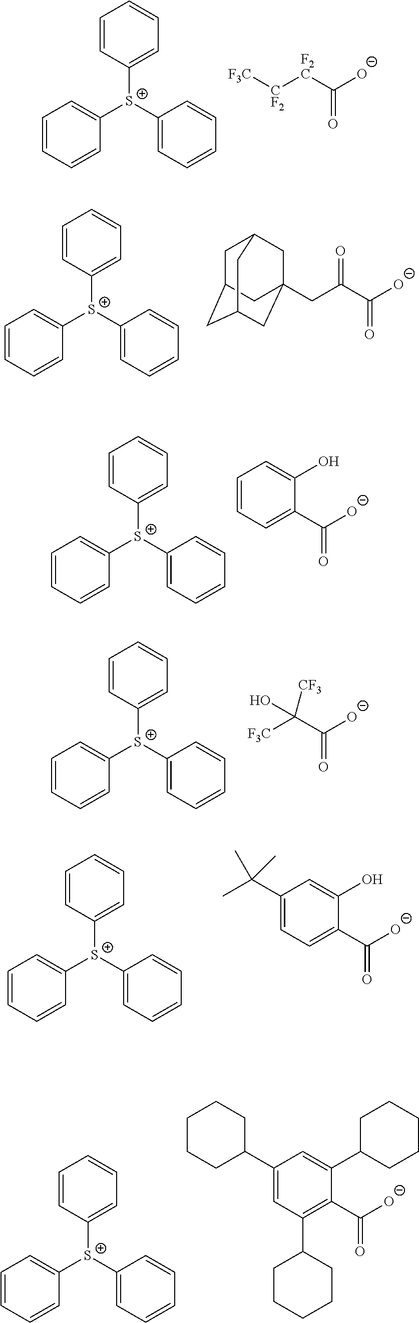

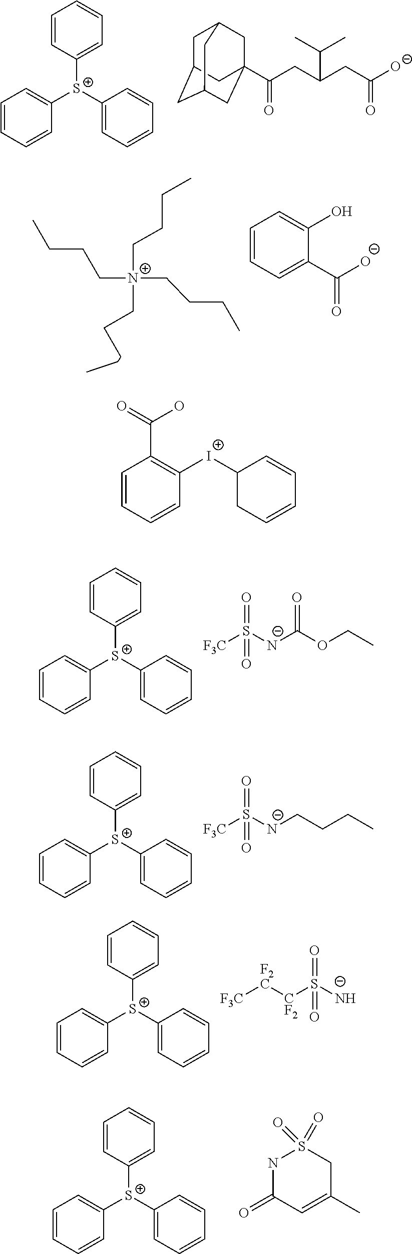

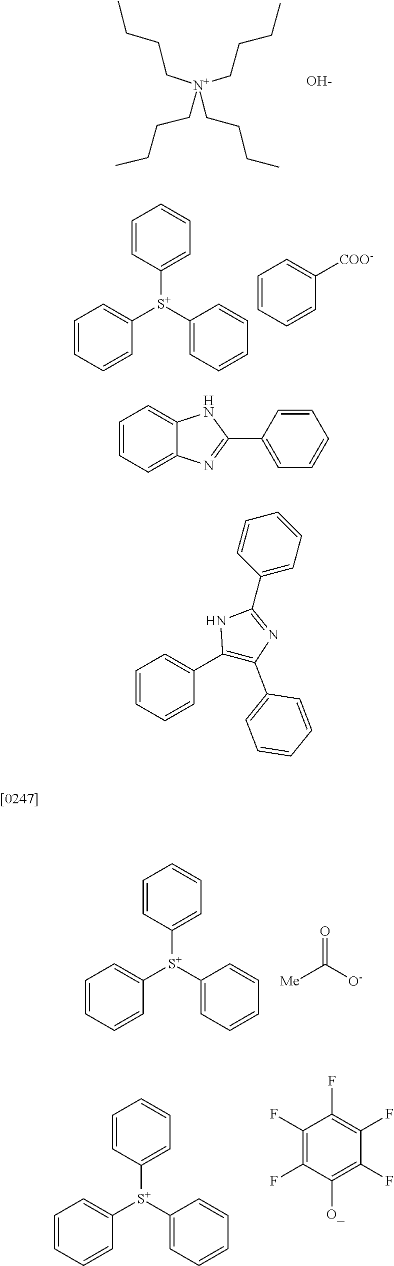

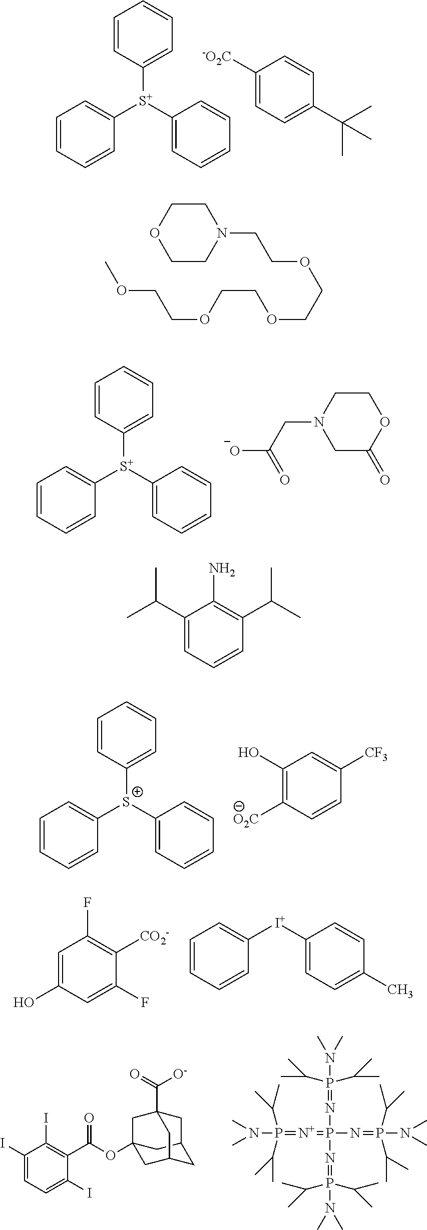

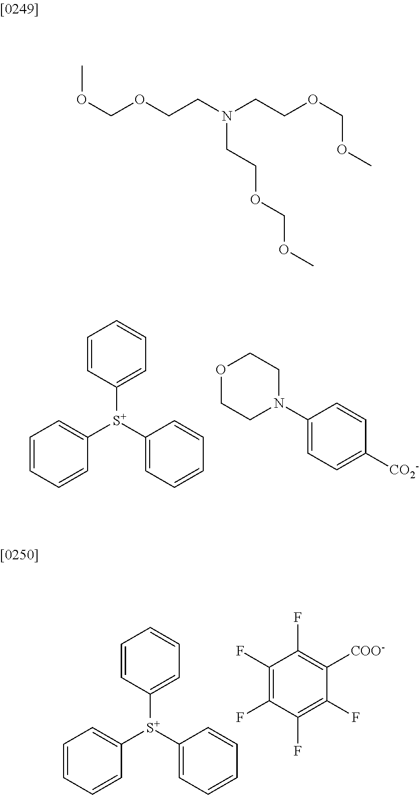

In the composition of the present invention, such acid diffusion control agents may be used alone or in combination of two or more thereof.

The content of the acid diffusion control agent in the composition of the present invention (in the case where a plurality of acid diffusion control agents are present, the total content thereof) is, relative to the total solid content of the composition, preferably 0.001 to 20 mass % and more preferably 0.01 to 10 mass %.

### Solvent

The composition of the present invention contains a solvent.

In the composition of the present invention, a publicly known resist solvent can be appropriately used. For example, publicly known solvents disclosed in paragraphs [0665] to [0670] of US2016/0070167A1, paragraphs [0210] to [0235] of US2015/0004544A1, paragraphs [0424] to [0426] of US2016/0237190A1, and paragraphs [0357] to [0366] of US2016/0274458A1 can be suitably used.

Examples of the solvent that can be used in the preparation of the composition include organic solvents such as alkylene glycol monoalkyl ether carboxylates, alkylene glycol monoalkyl ethers, alkyl lactates, alkyl alkoxypropionates, cyclic lactones (preferably having 4 to 10 carbon atoms), monoketone compounds (preferably having 4 to 10 carbon atoms) that may have a ring, alkylene carbonates, alkyl alkoxyacetates, and alkyl pyruvates.

Preferred examples of the alkylene glycol monoalkyl ether carboxylates include propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Preferred examples of the alkylene glycol monoalkyl ethers include propylene glycol monomethyl ether, propylene glycol monoethyl ether, propylene glycol monopropyl ether, propylene glycol monobutyl ether, ethylene glycol monomethyl ether, and ethylene glycol monoethyl ether.

Preferred examples of the alkyl lactates include methyl lactate, ethyl lactate, propyl lactate, and butyl lactate.

Preferred examples of the alkyl alkoxypropionates include ethyl 3-ethoxypropionate, methyl 3-methoxypropionate, methyl 3-ethoxypropionate, and ethyl 3-methoxypropionate.

Preferred examples of the cyclic lactones include β-propiolactone, β-butyrolactone, γ-butyrolactone, α-methyl-γ-butyrolactone, β-methyl-γ-butyrolactone, γ-valerolactone, γ-caprolactone, y-octanoic lactone, and a-hydroxy-γ-butyrolactone.

Preferred examples of the monoketone compounds that may contain a ring include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, 3-methylcycloheptanone, and diacetone alcohol.

Preferred examples of the alkylene carbonates include propylene carbonate, vinylene carbonate, ethylene carbonate, and butylene carbonate.

Preferred examples of the alkyl alkoxyacetates include 2-methoxyethyl acetate, 2-ethoxyethyl acetate, 2-(2-ethoxyethoxy) ethyl acetate, 3-methoxy-3-methylbutyl acetate, 1-methoxy-2-propyl acetate, and 3-methoxybutyl acetate.

Preferred examples of the alkyl pyruvates include methyl pyruvate, ethyl pyruvate, and propyl pyruvate.

In the present invention, the above-described solvents may be used alone or in combination of two or more thereof.

In the composition of the present invention, relative to the total amount of the solvent, the content of a solvent having a boiling point of 150° C. or more is 45 mass % or more. The boiling point is the boiling point at 1 atm (101325 Pa).

The above-described solvents may be used alone or in combination of two or more thereof. Further, a solvent having a boiling point of less than 150° C. at 1 atm may be used in combination.

In the composition of the present invention, relative to the total amount of the solvent, the content of a solvent having a boiling point of 150° C. or more is 45 mass % or more, preferably 60 mass % or more, more preferably 70 mass % or more, still more preferably 80 mass % or more, and particularly preferably 90 mass % or more.

In the composition of the present invention, relative to the total amount of the solvent, the content of a solvent having a boiling point of 150° C. or more is preferably 100 mass % or less.

In the composition of the present invention, relative to the total amount of the solvent, the content of a solvent having a boiling point of 150° C. or more is preferably 70 mass % to 100 mass %, more preferably 80 mass % to 100 mass %, and still more preferably 90 mass % to 100 mass %.

For the solvent having a boiling point of 150° C. or more, the boiling point is not particularly limited, but is ordinarily 200° C. or less, and preferably 180° C. or less.

The solvent having a boiling point of 150° C. or more is preferably an organic solvent and can be selected from the group consisting of organic solvents such as alkylene glycol monoalkyl ether carboxylates, alkylene glycol monoalkyl ethers, alkyl lactates, alkyl alkoxypropionates, cyclic lactones, monoketone compounds that may contain a ring, alkylene carbonates, alkyl alkoxyacetates, and alkyl pyruvates.

For example, a solvent having a boiling point of 150° C. or more at 1 atm may be selected from the group consisting of the following solvents, and such solvents may be used alone or in combination of two or more thereof and may be used in combination with a solvent having a boiling point of less than 150° C. at 1 atm.

Preferred examples of the alkylene glycol monoalkyl ether carboxylates include propylene glycol monomethyl ether acetate (PGMEA; 1-methoxy-2-acetoxypropane) (b.p.=146° C.), propylene glycol monoethyl ether acetate (b.p.=164 to 165° C.), propylene glycol monopropyl ether acetate (b.p.=173 to 174° C./740 mmHg), ethylene glycol monomethyl ether acetate (b.p.=143° C.), and ethylene glycol monoethyl ether acetate (b.p.=156° C.).

Preferred examples of the alkylene glycol monoalkyl ethers include propylene glycol monomethyl ether (PGME; 1-methoxy-2-propanol) (b.p.=120° C.), propylene glycol monoethyl ether (b.p.=130 to 131° C.), propylene glycol monopropyl ether (b.p.=148° C.), propylene glycol monobutyl ether (b.p.=169 to 170° C.), ethylene glycol monomethyl ether (b.p.=124 to 125° C.), and ethylene glycol monoethyl ether (b.p.=134 to 135° C.).

Preferred examples of the alkyl lactates include methyl lactate (b.p.=145° C.), ethyl lactate (b.p.=154° C.), propyl lactate (b.p.=169 to 172° C.), and butyl lactate (b.p.=185 to 187° C.).

Preferred examples of the alkyl alkoxypropionates include ethyl 3-ethoxypropionate (b.p.=170° C.), methyl 3-methoxypropionate (b.p.=144° C.), methyl 3-ethoxypropionate (b.p.=138 to 141° C.), and ethyl 3-methoxypropionate (b.p.=156 to 158° C.).

Preferred examples of the cyclic lactones include β-propiolactone (b.p.=162° C.), 3-butyrolactone (b.p.=71 to 73° C./29 mmHg), 7-butyrolactone (b.p.=204° C.), α-methyl-γ-butyrolactone (b.p.=78 to 81° C./10 mmHg), β-methyl-7-butyrolactone (b.p.=87 to 88° C./10 mmHg), 7-valerolactone (b.p.=82 to 85° C./10 mmHg), 7-caprolactone (b.p.=219° C.), 7-octanoic lactone (b.p.=234° C.), and a-hydroxy-7-butyrolactone (b.p.=133° C./10 mmHg).

Preferred examples of the monoketone compounds that may contain a ring include 2-butanone (b.p.=80° C.), 3-methylbutanone (b.p.=94 to 95° C.), pinacolone (b.p.=106° C.), 2-pentanone (b.p.=101 to 105° C.), 3-pentanone (b.p.=102° C.), 3-methyl-2-pentanone (b.p.=118° C.), 4-methyl-2-pentanone (b.p.=117 to 118° C.), 2-methyl-3-pentanone (b.p.=113° C.), 4,4-dimethyl-2-pentanone (b.p.=125 to 130° C.), 2,4-dimethyl-3-pentanone (b.p.=124° C.), 2,2,4,4-tetramethyl-3-pentanone (b.p.=152 to 153° C.), 2-hexanone (b.p.=127° C.), 3-hexanone (b.p.=123° C.), 5-methyl-2-hexanone (b.p.=145° C.), 2-heptanone (b.p.=151° C.), 3-heptanone (b.p.=146 to 148° C.), 4-heptanone (b.p.=145° C.), 2-methyl-3-heptanone (b.p.=158 to 160° C.), 5-methyl-3-heptanone (b.p.=161 to 162° C.), 2,6-dimethyl-4-heptanone (b.p.=165 to 170° C.), 2-octanone (b.p.=173° C.), 3-octanone (b.p.=167 to 168° C.), 2-nonanone (b.p.=192° C./743 mmHg), 3-nonanone (b.p.=187 to 188° C.), 5-nonanone (b.p.=186 to 187° C.), 2-decanone (b.p.=211° C.), 3-decanone (b.p.=204 to 205° C.), 4-decanone (b.p.=206 to 207° C.), 5-hexen-2-one (b.p.=128 to 129° C.), 3-penten-2-one (b.p.=121 to 124° C.), cyclopentanone (b.p.=130 to 131° C.), 2-methylcyclopentanone (b.p.=139° C.), 3-methylcyclopentanone (b.p.=145° C.), 2,2-dimethylcyclopentanone (b.p.=143-145° C.), 2,4,4-trimethylcyclopentanone (b.p.=160° C.), cyclohexanone (b.p.=157° C.), 3-methylcyclohexanone (b.p.=169 to 170° C.), 4-methylcyclohexanone (b.p.=169 to 171° C.), 4-ethylcyclohexanone (b.p.=192 to 194° C.), 2,2-dimethylcyclohexanone (b.p.=169 to 170° C.), 2,6-dimethylcyclohexanone (b.p.=174 to 176° C.), 2,2,6-trimethylcyclohexanone (b.p.=178 to 179° C.), cycloheptanone (b.p.=179° C.), 2-methylcycloheptanone (b.p.=182 to 185° C.), 3-methylcycloheptanone (b.p.=100° C./40 mmHg), and diacetone alcohol (b.p.=166° C.).

Preferred examples of the alkylene carbonates include propylene carbonate (b.p.=240° C.), vinylene carbonate (b.p.=162° C.), ethylene carbonate (b.p.=243 to 244° C./740 mmHg), and butylene carbonate (b.p.=88° C./0.8 mmHg).

Preferred examples of the alkyl alkoxyacetates include 2-methoxyethyl acetate (b.p.=145° C.), 2-ethoxyethyl acetate (b.p.=155 to 156° C.), 2-(2-ethoxyethoxy) ethyl acetate (b.p.=219° C.), 1-methoxy-2-propyl acetate (b.p.=145 to 146° C.), and 3-methoxybutyl acetate (b.p.=172° C.).

Preferred examples of the alkyl pyruvates include methyl pyruvate (b.p.=134 to 137° C.), ethyl pyruvate (b.p.=144° C.), and propyl pyruvate (b.p.=166° C.).

The solvent having a boiling point of 150° C. or more preferably contains a solvent having a hydroxyl group. A solvent having an alcoholic hydroxyl group is preferred because the solvent can well dissolve the resin (P) having the repeating unit (B) to thereby facilitate formation of a uniform film.

The solvent having a hydroxyl group and a boiling point of 150° C. or more is not particularly limited, and can be appropriately selected from the group consisting of the above-described solvents; preferred are diacetone alcohol, ethyl lactate, propyl lactate, and benzyl alcohol, and more preferred are diacetone alcohol, ethyl lactate, and propyl lactate.

The solvent having a boiling point of 150° C. or more may be only a solvent having a hydroxyl group and a boiling point of 150° C. or more, may be only a solvent not having a hydroxyl group and having a boiling point of 150° C. or more, or may be a combination of a solvent having a hydroxyl group and a boiling point of 150° C. or more and a solvent not having a hydroxyl group and having a boiling point of 150° C. or more.

The content of the solvent having a hydroxyl group and a boiling point of 150° C. or more relative to the total amount of the solvent is not particularly limited, but is 0 to 100 mass %, preferably 50 to 100 mass %, more preferably 70 to 100 mass %, and still more preferably 80 to 100 mass %.

The solvent having a boiling point of 150° C. or more is not particularly limited; preferred are diacetone alcohol, ethyl lactate, propyl lactate, benzyl alcohol, propylene glycol monomethyl ether acetate, ethyl 3-ethoxypropionate, 2-heptanone, 3-methoxybutyl acetate, and y-butyrolactone; more preferred are diacetone alcohol, ethyl lactate, propyl lactate, benzyl alcohol, propylene glycol monomethyl ether acetate, ethyl 3-ethoxypropionate, 2-heptanone, 3-methoxybutyl acetate, and γ-butyrolactone; and particularly preferred are diacetone alcohol, ethyl lactate, and γ-butyrolactone.

### Surfactant

The composition of the present invention may include a surfactant. When a surfactant is contained, use of an exposure light source having a wavelength of 250 nm or less, particularly 220 nm or less, can form, at high sensitivity and at high resolution, a pattern with less adhesiveness and less development defects.

The surfactant employed is particularly preferably a fluorine-based and/or silicone-based surfactant.

Examples of the fluorine-based and/or silicone-based surfactants include the surfactants described in [0276] of US2008/0248425A. Alternatively, also usable is EFTOP EF301 or EF303 (manufactured by Shin Akita Chemicals Corp.); Fluorad FC430, 431, or 4430 (manufactured by Sumitomo 3m Limited); MEGAFACE F171, F173, F176, F189, F113, F110, F177, F120, or R08 (manufactured by DIC Corporation); SURFLON S-382, SC101, 102, 103, 104, 105, or 106 (manufactured by Asahi Glass Co., Ltd.); Troysol S-366 (manufactured by Troy Chemical Corporation); GF-300 or GF-150 (manufactured by TOAGOSEI CO., LTD.); SURFLON S-393 (manufactured by Seimi Chemical Co., Ltd.); EFTOP EF121, EF122A, EF122B, RF122C, EF125M, EF135M, EF351, EF352, EF801, EF802, or EF601 (manufactured by JEMCO Inc.); PF636, PF656, PF6320, or PF6520 (manufactured by OMNOVA Solutions Inc.); or FTX-204G, 208G, 218G, 230G, 204D, 208D, 212D, 218D, or 222D (manufactured by NEOS COMPANY LIMITED). Note that polysiloxane polymer KP-341 (manufactured by Shin-Etsu Chemical Co., Ltd.) can also be used as the silicone-based surfactant.

In addition to the above-described publicly known surfactants, the surfactant may be synthesized using a fluoroaliphatic compound produced by the telomerization method (also referred to as the telomer method) or the oligomerization method (also referred to as the oligomer method). Specifically, a polymer including a fluoroaliphatic group derived from the fluoroaliphatic compound may be used as the surfactant. The fluoroaliphatic compound can be synthesized by, for example, the method described in JP2002-90991A.

The surfactants that are described in [0280] of US2008/0248425A and are not fluorine-based and/or silicone-based surfactants may also be used.

These surfactants may be used alone or in combination of two or more thereof.

When the composition of the present invention includes a surfactant, the content thereof relative to the total solid content of the resist composition is preferably 0.00001 to 2 mass %, more preferably 0.0001 to 2 mass %, and still more preferably 0.0005 to 1 mass %.

### Other Additives

In addition to the above-described components, the composition of the present invention may appropriately contain a carboxylic acid, a carboxylic acid onium salt, a dissolution inhibiting compound having a molecular weight of 3000 or less described in Proceeding of SPIE, 2724, 355 (1996) or the like, a dye, a plasticizer, a photosensitizer, a light absorber, an antioxidant, or the like.

In particular, the carboxylic acid can be suitably used to improve the performance. The carboxylic acid is preferably an aromatic carboxylic acid such as benzoic acid or naphthoic acid.

When the composition of the present invention includes a carboxylic acid, the content of the carboxylic acid relative to the total solid content of the composition is preferably 0.01 to 10 mass %, more preferably 0.01 to 5 mass %, still more preferably 0.01 to 3 mass %.

The composition of the present invention is, from the viewpoint of improving the resolving power, preferably used at a film thickness of 10 to 250 nm, more preferably used at a film thickness of 20 to 200 nm, and still more preferably used at a film thickness of 30 to 100 nm. Such a film thickness can be provided by setting the solid content concentration in the composition in an appropriate range to provide an appropriate viscosity, to thereby improve the coatability and the film formability.

The solid content concentration of the composition of the present invention is ordinarily 1.0 to 15 mass %, preferably 2.0 to 5.7 mass %, and more preferably 2.0 to 5.3 mass %. When the solid content concentration is set in such a range, the resist solution can be uniformly applied onto a substrate, and a resist pattern excellent in line width roughness can be formed.

The solid content concentration is a mass percentage of, relative to the total mass of the composition, the mass of the non-solvent components.

### Applications

The composition of the present invention is an actinic ray-sensitive or radiation-sensitive resin composition that reacts upon irradiation with an actinic ray or a radiation to undergo change in a property. More specifically, the composition of the present invention relates to an actinic ray-sensitive or radiation-sensitive resin composition used in a process for producing semiconductors such as ICs (integrated circuits), production of a circuit board for liquid crystal, a thermal head, or the like, production of a mold structure for imprinting, other photofabrication processes, or production of a lithographic printing plate or an acid-curable composition. The pattern formed in the present invention can be used in an etching step, an ion implantation step, a bump electrode forming step, a redistribution forming step, MEMS (Micro Electro Mechanical Systems), and the like.

### Actinic Ray-Sensitive or Radiation-Sensitive Film

The present invention also relates to an actinic ray-sensitive or radiation-sensitive film (preferably a resist film) formed from the actinic ray-sensitive or radiation-sensitive composition of the present invention. Such a film is formed by, for example, applying the composition of the present invention onto a support such as a substrate. This film preferably has a thickness of 0.02 to 0.1 m. For the method of applying it onto the substrate, it is applied onto the substrate by an appropriate coating method such as spin coating, roll coating, flow coating, dip coating, spray coating, or doctor coating; and preferred is spin coating in which the number of rotations is preferably 1,000 to 3000 rpm (rotations per minute). The coating film is pre-baked at 60 to 150° C. for 1 to 20 minutes, preferably at 80 to 120° C. for 1 to 10 minutes, to form a thin film.

For the material forming the substrate to be processed and the uppermost layer thereof, in a case of a semiconductor wafer, a silicon wafer can be used; examples of the material of the uppermost layer include Si, SiO₂, SiN, SiON, TiN, WSi, BPSG (Boron Phosphorus Silicon Glass), SOG (Spin on Glass), and organic antireflection films.

Before the formation of the actinic ray-sensitive or radiation-sensitive film, an antireflection film may be formed by application onto the substrate in advance.

The antireflection film may be an inorganic film formed of titanium, titanium dioxide, titanium nitride, chromium oxide, carbon, amorphous silicon, or the like or an organic film formed of a light absorber and a polymer material. Other organic antireflection films that can be employed are commercially available organic antireflection films such as DUV30 series and DUV-40 series manufactured by Brewer Science, Inc, and AR-2, AR-3, and AR-5 manufactured by Shipley Company L. L. C.

### Pattern Forming Method

The present invention also relates to a pattern forming method including an actinic ray-sensitive or radiation-sensitive film forming step of forming an actinic ray-sensitive or radiation-sensitive film from the actinic ray-sensitive or radiation-sensitive resin composition of the present invention, an exposure step of exposing the actinic ray-sensitive or radiation-sensitive film, and a development step of developing the exposed actinic ray-sensitive or radiation-sensitive film using a developer.

In the present invention, the exposure is preferably performed using an electron beam, an ArF excimer laser, or extreme ultraviolet rays, more preferably performed using an electron beam or extreme ultraviolet rays, and still more preferably performed using an electron beam. That is, in the exposure step, an electron beam is preferably used as the exposure light source.

In the production of a precision integrated circuit element or the like, the exposure (pattern forming step) on the actinic ray-sensitive or radiation-sensitive film is preferably performed by firstly irradiating patternwise the resist film with an ArF excimer laser, an electron beam, or extreme ultraviolet rays (EUV). The exposure is performed at an exposure dose of, in the case of an ArF excimer laser, about 1 to about 100 mJ/cm², and preferably about 20 to about 60 mJ/cm²; in the case of an electron beam, about 0.1 to about 20 μC/cm², and preferably about 3 to about 10 μC/cm²; and, in the case of extreme ultraviolet rays, about 0.1 to about 20 mJ/cm², and preferably about 3 to about 15 mJ/cm².

Subsequently, post-exposure baking is performed on a hot plate preferably at 60 to 150° C. for 5 seconds to 20 minutes, more preferably at 80 to 120° C. for 15 seconds to 10 minutes, and still more preferably at 80 to 120° C. for 1 to 10 minutes, and subsequently, development, rinsing, and drying are performed to form a pattern. The post-exposure baking is appropriately adjusted depending on the acid decomposability of the repeating unit having an acid decomposable group in the resin (P). When the acid decomposability is low, the post-exposure baking is also preferably performed at a temperature of 110° C. or more and for a baking time of 45 seconds or more.

The developer is appropriately selected, but is preferably an alkali developer (typically an alkaline aqueous solution) or a developer containing an organic solvent (also referred to as an organic-based developer). When the developer is an alkaline aqueous solution, development is carried out with a 0.1 to 5 mass %, preferably 2 to 3 mass %, alkaline aqueous solution of tetramethylammonium hydroxide (TMAH), tetrabutylammonium hydroxide (TBAH), or the like for 0.1 to 3 minutes, preferably 0.5 to 2 minutes, by a standard method such as a dipping method, a puddling method, or a spraying method. To the alkali developer, an appropriate amount of an alcohol and/or a surfactant may be added. Thus, in the formation of a negative-type pattern, the film in the unexposed regions dissolves and the exposed regions are less likely to dissolve in the developer, or, in the formation of a positive-type pattern, the film in the exposed regions dissolves and the film in the unexposed regions is less likely to dissolve in the developer, so that a desired pattern is formed on the substrate.

In the case where the pattern forming method of the present invention has a step of performing development using an alkali developer, examples of the alkali developer include alkaline aqueous solutions of inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcoholamines such as dimethylethanolamine and triethanolamine; tetraalkylammonium hydroxides such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide; quaternary ammonium salts such as trimethylphenylammonium hydroxide, trimethylbenzylammonium hydroxide, triethylbenzylammonium hydroxide, and dimethylbis(2-hydroxyethyl) ammonium hydroxide; and cyclic amines such as pyrrole and piperidine.

Further, such an alkaline aqueous solution to which an appropriate amount of an alcohol or a surfactant is added may be used.

The alkali developer has an alkali concentration of ordinarily 0.1 to 20 mass %.

The alkali developer has a pH of ordinarily 10.0 to 15.0.

In particular, a 2.38 mass % aqueous solution of tetramethylammonium hydroxide is desirable.

As the rinsing solution in the rinsing treatment performed after the alkaline development, pure water can be used and an appropriate amount of a surfactant can be added thereto.

After the developing treatment or the rinsing treatment, a treatment of removing, using a supercritical fluid, the developer or the rinsing solution adhering to the pattern can be performed.

In a case where the pattern forming method of the present invention has a step of performing development using a developer containing an organic solvent, the developer in the step (hereinafter, also referred to as the organic-based developer) can be a polar solvent and hydrocarbon-based solvent such as a ketone-based solvent, an ester-based solvent, an alcohol-based solvent, an amide-based solvent, or an ether-based solvent.

In the present invention, the ester-based solvent is a solvent having an ester group in the molecule; the ketone-based solvent is a solvent having a ketone group in the molecule; the alcohol-based solvent is a solvent having an alcoholic hydroxyl group in the molecule; the amide-based solvent is a solvent having an amide group in the molecule; and the ether-based solvent is a solvent having an ether bond in the molecule. These include a solvent having a plurality of such functional group species in a single molecule; in this case, it is regarded as belonging to any solvent species including the functional groups that the solvent has. For example, diethylene glycol monomethyl ether belongs to, of the above-described classifications, both the alcohol-based solvent and the ether-based solvent. The hydrocarbon-based solvent is a hydrocarbon solvent not having a substituent.

In particular, the developer is preferably a developer containing at least one solvent selected from the group consisting of a ketone-based solvent, an ester-based solvent, an alcohol-based solvent, and an ether-based solvent.

The developer is, from the viewpoint of achieving suppression of the swelling of the actinic ray-sensitive or radiation-sensitive film, preferably an ester-based solvent having 7 or more (preferably 7 to 14, more preferably 7 to 12, and still more preferably 7 to 10) carbon atoms and 2 or less heteroatoms.

The heteroatom of the ester-based solvent is an atom other than a carbon atom and a hydrogen atom, and examples thereof include an oxygen atom, a nitrogen atom, and a sulfur atom. The number of heteroatoms is preferably 2 or less.

Preferred examples of the ester-based solvent having 7 or more carbon atoms and 2 or less heteroatoms include amyl acetate, isoamyl acetate, 2-methylbutyl acetate, 1-methylbutyl acetate, hexyl acetate, pentyl propionate, hexyl propionate, heptyl propionate, butyl butanoate, and isobutyl isobutanoate; and particularly preferred are isoamyl acetate and isobutyl isobutanoate.

For the developer, instead of the above-described ester-based solvent having 7 or more carbon atoms and 2 or less heteroatoms, a mixed solvent of the ester-based solvent and the hydrocarbon-based solvent, or a mixed solvent of the ketone-based solvent and the hydrocarbon solvent may be used. Also in this case, swelling of the resist film is effectively suppressed.

In the case where an ester-based solvent and a hydrocarbon-based solvent are used in combination, the ester-based solvent is preferably isoamyl acetate. The hydrocarbon-based solvent is, from the viewpoint of adjusting the solubility of the resist film, preferably a saturated hydrocarbon solvent (for example, octane, nonane, decane, dodecane, undecane, or hexadecane).

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, 2,5-dimethyl-4-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, and propylene carbonate; and particularly preferred are diisobutyl ketone and 2,5-dimethyl-4-hexanone.

Examples of the ester-based solvent include methyl acetate, butyl acetate, ethyl acetate, isopropyl acetate, pentyl acetate, isoamyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxy propionate, 3-methoxybutyl acetate, 3-methyl-3-methoxybutyl acetate, methyl formate, ethyl formate, butyl formate, propyl formate, ethyl lactate, butyl lactate, propyl lactate, butyl butyrate, and methyl 2-hydroxyisobutyrate.

Examples of the alcohol-based solvent include alcohols such as methyl alcohol, ethyl alcohol, n-propyl alcohol, isopropyl alcohol, n-butyl alcohol, sec-butyl alcohol, 4-methyl-2-pentanol, tert-butyl alcohol, isobutyl alcohol, n-hexyl alcohol, n-heptyl alcohol, n-octyl alcohol, and n-decanol; glycol-based solvents such as ethylene glycol, diethylene glycol, and triethylene glycol; and glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethylbutanol.

Examples of the ether-based solvent include, in addition to the glycol ether-based solvents, anisole, dioxane, and tetrahydrofuran.

Examples of the amide-based solvent include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include aromatic hydrocarbon-based solvents such as toluene and xylene, and aliphatic hydrocarbon-based solvents such as pentane, hexane, octane, decane, and undecane.

Note that such an aliphatic hydrocarbon-based solvent, which is a hydrocarbon-based solvent, may be a mixture of compounds having the same number of carbon atoms but having different structures. For example, in the case of using, as the aliphatic hydrocarbon-based solvent, decane, compounds having the same number of carbon atoms but having different structures such as 2-methylnonane, 2,2-dimethyloctane, 4-ethyloctane, or isooctane may be included in the aliphatic hydrocarbon-based solvent.

For the compounds having the same number of carbon atoms but having different structures, a single compound alone may be included, or a plurality of compounds may be included as described above.

For the above-described solvents, two or more thereof may be mixed together, or such a solvent may be mixed with a solvent other than those described above or water and used. Note that, in order to fully provide advantages of the present invention, the moisture content of the entire developer is preferably less than 10 mass %, and, more preferably, the developer substantially does not contain water.

The concentration of the organic solvent (in the case of a mixture of a plurality of solvents, the total concentration thereof) in the organic-based developer is preferably 50 mass % or more, more preferably 50 to 100 mass %, still more preferably 85 to 100 mass %, yet more preferably 90 to 100 mass %, and particularly preferably 95 to 100 mass %. Most preferably, it consists essentially of an organic solvent. Note that the case where it consists essentially of an organic solvent includes the cases where it contains a small amount of a surfactant, an antioxidant, a stabilizer, an anti-foaming agent, or the like.

In particular, the organic-based developer is preferably a developer containing at least one organic solvent selected from the group consisting of a ketone-based solvent, an ester-based solvent, an alcohol-based solvent, an amide-based solvent, and an ether-based solvent.

The vapor pressure of the organic-based developer at 20° C. is preferably 5 kPa or less, more preferably 3 kPa or less, and particularly preferably 2 kPa or less. When the vapor pressure of the organic-based developer is set to 5 kPa or less, the evaporation of the developer on the substrate or in the developing cup is suppressed, the wafer in-plane temperature uniformity is improved, and as a result, the wafer in-plane dimensional uniformity is improved.

Specific examples having a vapor pressure of 5 kPa or less include ketone-based solvents such as 1-octanone, 2-octanone, 1-nonanone, 2-nonanone, 2-heptanone (methyl amyl ketone), 4-heptanone, 2-hexanone, diisobutyl ketone, cyclohexanone, methylcyclohexanone, phenylacetone, and methyl isobutyl ketone; ester-based solvents such as butyl acetate, pentyl acetate, isoamyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate, and propyl lactate; alcohol-based solvents such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, diethylene glycol, and triethylene glycol; glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethylbutanol; ether-based solvents such as tetrahydrofuran; amide-based solvents such as N-methyl-2-pyrrolidone, N,N-dimethylacetamide, and N,N-dimethylformamide; aromatic hydrocarbon-based solvents such as toluene and xylene; and aliphatic hydrocarbon-based solvents such as octane and decane.

Specific examples having a vapor pressure of 2 kPa or less, which is a particularly preferred range, include ketone-based solvents such as 1-octanone, 2-octanone, 1-nonanone, 2-nonanone, 2-heptanone, 4-heptanone, 2-hexanone, diisobutyl ketone, cyclohexanone, methylcyclohexanone, and phenylacetone; ester-based solvents such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate, and propyl lactate; alcohol-based solvents such as n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, diethylene glycol, and triethylene glycol; glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethylbutanol; amide-based solvents such as N-methyl-2-pyrrolidone, N,N-dimethylacetamide, and N,N-dimethylformamide; aromatic hydrocarbon-based solvents such as xylene; and aliphatic hydrocarbon-based solvents such as octane, decane, and undecane.

The organic-based developer may include a basic compound. Specific examples and preferred examples of the basic compound that the developer used in the present invention can include are the same as those in the basic compound that the above-described actinic ray-sensitive or radiation-sensitive composition can include.

To the organic-based developer, an appropriate amount of a surfactant can be added as needed.

The surfactant is not particularly limited, and for example, an ionic or nonionic fluorine-based and/or silicone-based surfactant can be used. Examples of such fluorine-based and/or silicone-based surfactants include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H7-230165A), JP1996-62834A(JP-H8-62834A), JP1997-54432A(JP-H9-54432A), JP1997-5988A (JP-H9-5988A), U.S. Pat. Nos. 5,405,720A, 5,360,692A, 5,529,881A, 5,296,330A, 5,436,098A, 5,576,143A, 5,294,511A, and 5,824,451A; preferred are nonionic surfactants. Such a nonionic surfactant is not particularly limited, but more preferably a fluorine-based surfactant or a silicone-based surfactant is used.

The amount of the surfactant used relative to the total amount of the developer is preferably 0.0001 to 2 mass %, more preferably 0.0001 to 1 mass %, and particularly preferably 0.0001 to 0.1 mass %.

The developing method that can be applied is, for example, a method of immersing the substrate in a tank filled with the developer for a certain period of time (dipping method), a method of puddling the substrate surface with the developer by surface tension and leaving the developer at rest for a certain period of time to perform development (puddling method), a method of spraying the developer on the substrate surface (spraying method), or a method of continuously ejecting the developer while the substrate rotating at a certain rate is scanned with a developer ejection nozzle at a certain rate (dynamic dispensing method).

In the case where the above-described various developing methods include a step of ejecting the developer from a developing nozzle of a developing apparatus toward a resist film, the ejection pressure of the developer ejected (flow rate per unit area of the developer ejected) is preferably 2 mL/sec/mm² or less, more preferably 1.5 mL/sec/mm² or less, and still more preferably 1 mL/sec/mm² or less. The lower limit of the flow rate is not particularly limited, but is preferably 0.2 mL/sec/mm² or more from the viewpoint of throughput.

When the ejection pressure of the developer ejected is set to such a range, defects of the pattern derived from the resist scum after development can be markedly reduced.

This mechanism has not been specifically clarified; however, inferentially, the ejection pressure is set to such a range, so that the pressure applied to the resist film by the developer is reduced, which inferentially suppresses unintended wear or collapse of the resist film and pattern.

Note that the ejection pressure of the developer (mL/sec/mm²) is a value at the outlet of the developing nozzle in the developing apparatus.

Examples of the method of adjusting the ejection pressure of the developer include a method of adjusting the ejection pressure using a pump or the like, and a method of changing the ejection pressure by adjusting the pressure on the basis by supply from a pressure tank.

After the step of performing development using the developer including an organic solvent, a step of stopping the development while the developer is replaced with another solvent may be performed.

After the step of performing development using the developer including the organic solvent, a step of performing cleaning using a rinsing solution may be included, but from the viewpoint of throughput (productivity), the amount of rinsing solution used, and the like, the step of performing cleaning using a rinsing solution may not be included.

The rinsing solution used in the rinsing step after the step of performing development using a developer including an organic solvent is not particularly limited as long as it does not dissolve the resist pattern, and a solution including a general organic solvent can be used. As the rinsing solution, a rinsing solution containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent include the same as those described in the developer including an organic solvent; and particularly preferred are butyl acetate and methylisobutylcarbinol.

More preferably, the step of performing development using the developer including an organic solvent is followed by a step of performing cleaning using a rinsing solution containing at least one organic solvent selected from the group consisting of an ester-based solvent, an alcohol-based solvent, and a hydrocarbon-based solvent, and still more preferably followed by a step of performing cleaning using a rinsing solution containing an alcohol-based solvent or a hydrocarbon-based solvent.

The organic solvent included in the rinsing solution is also preferably, of organic solvents, a hydrocarbon-based solvent, and more preferably an aliphatic hydrocarbon-based solvent. The aliphatic hydrocarbon-based solvent used in the rinsing solution is preferably, from the viewpoint of providing its effect further improved, an aliphatic hydrocarbon-based solvent having 5 or more carbon atoms (for example, pentane, hexane, octane, decane, undecane, dodecane, or hexadecane), preferably an aliphatic hydrocarbon-based solvent having 8 or more carbon atoms, and more preferably an aliphatic hydrocarbon-based solvent having 10 or more carbon atoms.

The upper limit value of the number of carbon atoms of the aliphatic hydrocarbon-based solvent is not particularly limited, and is, for example, 16 or less, preferably 14 or less, and more preferably 12 or less.

Of the above-described aliphatic hydrocarbon-based solvents, particularly preferred are decane, undecane, and dodecane; and most preferred is undecane.

In such a case of using, as the organic solvent included in the rinsing solution, a hydrocarbon-based solvent (in particular, an aliphatic hydrocarbon-based solvent), the developer that has slightly permeated the resist film after development is washed away, and the effects of further suppressing swelling and suppressing pattern collapse are further exerted.

Of the above-described components, two or more thereof may be mixed together, or a component may be mixed with an organic solvent other than those described above and used.

The moisture content in the rinsing solution is preferably 10 mass % or less, more preferably 5 mass % or less, and particularly preferably 3 mass % or less. When the moisture content is set to 10 mass % or less, good development characteristics can be provided.

The rinsing solution used after the step of performing development using the developer including an organic solvent preferably has a vapor pressure at 20° C. of 0.05 kPa or more and 5 kPa or less, more preferably 0.1 kPa or more and 5 kPa or less, and most preferably 0.12 kPa or more and 3 kPa or less. When the vapor pressure of the rinsing solution is set to 0.05 kPa or more and 5 kPa or less, the wafer in-plane temperature uniformity is improved, and further, the swelling caused by permeation of the rinsing solution is suppressed, and the wafer in-plane dimensional uniformity is improved.

Such a rinsing solution to which an appropriate amount of a surfactant is added can be used.

In the rinsing step, the wafer having been subjected to development using the developer including an organic solvent is subjected to a cleaning treatment using the above-described rinsing solution including an organic solvent. The method of performing the cleaning treatment is not particularly limited, and for example, a method of continuously ejecting the rinsing solution onto the substrate rotating at a constant rate (spin coating method), a method of immersing the substrate in a tank filled with the rinsing solution for a certain period of time (dipping method), a method of spraying the rinsing solution on the substrate surface (spraying method), or the like can be applied; of these, preferably, the spin coating method is used to perform the cleaning treatment, and the cleaned substrate is rotated at a rotational rate of 2000 rpm to 4000 rpm to remove the rinsing solution from the substrate. After the rinsing step, a heating step (PostBake) is preferably included. The baking results in removal of the developer and the rinsing solution remaining between the pattern portions and inside the pattern. The heating step after the rinsing step is carried out at ordinarily 40 to 160° C., preferably 70 to 95° C., for ordinarily 10 seconds to 3 minutes, preferably 30 seconds to 90 seconds.

In the case of not having the step of performing cleaning using a rinsing solution, for example, the developing treatment method described in paragraphs [0014] to [0086] of JP2015-216403A can be employed.

The pattern forming method of the present invention may have a development step using an organic-based developer and a development step using an alkali developer. The development using an organic-based developer results in removal of regions subjected to a low exposure intensity, and the development using an alkali developer also results in removal of regions subjected to a high exposure intensity. Such a multiple developing process in which developments are performed a plurality of times is performed, so that only regions subjected to an intermediate exposure intensity are not dissolved to form a pattern, which results in formation of a finer pattern (by the same mechanism as in paragraph [0077] of JP2008-292975A).

The actinic ray-sensitive or radiation-sensitive composition in the present invention and various materials used in the pattern forming method of the present invention (for example, a developer, a rinsing solution, a composition for forming an antireflection film, and a composition for forming a topcoat) preferably do not include impurities such as metals, metal salts including halogens, acids, alkalis, and components including sulfur atoms or phosphorus atoms. Examples of the impurities including metal atoms include Na, K, Ca, Fe, Cu, Mn, Mg, Al, Cr, Ni, Zn, Ag, Sn, Pb, Li, and salts of these.

The content of the impurities included in the materials is preferably 1 ppm or less, more preferably 1 ppb (parts per billion) or less, still more preferably 100 ppt (parts per trillion) or less, particularly preferably 10 ppt or less; and most preferably the impurities are substantially not included (the content is equal to or less than the detection limit of the measurement apparatus).

The method for removing impurities such as metals from various materials is, for example, filtration using a filter. For the filter pore size, the pore size is preferably 10 nm or less, more preferably 5 nm or less, and still more preferably 3 nm or less. For the material of the filter, a filter formed of polytetrafluoroethylene, polyethylene, or nylon is preferred. The filter may be a composite material that is a combination of such a material and ion exchange media. The filter that is washed with an organic solvent in advance may be used. In the filter filtration step, a plurality of filters connected in series or in parallel may be used. In the case of using a plurality of filters, filters that are different in pore sizes and/or materials may be used in combination. Various materials may be filtered a plurality of times, and the step of performing filtration a plurality of times may be a circulation filtration step.

Examples of the method of reducing impurities such as metals included in various materials include a method of selecting raw materials having a low metal content as raw materials for constituting various materials, a method of filtering raw materials for constituting various materials through a filter, and a method of performing distillation under a condition in which contamination is suppressed as much as possible by, for example, lining the inside of an apparatus with TEFLON (registered trademark). Preferred conditions for the filter filtration of the raw materials for constituting various materials are the same as the above-described conditions.

In addition to the filter filtration, removal of impurities using an adsorbent may be performed, and the filter filtration and the adsorbent may be used in combination. For the adsorbent, publicly known adsorbents can be used, and, for example, an inorganic adsorbent such as silica gel or zeolite, or an organic adsorbent such as activated carbon can be used.

Examples of the method of reducing impurities such as metals included in the organic solvent (also referred to as “organic treatment solution”) that can be used in the developer and rinsing solution of the present invention include a method of selecting raw materials having a low metal content as raw materials for constituting various materials, a method of filtering raw materials for constituting various materials through a filter, and a method of performing distillation under a condition in which contamination is suppressed as much as possible by, for example, lining the inside of an apparatus with TEFLON (registered trademark). Preferred conditions for the filter filtration of the raw materials for constituting various materials are the same as the above-described conditions.

In addition to the filter filtration, removal of impurities using an adsorbent may be performed, or the filter filtration and the adsorbent may be used in combination. For the adsorbent, publicly known adsorbents can be used, and, for example, an inorganic adsorbent such as silica gel or zeolite, or an organic adsorbent such as activated carbon can be used.

A conductive compound may be added to the organic treatment solution of the present invention in order to prevent failures of chemical pipes and various parts (such as filters, 0-rings, and tubes) due to electrostatic charging and subsequent electrostatic discharge. The conductive compound is not particularly limited, and is, for example, methanol. The addition amount is not particularly limited, but is, from the viewpoint of maintaining preferable development characteristics, preferably 10 mass % or less, and more preferably 5 mass % or less. For members of the chemical pipes, various pipes formed of SUS (stainless steel), or coated with polyethylene, polypropylene, or a fluororesin (such as polytetrafluoroethylene or a perfluoroalkoxy resin) subjected to an antistatic treatment can be used. Similarly, for the filters and the O—rings, polyethylene, polypropylene, or a fluororesin (such as polytetrafluoroethylene or a perfluoroalkoxy resin) subjected to an antistatic treatment can be used.

Note that, in general, the developer and the rinsing solution after use are collected through a pipe into a waste liquid tank. In this case, when a hydrocarbon-based solvent is used as the rinsing solution, in order to prevent eduction of the resist dissolved in the developer and adhesion to the back surface of the wafer, the side surface of the pipe, and the like, a method of passing the solvent in which the resist is dissolvable through the pipe again may be used. Examples of the method of passing through the pipe include a method of, after washing with the rinsing solution, washing the back surface of the substrate, the side surface, and the like with the solvent in which the resist is dissolvable to pass the solvent, and a method of passing the solvent in which the resist is dissolvable through the pipe without bringing the solvent into contact with the resist.

The solvent that is passed through the pipe is not particularly limited as long as it is a solvent in which the resist is dissolvable, and examples thereof include the above-described organic solvents and include propylene glycol monomethyl ether acetate (PGMEA), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, ethylene glycol monoethyl ether acetate, propylene glycol monomethyl ether (PGME), propylene glycol monoethyl ether, propylene glycol monopropyl ether, propylene glycol monobutyl ether, ethylene glycol monomethyl ether, ethylene glycol monoethyl ether, 2-heptanone, ethyl lactate, 1-propanol, and acetone. Of these, preferably used are PGMEA, PGME, and cyclohexanone. Method for producing electronic device

In addition, the present invention also relates to a method for producing an electronic device, the method including the above-described pattern forming method. The electronic device produced by the method for producing an electronic device of the present invention is suitably mounted on electric and electronic apparatuses (for example, home appliances, OA (Office Automation)—related apparatuses, media-related apparatuses, optical apparatuses, and communication apparatuses).

### EXAMPLES

Hereinafter, the present invention will be described further in detail with reference to Examples. The materials, usage amounts, ratios, details of treatments, and procedures of treatments described in the following Examples can be appropriately changed without departing from the spirit and scope of the present invention. Therefore, the scope of the present invention should not be construed as being limited to the following Examples.

Various components used in the resist compositions of Examples and Comparative Examples will be described below.

### Resin (P)

### Synthesis Example 1: Synthesis of Monomer (b-1)

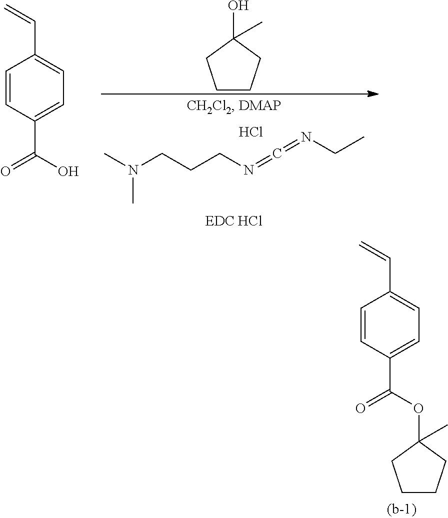

4-Vinylbenzoic acid (50.0 g, 337 mmol), 1-methylcyclopentanol (40.6 g, 405 mmol), 500 ml of methylene chloride, and 4-dimethylaminopyridine (45.3 g, 371 mmol) were charged, and cooled to −10° C. At −10° C., 1-(3-dimethylaminopropyl)-3-ethylcarbodiimide hydrochloride (71.1 g, 371 mmol) was added, and warming to room temperature (23° C.) was performed and subsequently stirring for 15 hours was performed. The organic phase was washed with pure water, and subsequently the solvent was distilled off under a reduced pressure. The residue was purified by silica gel column chromatography (eluant: ethyl acetate/n-hexane=3/97) to provide 60 g of a monomer (b-1). The compound was identified by ESI-MS.

$$MS ‐ ESI ( positive ) m / z = {229.1 [ M ]}^{+}$$

### Synthesis Example 2: Synthesis of Monomer (b-13)

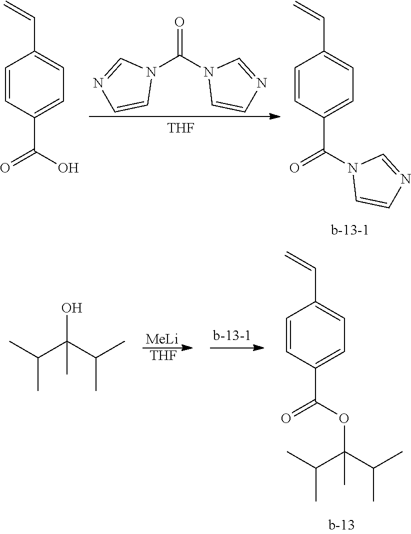

### Synthesis of Intermediate (b-13-1)

4-Vinylbenzoic acid (2.00 g, 13.5 mmol) was dissolved in 10 mL of THF, 1,1′-carbonyldiimidazole (2.23 g, 13.8 mmol) was added, and subsequently stirring was performed at room temperature for 2 hours to provide a THE solution of (b-13-1) (about 14 mL). This intermediate (b-13-1) solution was used for the subsequent reaction without further purification. Synthesis of monomer (b-13)

2,3,4-Trimethylpentanol (5.46 g, 41.9 mmol) and 25 mL of tetrahydrofuran were mixed together and cooled to −78° C. under a nitrogen atmosphere. Methyl lithium (1.4 M cyclopentyl methyl ether solution) (28.9 ml (40 mmol)) was added dropwise, and stirring was further performed at room temperature for 1 hour. To the reaction solution cooled to −10° C., the THF solution of the intermediate (b-13-1) (about 14 mL) was added dropwise. After stirring at 60° C. for 1 hour, 100 mL of n-hexane and 100 mL of distillated water were added, and extraction procedures were performed. The solvent of the organic layer was distilled off under a reduced pressure. The residue was purified by silica gel column chromatography (eluant: ethyl acetate/n-hexane=3/97) to provide 2.5 g of a monomer (b-13). The compound was identified by ESI-MS.

$$MS ‐ ESI ( positive ) m / z = {259.2 [ M ]}^{+}$$

### Synthesis Example 3: Synthesis of Monomer (c-1)

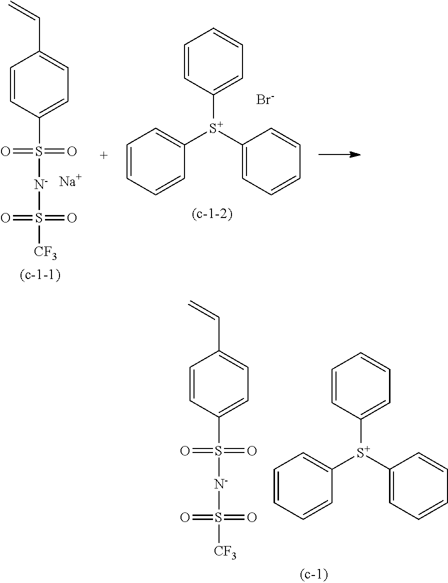 [SMILES: C=Cc1ccc(S(=O)(=O)[N-]S(=O)(=O)C(F)(F)F)cc1 ; [Na+] ; c1ccc([S+](c2ccccc2)c2ccccc2)cc1 ; [Br-] ; C=Cc1ccc(S(=O)(=O)[N-]S(=O)(=O)C(F)(F)F)cc1 ; c1ccc([S+](c2ccccc2)c2ccccc2)cc1]

The compound (c-1-1) (10.0 g, 29.67 mmol), the compound (c-1-2) (triphenylsulfonium bromide) (10.6 g, 31.1 mmol), 150 g of methylene chloride, and 100 g of pure water were charged, and stirred at room temperature for 3 hours. The organic phase was washed with pure water; subsequently, the solvent was distilled off under a reduced pressure, and isopropyl ether was used to cause azeotropy. The resultant crude product was recrystallized from ethyl acetate/isopropyl ether, and dried in a vacuum to provide a compound (c-1) (8.56 g, 14.8 mmol). The compound was identified by ESI-MS.

$$MS ‐ ESI ( positive ) m / z = {263.1 [ M ]}^{+}$$

$$MS ‐ ESI ( negative ) m / z = {314. [ M ]}^{+}$$

### Synthesis Example 4: Synthesis of Monomer (c-2)

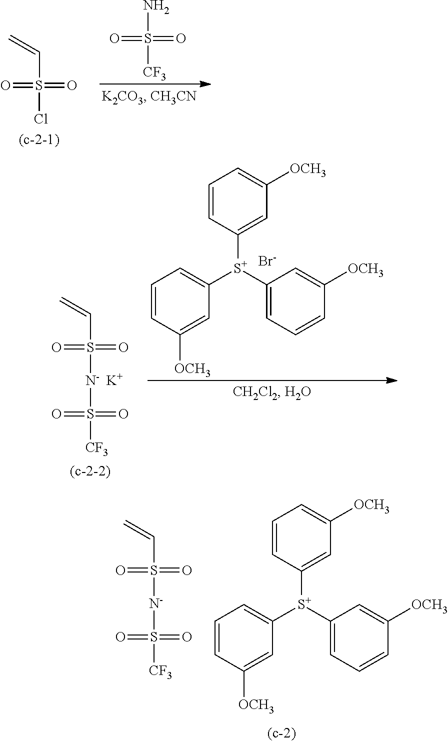

(c-2) is synthesized in accordance with the method described in Org. Lett. 2010, 12, 2.

The compound (c-2-1) (12.7 g, 100 mmol), trifluoromethanesulfonamide (14.9 g, 100 mmol), potassium carbonate (27.6 g, 200 mmol), and 200 ml of acetonitrile were charged, and caused to react under reflux at the boiling point for 3 hours in a nitrogen atmosphere. Acetonitrile was distilled off from the reaction mixture; concentration was performed, 400 ml of acetone was added, and stirring was performed. The unwanted substances were removed by filtration and the acetone solution was concentrated to provide 25 g of a crude crystal (c-2-2). Tris(3-methoxyphenyl)sulfonium bromide (43.3 g, 100 mmol), 300 g of methylene chloride, and 150 g of pure water were charged and stirred at room temperature for 3 hours. The organic phase was washed with pure water; subsequently, the solvent was distilled off under a reduced pressure, and isopropyl ether was used to cause azeotropy. The resultant crude product was recrystallized from ethyl acetate/isopropyl ether, and dried in a vacuum to provide a monomer (c-2) (24.8 g, 41.9 mmol). The compound was identified by ESI-MS.

$$MS ‐ ESI ( positive ) m / z = {353.1 [ M ]}^{+}$$

$$MS ‐ ESI ( negative ) m / z = {238. [ M ]}^{+}$$

### Synthesis Example 5: Synthesis of Resin (A-1)

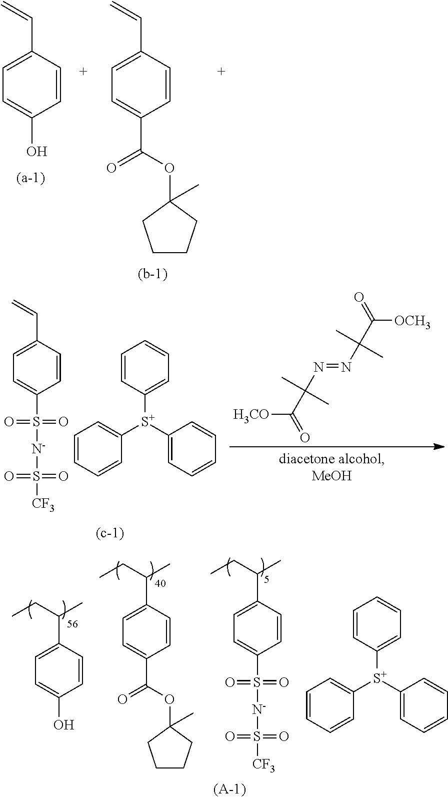

(a-1), (b-1), and (c-1) were employed as monomers and the monomers were mixed together in a molar ratio of (a-1):(b-1):(c-1)=50/45/5; a mixed solvent of diacetone alcohol:methanol=4:3 was added so as to provide a solution having a monomer concentration of 30 mass %, and dimethyl-2,2′-azobis(2-methylpropionate) serving as an initiator was added in an amount of 12 mol %, to prepare a monomer solution. Under a nitrogen atmosphere, diacetone alcohol in an amount of 0.1 times by mass the monomer solution was heated to 75° C., the monomer solution was added dropwise over 2 hours, and subsequently a reaction was caused at 75° C. for 2 hours. The resultant resin solution was added dropwise to a mixed solvent of ethyl acetate:n-heptane=1:9 to cause precipitation of the resin; the resin was filtered, and collected. The collected resin was dissolved in diacetone alcohol, and added dropwise to water to reprecipitate the resin; the resin was filtered, collected, and subsequently dried in a vacuum to provide a resin (A-1) in a yield of 46%.

For resins A-2 to A-48, resins synthesized by the same method as described above were employed. Table 1 describes the types and contents (content ratios (mol %)) of repeating units, weight-average molecular weight (Mw), and dispersity (Mw/Mn).

In Table 1, repeating units (b-1) to (b-35) described in Repeating unit 2 and corresponding to the repeating unit (A) are respectively repeating units derived from raw material monomers (b-1) to (b-35) described later.

For resins A-1 to A-48, the weight-average molecular weight (Mw) and the dispersity (Mw/Mn) were measured by GPC (carrier: tetrahydrofuran (THF)) (in terms of polystyrene). The ratios of the repeating units were measured by ¹³C-NMR (nuclear magnetic resonance).

TABLE 1

| | | | | | | Composition ratio | Weight-average | |
|---|---|---|---|---|---|---|---|---|
| | Repeating | Repeating | Repeating | Repeating | Repeating | (molar ratio) | molecular | |
| Resin | unit 1 | unit 2 | unit 3 | unit 4 | unit 5 | from the left | weight | Dispersity |
| A-1 | a-1 | b-1 | c-1 | | | 55/40/5 | 7382 | 1.71 |
| A-2 | a-1 | b-1 | c-2 | | | 60/34/6 | 8809 | 1.42 |
| A-3 | a-2 | b-2 | c-3 | | e-1 | 45/30/12/13 | 5891 | 1.82 |
| A-4 | a-3 | b-3 | c-4 | d-1 | | 45/35/3/17 | 9626 | 1.69 |
| A-5 | a-4 | b-4 | c-5 | | | 49/40/11 | 7516 | 1.55 |
| A-6 | a-5 | b-5 | c-6 | | e-4 | 61/33/4/2 | 7773 | 1.56 |
| A-7 | a-6 | b-6 | c-7 | d-4 | | 51/42/3/4 | 12547 | 1.62 |
| A-8 | a-7 | b-7 | c-8 | | | 55/40/5 | 9517 | 1.56 |
| A-9 | a-8 | b-8 | c-9 | d-6 | e-7 | 60/24/6/4/6 | 9808 | 1.8 |
| A-10 | a-9 | b-10 | c-10 | d-7 | e-8 | 43/38/4/12/3 | 12679 | 1.47 |
| A-11 | a-11 | b-11 | c-11 | | | 57/40/3 | 12086 | 1.59 |
| A-12 | a-1 | b-12 | c-12 | d-9 | e-10 | 33/41/6/14/6 | 9832 | 1.84 |
| A-13 | a-2 | b-13 | c-13 | | | 54/37/9 | 11097 | 1.76 |
| A-14 | a-3 | b-14 | c-14 | d-11 | | 38/44/12/6 | 11094 | 1.51 |
| A-15 | a-1 | b-15 | c-15 | | | 66/31/3 | 5922 | 1.58 |
| A-16 | a-1 | b-16 | c-16 | | | 43/44/13 | 12923 | 1.89 |
| A-17 | a-1 | b-17 | c-17 | d-2 | e-2 | 43/29/8/17/3 | 9511 | 1.56 |
| A-18 | a-4 | b-18 | c-18 | | | 55/39/6 | 8580 | 1.57 |
| A-19 | a-1 | b-19 | c-1 | | | 51/42/7 | 11456 | 1.87 |
| A-20 | a-2 | b-20 | c-2 | d-3 | e-3 | 50/31/6/4/9 | 7331 | 1.71 |
| A-21 | a-3 | b-21 | c-3 | | | 48/43/9 | 8968 | 1.7 |
| A-22 | a-1 | b-22 | c-4 | | | 58/38/4 | 10694 | 1.76 |
| A-23 | a-2 | b-23 | c-5 | d-5 | | 54/38/3/5 | 8884 | 1.5 |
| A-24 | a-9 | b-24 | c-6 | | | 55/40/5 | 9179 | 1.82 |
| A-25 | a-12 | b-25 | c-7 | | | 60/37/3 | 10609 | 1.47 |
| A-26 | a-1 | b-26 | c-8 | | | 55/40/5 | 6750 | 1.89 |
| A-27 | a-9 | b-27 | c-9 | d-8 | | 70/20/3/7 | 10969 | 1.81 |
| A-28 | a-1 | b-28 | c-10 | | | 60/36/4 | 9820 | 1.52 |
| A-29 | a-9 | b-29 | c-11 | | e-11 | 55/32/8/5 | 8132 | 1.4 |
| A-30 | a-1 | b-30 | c-12 | | | 58/35/7 | 8609 | 1.44 |
| A-31 | a-11 | b-31 | c-13 | | e-9 | 67/29/2/2 | 7210 | 1.73 |
| A-32 | a-3 | b-32 | c-14 | | | 64/40/6 | 11596 | 1.63 |
| A-33 | a-4 | b-33 | c-15 | d-12 | | 63/20/11/6 | 7990 | 1.55 |
| A-34 | a-10 | b-34 | c-16 | | | 55/41/4 | 9630 | 1.52 |
| A-35 | a-7 | b-35 | c-17 | d-10 | | 59/30/7/4 | 6140 | 1.55 |
| A-36 | a-1 | b-9 | c-18 | | | 63/33/4 | 7436 | 1.7 |
| A-37 | a-4 | b-5 | c-5 | | | 59/35/6 | 8009 | 1.58 |
| A-38 | a-1 | b-1 | c-4 | | | 58/38/4 | 6207 | 1.61 |
| A-39 | a-4 | b-27 | c-4 | | e-6 | 60/32/3/5 | 12216 | 1.56 |
| A-40 | a-1 | b-21 | c-3 | | | 55/37/8 | 11853 | 1.43 |
| A-41 | a-4 | b-20 | c-8 | | | 50/40/10 | 6544 | 1.65 |
| A-42 | a-9 | b-13 | c-13 | | | 68/29/3 | 9104 | 1.54 |
| A-43 | a-1 | b-5 | c-3 | | | 55/36/9 | 8472 | 1.76 |
| A-44 | a-9 | b-8 | c-14 | | e-5 | 55/35/6/4 | 8722 | 1.49 |
| A-45 | a-1 | b-15 | c-7 | | | 60/36/4 | 10172 | 1.63 |
| A-46 | a-1 | b-5 | c-19 | | | 60/35/5 | 12354 | 1.82 |
| A-47 | a-1 | b-1 | c-20 | | | 67/30/3 | 13458 | 1.75 |
| A-48 | a-1 | b-1 | c-20 | | | 59/32/9 | 14720 | 1.79 |

The structural formulas of the repeating units described in Table 1 will be described below. For repeating units described in Repeating unit 2 and corresponding to the repeating unit (A), the structural formulas of corresponding raw material monomers will be described.

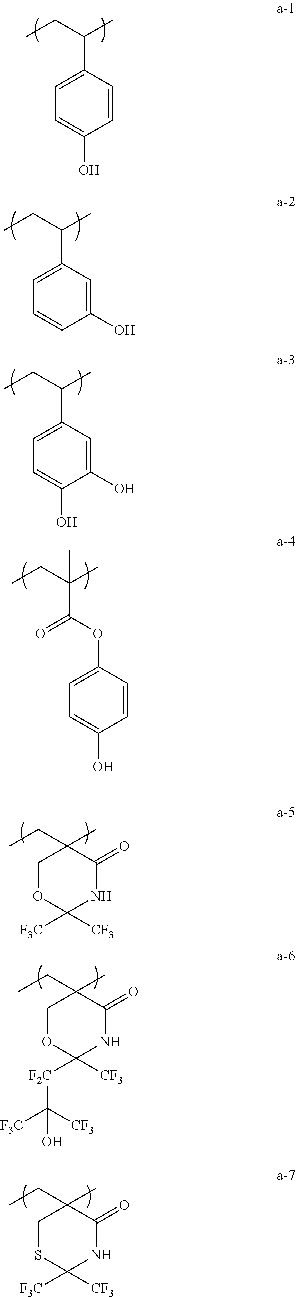

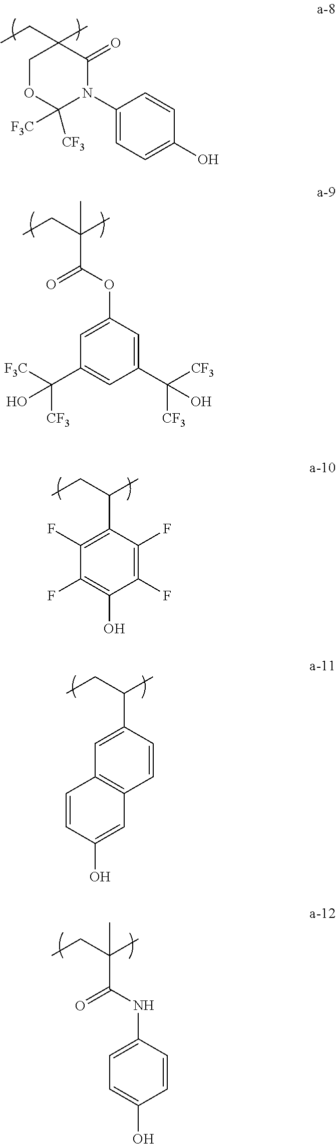

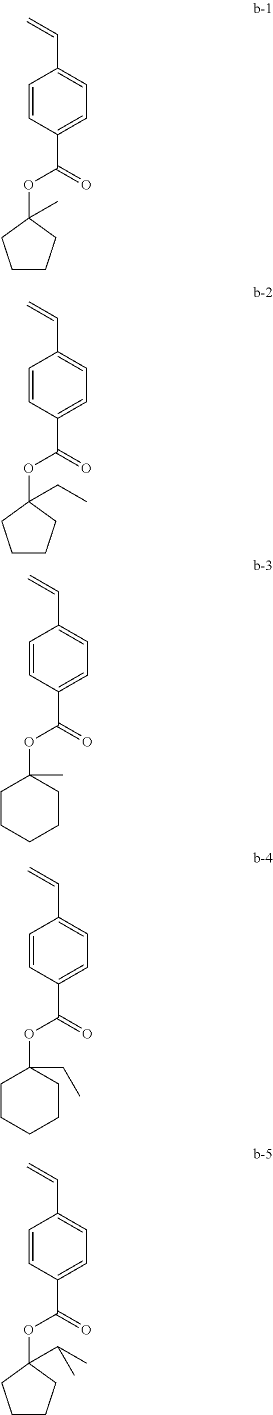

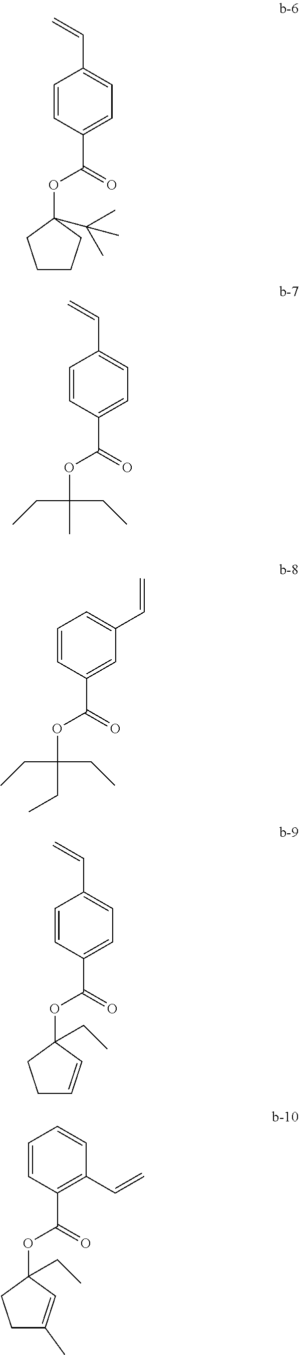

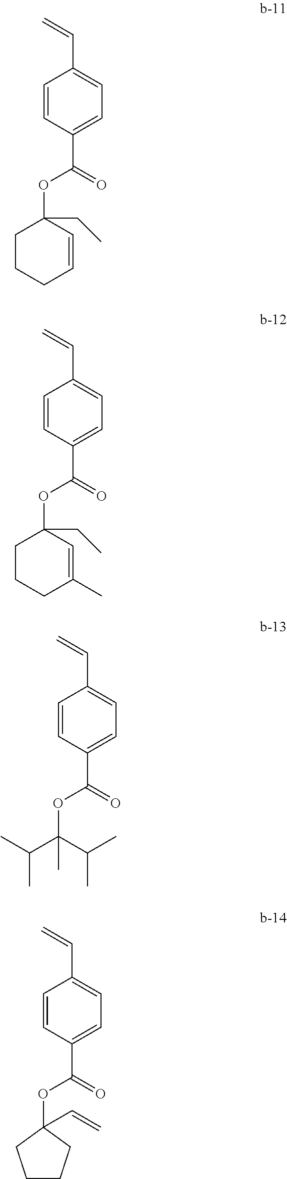

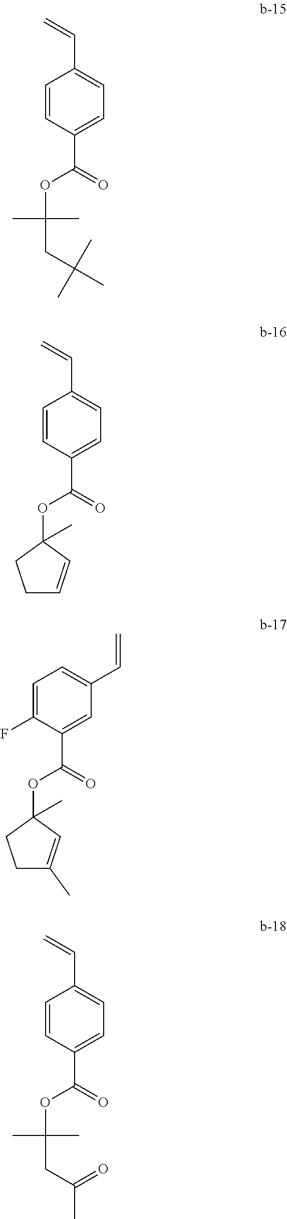

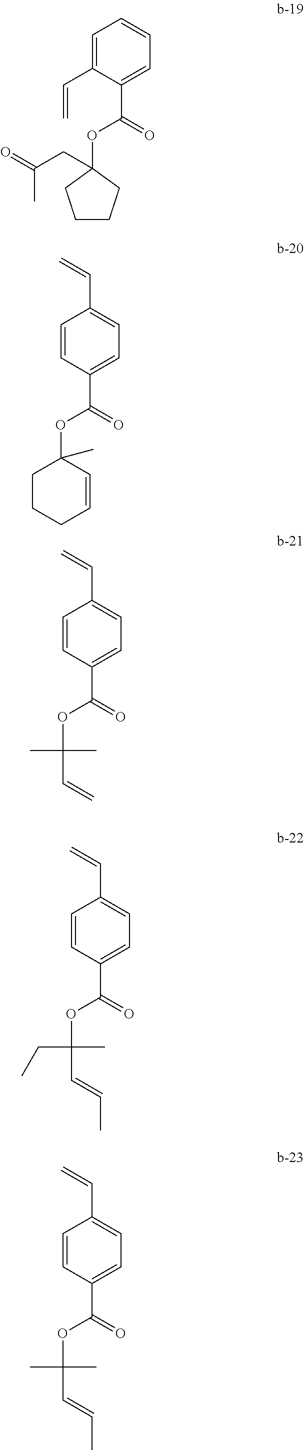

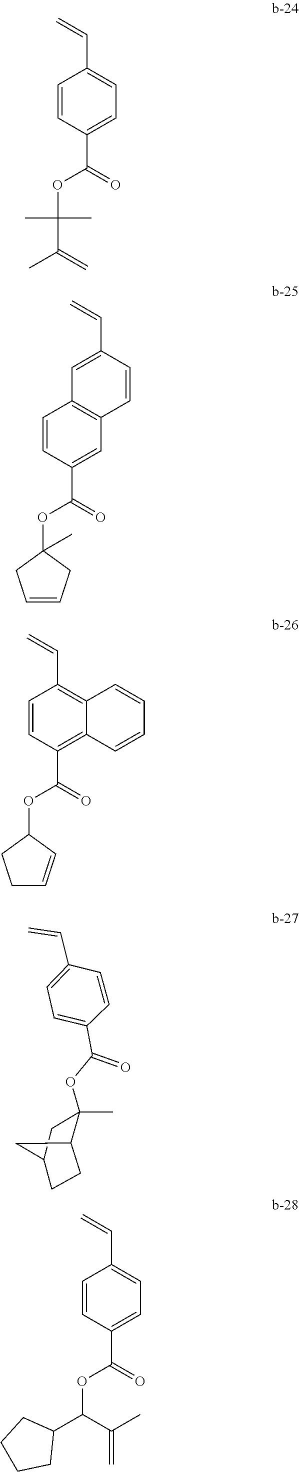

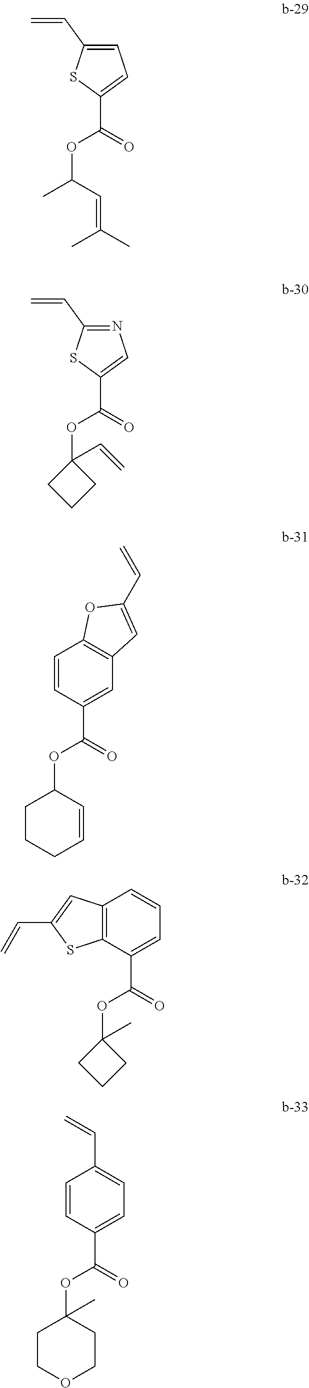

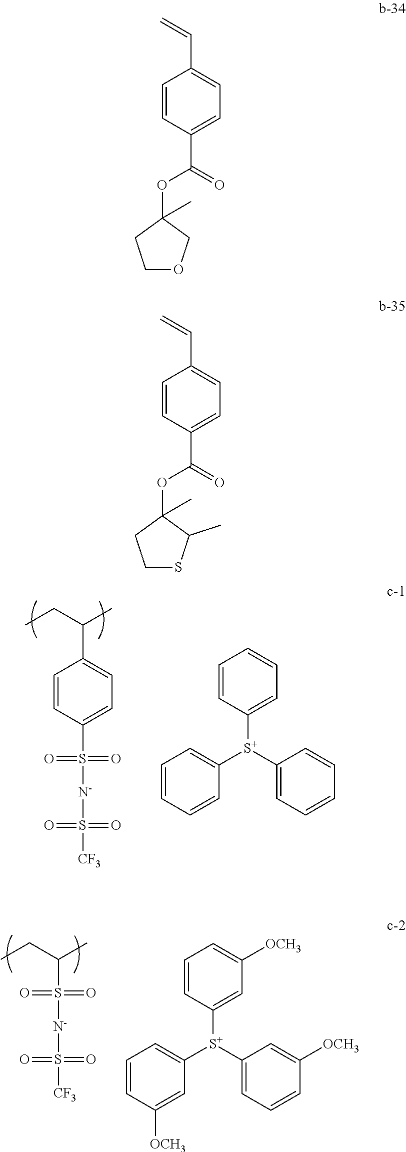

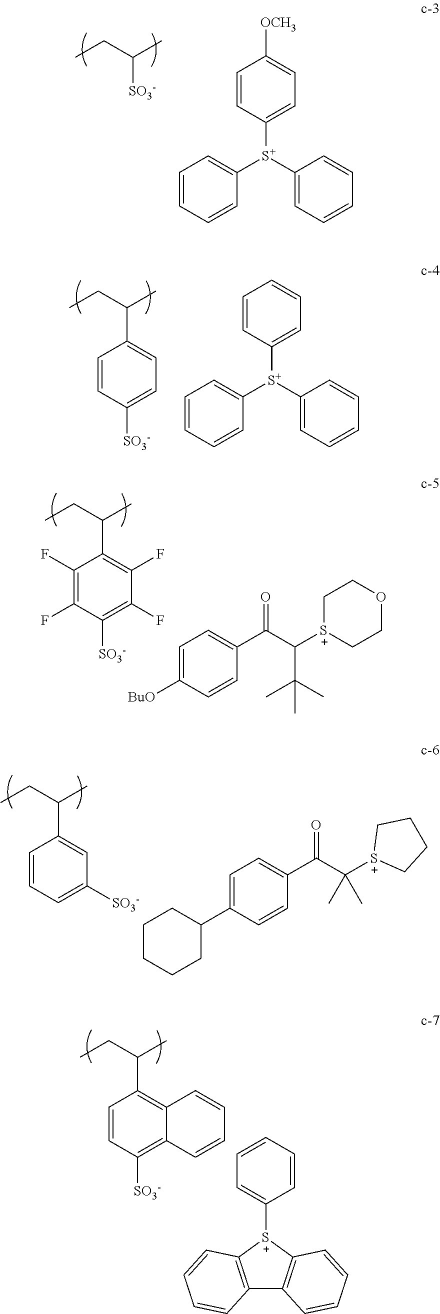

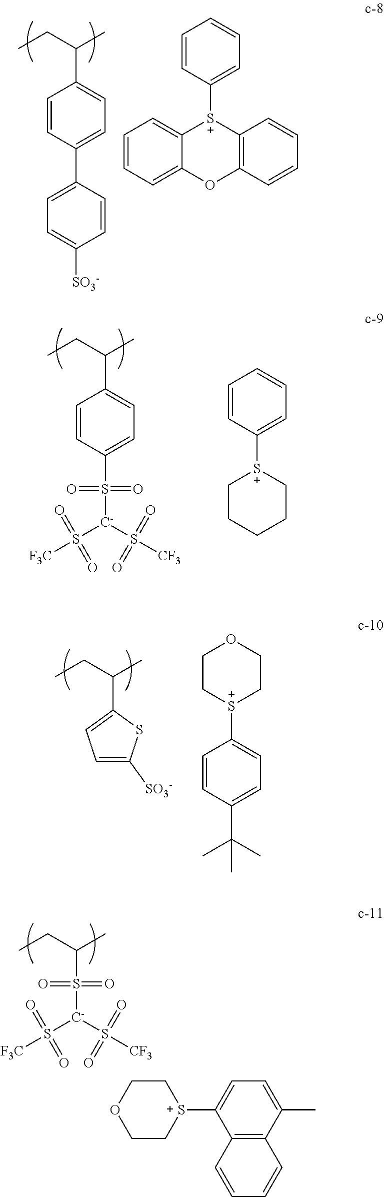

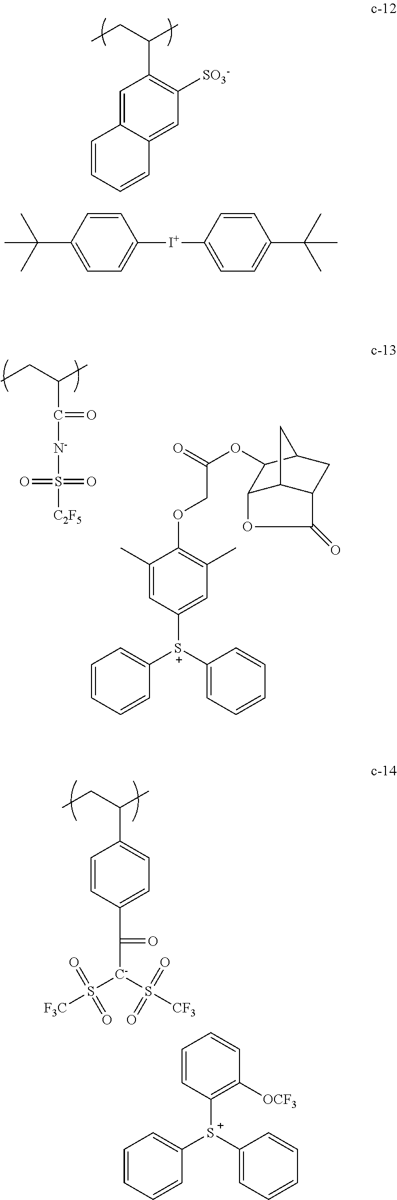

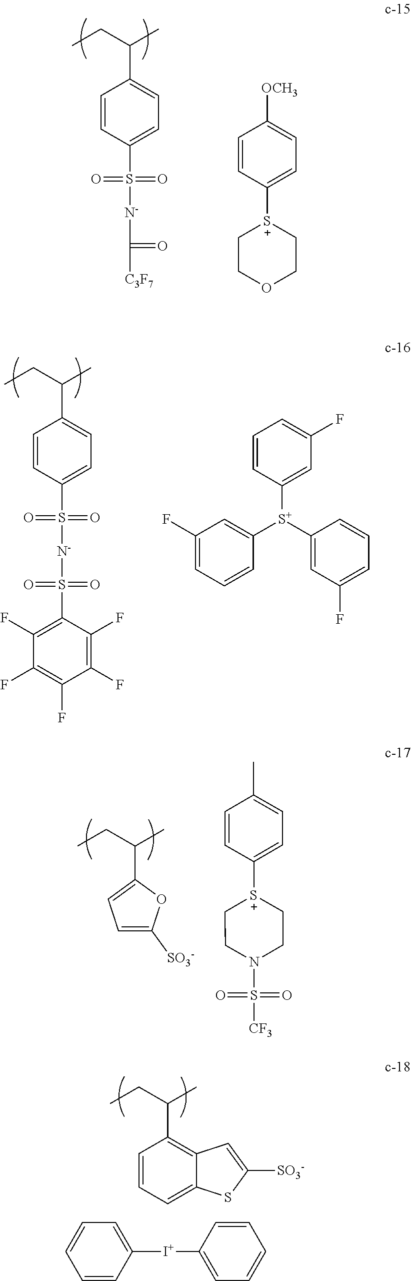

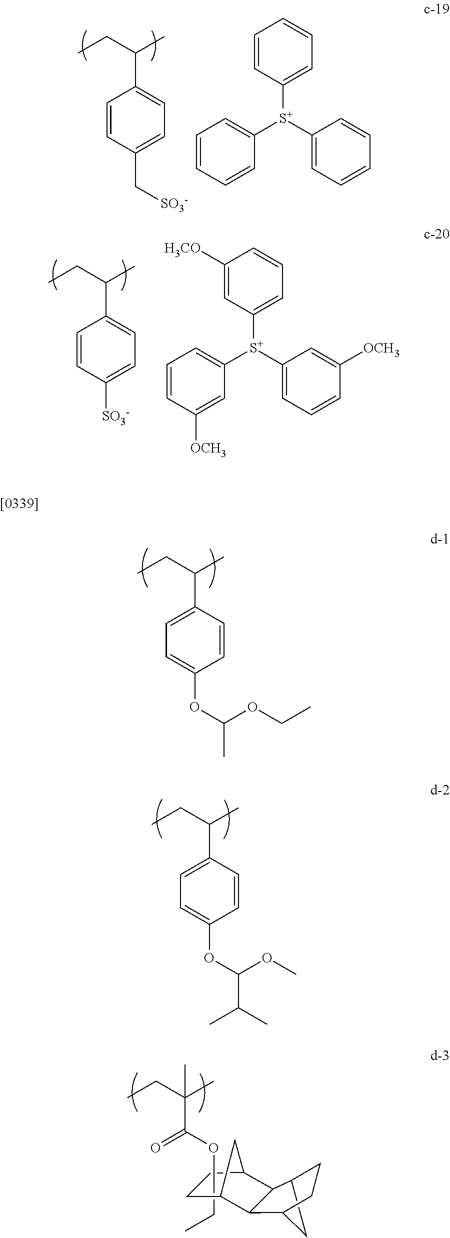

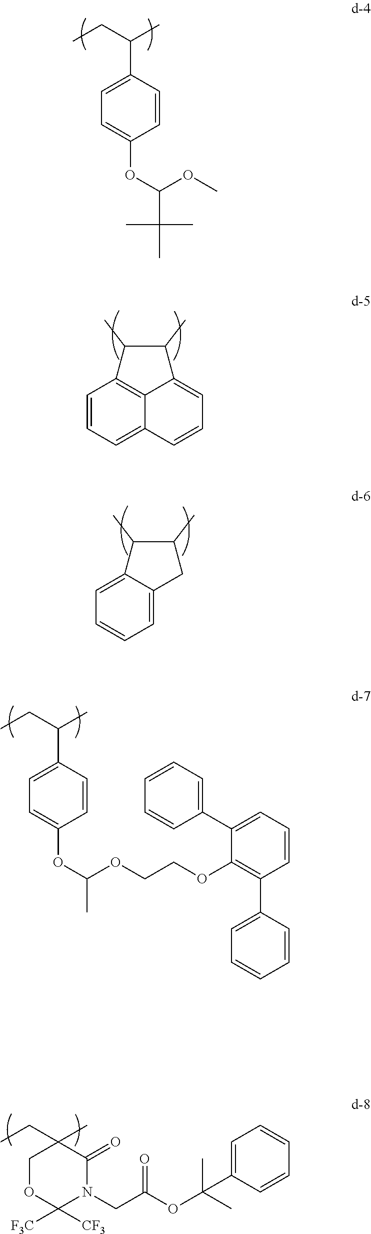

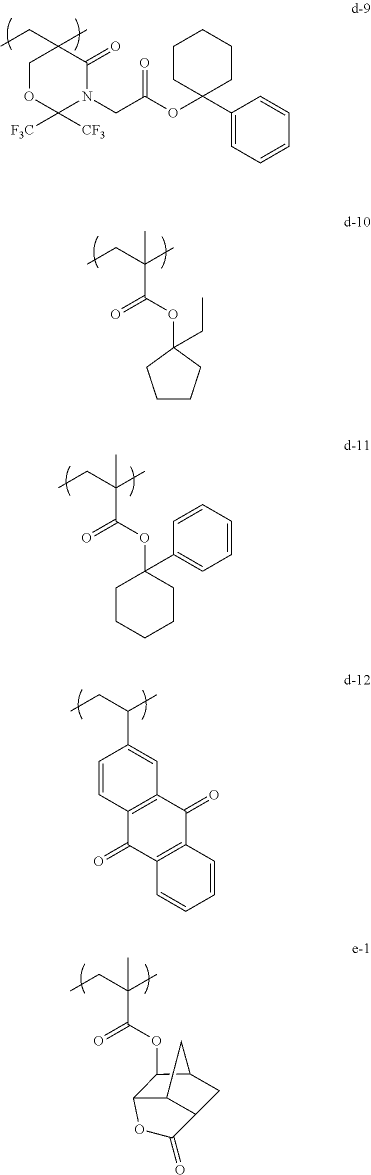

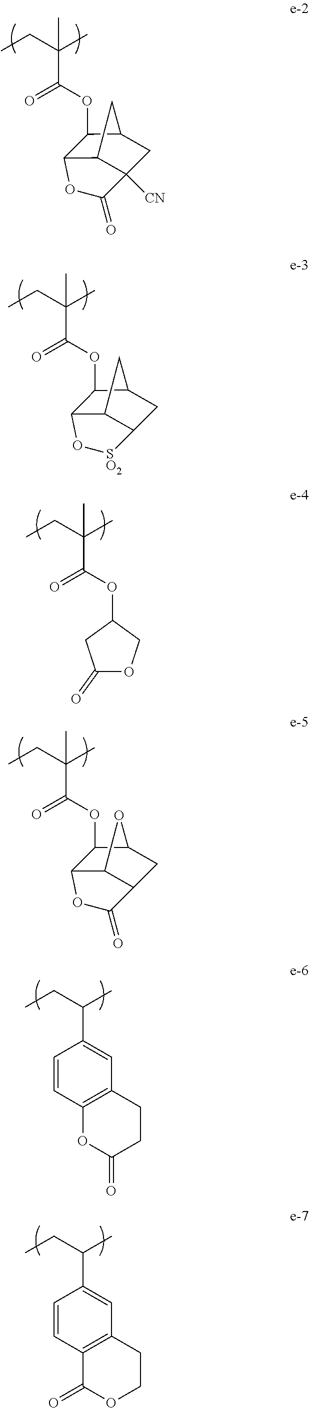

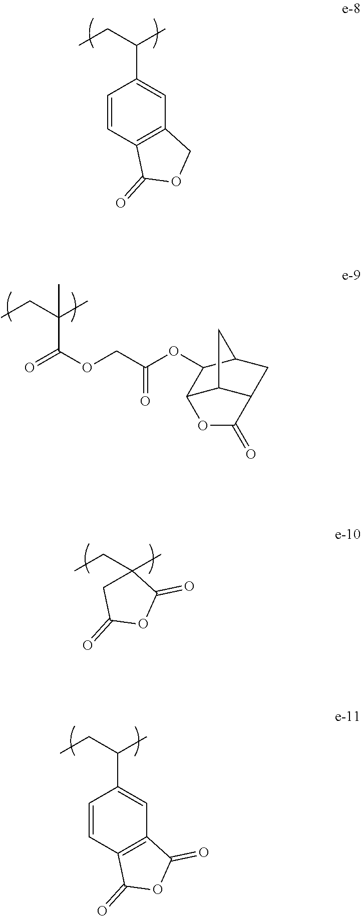

For Comparative Examples, the following resins (AX-1) to (AX-4) were used.

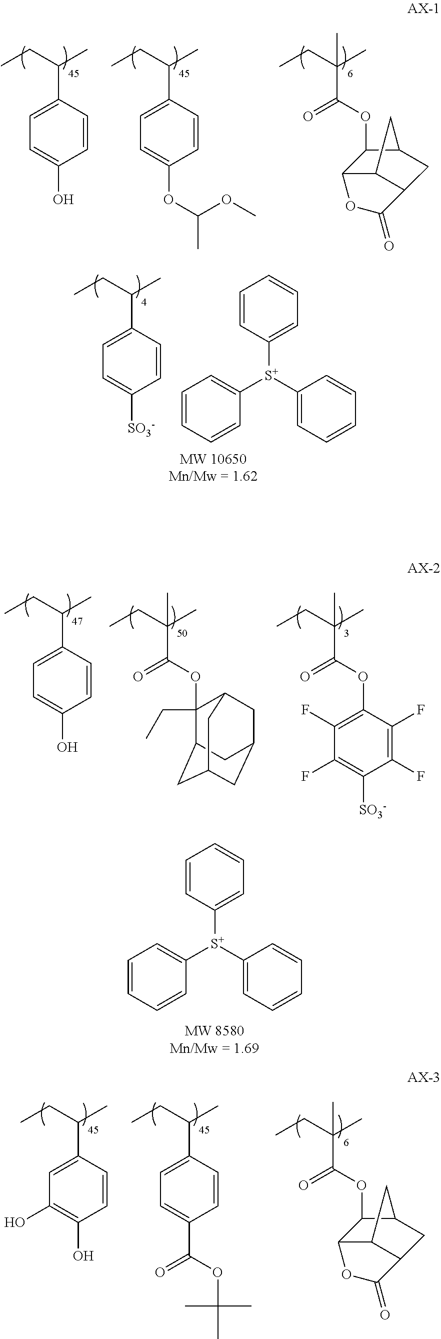

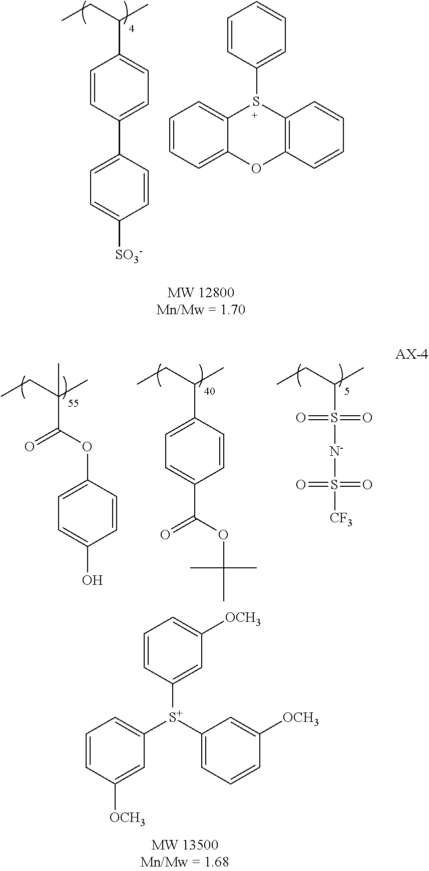

### Acid Diffusion Control Agent

The structures of the acid diffusion control agents used will be described below.

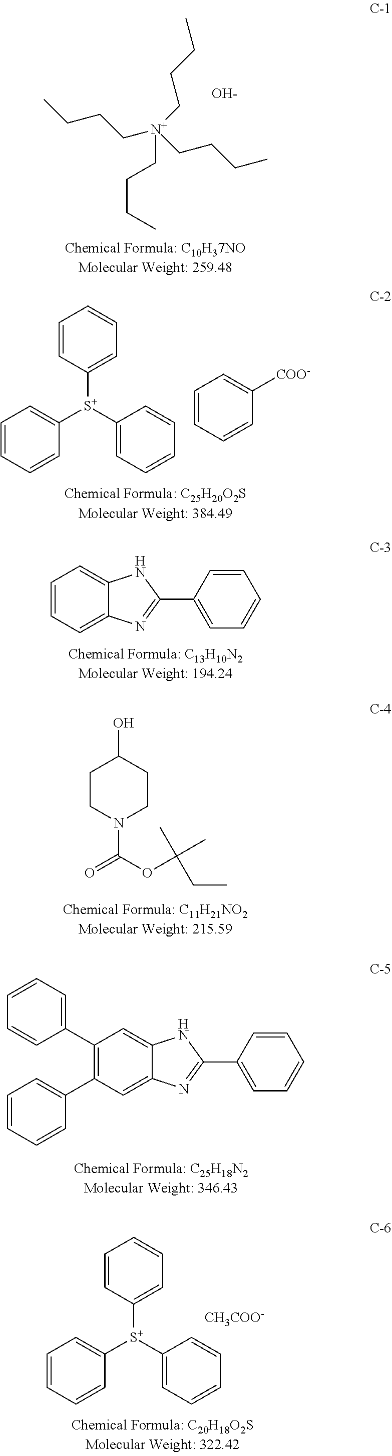

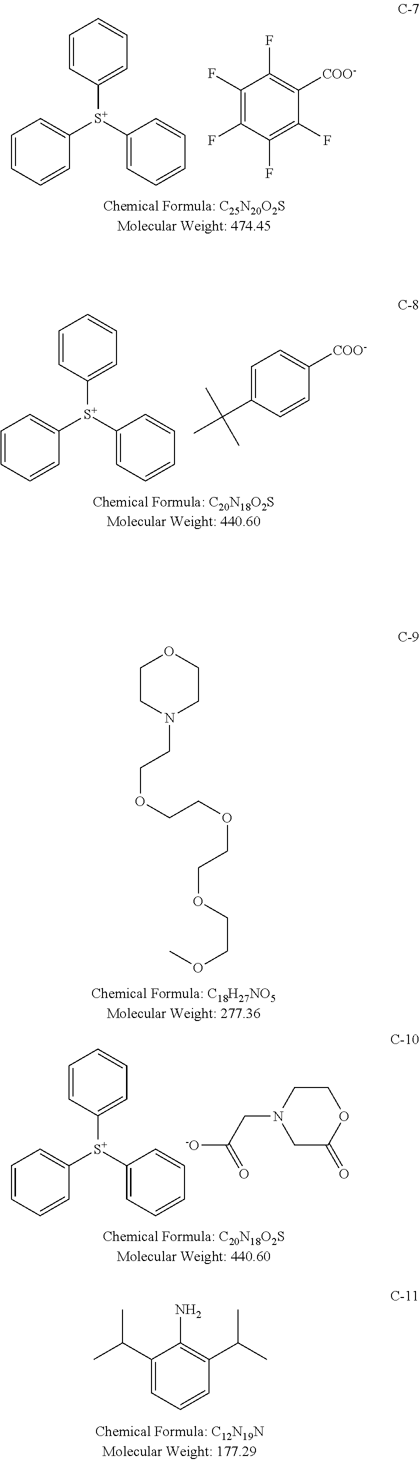

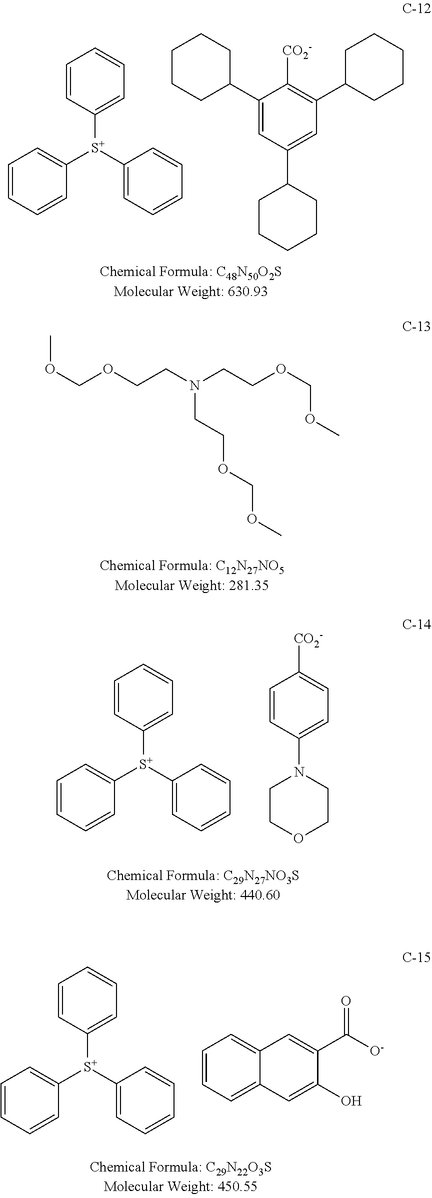

### Surfactant

As surfactants, the following W-1 to W-4 were used.
W-1: MEGAFACE R₀₈ (manufactured by Dainippon Ink and Chemicals, Inc.; fluorine and silicone-based)
W-2: polysiloxane polymer KP-341 (manufactured by Shin-Etsu Chemical Co., Ltd.; silicone-based)
W-3: Troysol S-366 (manufactured by Troy Chemical Corporation; fluorine-based)
W-4: PF6320 (manufactured by OMNOVA Solutions Inc.; fluorine-based)

### Solvent

The solvents used will be described below. The boiling points of the solvents will also be described.
S-1: diacetone alcohol (DAA), 166° C.
S-2: ethyl lactate (EL), 154° C.
S-3: ethyl 3-ethoxypropionate (EEP), 170° C.
S-4: 2-heptanone (MAK), 151° C.
S-5: 3-methoxybutyl acetate, 172° C.
S-6: γ-butyrolactone, 204° C.
S-7: methyl 3-methoxypropionate (MMP), 144° C.
S-8: propylene glycol monomethyl ether acetate (PGMEA), 146° C.
S-9: propylene glycol monomethyl ether (PGME), 120° C.

### Preparation and Application of Coating Liquid of Resist Composition

### (1) Preparation of support

An 8-inch wafer on which Cr oxynitride was vapor-deposited (wafer used for an ordinary photo mask blank and having been subjected to the shielding-film treatment) was prepared.

### (2) Preparation of Resist Composition

Components described in Table 2 were dissolved in a solvent described in the same table to prepare a solution having a solid content concentration described in the same table; and the solution was filtered through a polyethylene filter having a pore size of 0.03 m to prepare a resist composition.

### (3) Preparation of Resist Film

The resist composition was applied onto the 8-inch wafer using a spin coater Mark8 manufactured by Tokyo Electron Ltd., and dried on a hot plate at 120° C. for 600 seconds to provide a resist film having a film thickness of 100 nm. Thus, a resist-coated wafer was obtained.

### EB Exposure and Development

### (4) Preparation of Resist Pattern

The resist film obtained in (3) above was irradiated to form a pattern using an electron-beam lithography apparatus (manufactured by ADVANTEST CORPORATION; F7000S, accelerating voltage: 50 KeV). After the irradiation, heating at 100° C. for 600 seconds on a hot plate was performed; immersion using a 2.38 mass % aqueous solution of tetramethylammonium hydroxide (TMAH) for 60 seconds was performed; subsequently, rinsing with water for 30 seconds and drying were performed.

### Evaluations

### (5) Evaluation of Resist Pattern

The obtained pattern was evaluated for resolution and pattern profile by the following methods. The results will be described later in Table 3.

The irradiation energy for resolving a 1:1 line-and-space pattern having a line width of 50 nm was defined as sensitivity (Eop).

L/S resolution

The limiting resolving power (minimum line width at which a line and a space (line:space=1:1) are separated and resolved) at the exposure dose providing the above-described sensitivity (Eop) was defined as the resolving power (nm).

Isolated space pattern (IS) resolution

The limiting resolving power of an isolated space (line:space=100:1) provided at (Eop) above (minimum space width at which a line and a space are resolved) was determined. This value was defined as the “isolated space pattern resolving power (nm)”.

### Pattern Profile

Profiles of 1:1 line-and-space patterns having a line width of 50 nm and formed at an irradiation dose providing the above-described sensitivity were observed using a scanning electron microscope (5-4800 manufactured by Hitachi, Ltd.) and evaluated: a profile of a line pattern in which a ratio represented by [line width at top portion (surface portion) of line pattern/line width at middle portion (at height position corresponding to half of height of line pattern) of line pattern] was 1.1 or more, was evaluated as “Reverse taper”; a profile of a line pattern in which the ratio was 1.03 or more and less than 1.1 was evaluated as “Slightly reverse taper”; and a profile of a line pattern in which the ratio was less than 1.03 was evaluated as “Square”.

Note that, in Table 2 below, the content (mass %) of each component other than the solvent means the content ratio relative to the total solid content. In addition, Table 2 below describes the content ratios (mass) of solvents used to all the solvents.

In addition, in Table 2, the content (mass % o) of a solvent having a boiling point of 150° C. or more relative to all the solvents is described as “Solvent having boiling point of 150C or more”, and the content (mass %) of a solvent having a boiling point of 150° C. or more and a hydroxyl group relative to all the solvents is described as “Solvent having boiling point of 150° C. or more and hydroxyl group”.

TABLE 2

| | | | | | | Solvent | |
|---|---|---|---|---|---|---|---|
| | | | | | | | Content |
| | | | Acid diffusion | | Surfactant | | ratio of |
| | Resin (P) | | control agent | | Type | | solvent |
| Resist | | Content | | Content | (0.01 | Solvent | 1 |
| composition | Compound | (mass %) | Compound | (mass %) | mass %) | 1 | (mass %) |
| R-1 | (A-1) | 99.85 | C-12 | 0.15 | | S-1 | 100 |
| R-2 | (A-2) | 99.88 | C-13 | 0.11 | W-1 | S-1 | 80 |
| R-3 | (A-3) | 99.90 | C-4 | 0.10 | | S-1 | 80 |
| R-4 | (A-4) | 99.93 | C-10 | 0.06 | W-1 | S-1 | 39 |
| R-5 | (A-5) | 99.91 | C-2 | 0.09 | | S-1 | 41 |
| R-6 | (A-6) | 99.82 | C-7 | 0.18 | | S-1 | 60 |
| R-7 | (A-7) | 99.93 | C-3 | 0.06 | W-4 | S-1 | 70 |
| R-8 | (A-8) | 99.89 | C-12 | 0.11 | | S-2 | 34 |
| R-9 | (A-9) | 97.75 | C-13 | 2.25 | | S-1 | 30 |
| R-10 | (A-10) | 99.78 | C-6 | 0.22 | | S-1 | 40 |
| R-11 | (A-11) | 99.94 | C-9 | 0.05 | W-2 | S-1 | 100 |
| R-12 | (A-12) | 99.77 | C-11 | 0.23 | | S-1 | 20 |
| R-13 | (A-13) | 96.82 | C-12 | 3.18 | | S-1 | 55 |
| R-14 | (A-14) | 99.93 | C-11 | 0.06 | W-3 | S-1 | 40 |
| R-15 | (A-15) | 99.82 | C-12 | 0.17 | W-1 | S-1 | 50 |
| R-16 | (A-16) | 99.88 | C-13 | 0.12 | | S-1 | 30 |
| R-17 | (A-17) | 99.82 | C-10 | 0.18 | | S-1 | 50 |
| R-18 | (A-18) | 99.79 | C-10 | 0.20 | W-2 | S-1 | 23 |
| R-19 | (A-19) | 98.78 | C-3 | 1.22 | | S-1 | 20 |
| R-20 | (A-20) | 99.88 | C-10 | 0.12 | | S-1 | 41 |
| R-21 | (A-21) | 99.79 | C-1 | 0.21 | | S-1 | 38 |
| R-22 | (A-22) | 99.86 | C-5 | 0.13 | W-4 | S-1 | 30 |
| R-23 | (A-23) | 98.85 | C-14 | 1.15 | | S-2 | 10 |
| R-24 | (A-24) | 99.86 | C-13 | 0.14 | | S-2 | 25 |
| R-25 | (A-25) | 99.88 | C-7 | 0.11 | W-2 | S-1 | 10 |
| R-26 | (A-26) | 99.79 | C-11 | 0.21 | | S-2 | 100 |
| R-27 | (A-27) | 99.86 | C-1 | 0.13 | W-2 | S-1 | 57 |
| R-28 | (A-28) | 99.89 | C-2 | 0.11 | | S-1 | 50 |
| R-29 | (A-29) | 99.78 | C-6 | 0.22 | | S-1 | 80 |
| R-30 | (A-30) | 99.77 | C-9 | 0.33 | | S-1 | 70 |

| | Solvent | | | | | | |
|---|---|---|---|---|---|---|---|
| | | | | | | Solvent | |
| | | | | | | having | |
| | | | | | | boiling | |
| | | | | | Solvent | point of | |
| | | | | | having | 150° C. | |
| | | Content | | Content | boiling | or more | |
| | | ratio of | | ratio of | point of | and | |
| | | solvent | | solvent | 150° C. | hydroxyl | Solid content |
| Resist | Solvent | 2 | Solvent | 3 | or more | group | concentration |
| composition | 2 | (mass %) | 3 | (mass %) | (mass %) | (mass %) | (mass %) |
| R-1 | | | | | 100 | 100 | 3.5 |
| R-2 | S-4 | 20 | — | | 100 | 80 | 4.7 |
| R-3 | S-3 | 10 | S-9 | 10 | 90 | 80 | 2.8 |
| R-4 | S-2 | 20 | S-3 | 41 | 100 | 59 | 3.7 |
| R-5 | S-6 | 40 | S-7 | 19 | 81 | 41 | 4.5 |
| R-6 | S-2 | 20 | S-7 | 20 | 80 | 80 | 3.3 |
| R-7 | S-4 | 25 | S-5 | 5 | 100 | 70 | 3.9 |
| R-8 | S-3 | 46 | S-4 | 20 | 100 | 34 | 3.3 |
| R-9 | S-2 | 20 | S-3 | 50 | 100 | 50 | 4.5 |
| R-10 | S-2 | 25 | S-4 | 35 | 100 | 65 | 2.8 |
| R-11 | | | | | 100 | 100 | 3.8 |
| R-12 | S-3 | 30 | S-7 | 50 | 50 | 20 | 4.0 |
| R-13 | S-4 | 30 | S-8 | 15 | 85 | 55 | 3.7 |
| R-14 | S-5 | 10 | S-6 | 50 | 100 | 40 | 3.9 |
| R-15 | S-4 | 20 | S-8 | 30 | 70 | 50 | 4.3 |
| R-16 | S-4 | 25 | S-7 | 45 | 55 | 30 | 3.7 |
| R-17 | S-2 | 50 | | | 100 | 100 | 4.3 |
| R-18 | S-2 | 27 | S-7 | 50 | 50 | 50 | 2.8 |
| R-19 | S-5 | 70 | S-3 | 10 | 100 | 20 | 3.2 |
| R-20 | S-6 | 20 | S-9 | 39 | 61 | 41 | 3.2 |
| R-21 | S-4 | 47 | S-8 | 15 | 85 | 38 | 2.8 |
| R-22 | S-3 | 30 | S-7 | 40 | 60 | 30 | 2.5 |
| R-23 | S-3 | 50 | S-7 | 40 | 60 | 10 | 2.8 |
| R-24 | S-3 | 20 | S-9 | 55 | 45 | 25 | 3.3 |
| R-25 | S-2 | 58 | S-9 | 32 | 68 | 68 | 3.1 |
| R-26 | | | | | 100 | 100 | 4.0 |
| R-27 | S-4 | 33 | S-8 | 10 | 90 | 57 | 2.8 |
| R-28 | S-2 | 50 | | | 100 | 100 | 3.3 |
| R-29 | S-4 | 20 | | | 100 | 80 | 3.1 |
| R-30 | S-2 | 15 | S-3 | 15 | 100 | 85 | 2.9 |

| | | | | | | Solvent | |
|---|---|---|---|---|---|---|---|
| | | | | | | | Content |
| | | | Acid diffusion | | Surfactant | | ratio of |
| | Resin (P) | | control agent | | Type | | solvent |
| Resist | | Content | | Content | (0.01 | Solvent | 1 |
| composition | Compound | (mass %) | Compound | (mass %) | mass %) | 1 | (mass %) |
| R-31 | (A-31) | 99.79 | C-7 | 0.21 | | S-1 | 60 |
| R-32 | (A-32) | 99.76 | C-2 | 0.24 | | S-1 | 20 |
| R-33 | (A-33) | 99.92 | C-2 | 0.07 | W-2 | S-3 | 37 |
| R-34 | (A-34) | 99.85 | C-9 | 0.15 | | S-1 | 20 |
| R-35 | (A-35) | 99.87 | C-9 | 0.13 | | S-1 | 20 |
| R-36 | (A-36) | 99.81 | C-13 | 0.19 | | S-3 | 57 |
| R-37 | (A-37) | 99.88 | C-10 | 0.11 | W-4 | S-4 | 44 |
| R-38 | (A-38) | 99.76 | C-13 | 0.24 | | S-1 | 10 |
| R-39 | (A-39) | 99.78 | C-5 | 0.22 | | S-1 | 16 |
| R-40 | (A-40) | 99.82 | C-11 | 0.18 | | S-1 | 40 |
| R-41 | (A-41) | 99.91 | C-8 | 0.08 | W-1 | S-2 | 100 |
| R-42 | (A-42) | 99.82 | C-10 | 0.18 | | S-1 | 70 |
| R-43 | (A-43) | 99.75 | C-4 | 0.25 | | S-1 | 65 |
| R-44 | (A-44) | 99.78 | C-12 | 0.22 | | S-1 | 65 |
| R-45 | (A-45) | 99.87 | C-11 | 0.13 | | S-1 | 50 |
| R-46 | (A-38) | 99.76 | C-13 | 0.24 | | S-1 | 90 |
| R-47 | (A-40) | 99.82 | C-11 | 0.18 | | S-2 | 100 |
| R-48 | (A-46) | 99.76 | C-8 | 0.24 | | S-1 | 30 |
| R-49 | (A-47) | 89.97 | C-15 | 10.03 | | S-2 | 60 |
| R-50 | (A-48) | 86.02 | C-15 | 13.98 | | S-1 | 80 |
| R-51 | (A-38) | 84.32 | C-2 | 15.68 | | S-1 | 85 |
| R-52 | (A-43) | 92.41 | C-8 | 7.59 | | S-2 | 70 |
| R-53 | (A-1) | 95.54 | C-2 | 4.46 | | S-2 | 60 |
| R-54 | (A-19) | 91.59 | C-2 | 8.41 | | S-2 | 60 |
| RX-1 | AX-1 | 99.79 | C-2 | 0.21 | | S-1 | 60 |
| RX-2 | AX-2 | 99.80 | C-1 | 0.20 | | S-1 | 55 |
| RX-3 | (A-21) | 99.87 | C-13 | 0.12 | W-2 | S-1 | 30 |
| RX-4 | (A-35) | 99.81 | C-13 | 0.19 | | S-1 | 40 |
| RX-5 | AX-3 | 99.75 | C-5 | 0.25 | | S-1 | 50 |
| RX-6 | AX-4 | 99.79 | C-11 | 0.21 | | S-1 | 60 |

| | Solvent | | | | | | |
|---|---|---|---|---|---|---|---|
| | | | | | | Solvent | |
| | | | | | | having | |
| | | | | | | boiling | |
| | | | | | Solvent | point of | |
| | | | | | having | 150° C. | |
| | | Content | | Content | boiling | or more | |
| | | ratio of | | ratio of | point of | and | |
| | | solvent | | solvent | 150° C. | hydroxyl | Solid content |
| Resist | Solvent | 2 | Solvent | 3 | or more | group | concentration |
| composition | 2 | (mass %) | 3 | (mass %) | (mass %) | (mass %) | (mass %) |
| R-31 | S-3 | 40 | | | 100 | 60 | 3.2 |
| R-32 | S-2 | 20 | S-3 | 60 | 100 | 40 | 3.8 |
| R-33 | S-4 | 30 | S-8 | 33 | 67 | 0 | 3.6 |
| R-34 | S-3 | 50 | S-5 | 30 | 100 | 20 | 5.4 |
| R-35 | S-2 | 70 | S-6 | 10 | 100 | 20 | 3.5 |
| R-36 | S-4 | 30 | S-8 | 13 | 87 | 0 | 3.8 |
| R-37 | S-2 | 30 | S-7 | 26 | 74 | 30 | 4.1 |
| R-38 | S-3 | 41 | S-8 | 49 | 51 | 10 | 3.2 |
| R-39 | S-2 | 36 | S-8 | 48 | 52 | 52 | 3.7 |
| R-40 | S-4 | 22 | S-7 | 38 | 62 | 40 | 4.7 |
| R-41 | | | | | 100 | 100 | 3.8 |
| R-42 | S-5 | 30 | | | 100 | 70 | 3.9 |
| R-43 | S-2 | 35 | | | 100 | 100 | 3.0 |
| R-44 | S-5 | 30 | S-6 | 5 | 100 | 65 | 4.3 |
| R-45 | S-4 | 20 | S-5 | 30 | 100 | 50 | 3.7 |
| R-46 | S-8 | 10 | | | 90 | 90 | 3.3 |
| R-47 | | | | | 100 | 100 | 4.5 |
| R-48 | S-3 | 30 | S-7 | 40 | 60 | 30 | 2.5 |
| R-49 | S-8 | 20 | S-9 | 20 | 60 | 60 | 2.7 |
| R-50 | S-9 | 20 | | | 80 | 80 | 1.6 |
| R-51 | S-9 | 15 | | | 85 | 85 | 2.0 |
| R-52 | S-8 | 20 | S-9 | 10 | 70 | 70 | 2.6 |
| R-53 | S-8 | 20 | S-9 | 20 | 60 | 60 | 2.5 |
| R-54 | S-8 | 20 | S-9 | 20 | 60 | 60 | 2.2 |
| RX-1 | S-2 | 40 | | | 100 | 100 | 5.0 |
| RX-2 | S-4 | 45 | | | 100 | 55 | 3.5 |
| RX-3 | S-7 | 70 | | | 30 | 30 | 3.6 |
| RX-4 | S-8 | 60 | | | 40 | 40 | 4.1 |
| RX-5 | S-2 | 50 | | | 100 | 100 | 3.8 |
| RX-6 | S-3 | 40 | | | 100 | 60 | 2.9 |

TABLE 3

| | | L/S | IS | |
|---|---|---|---|---|
| | Resist | resolution | resolution | Pattern |
| | composition | [nm] | [nm] | profile |
| Example 1a | R-1 | 18.1 | 18.0 | Square |
| Example 2a | R-2 | 18.2 | 18.0 | Square |
| Example 3a | R-3 | 18.6 | 18.9 | Square |
| Example 4a | R-4 | 19.2 | 19.6 | Square |
| Example 5a | R-5 | 18.9 | 19.1 | Square |
| Example 6a | R-6 | 19.5 | 19.0 | Square |
| Example 7a | R-7 | 18.5 | 18.9 | Square |
| Example 8a | R-8 | 18.6 | 18.8 | Square |
| Example 9a | R-9 | 18.6 | 18.6 | Square |
| Example 10a | R-10 | 19.0 | 19.1 | Square |
| Example 11a | R-11 | 18.8 | 18.7 | Square |
| Example 12a | R-12 | 18.9 | 19.2 | Square |
| Example 13a | R-13 | 18.7 | 18.6 | Square |
| Example 14a | R-14 | 18.9 | 18.6 | Square |
| Example 15a | R-15 | 18.6 | 18.7 | Square |
| Example 16a | R-16 | 19.0 | 18.9 | Square |
| Example 17a | R-17 | 19.0 | 18.7 | Square |
| Example 18a | R-18 | 18.7 | 18.6 | Square |
| Example 19a | R-19 | 18.2 | 18.1 | Square |
| Example 20a | R-20 | 19.1 | 18.7 | Square |
| Example 21a | R-21 | 18.8 | 18.8 | Square |
| Example 22a | R-22 | 19.1 | 19.2 | Square |
| Example 23a | R-23 | 19.6 | 19.5 | Square |
| Example 24a | R-24 | 19.5 | 19.0 | Square |
| Example 25a | R-25 | 18.7 | 18.5 | Square |
| Example 26a | R-26 | 19.3 | 19.2 | Square |
| Example 27a | R-27 | 19.2 | 19.7 | Square |
| Example 28a | R-28 | 18.5 | 18.6 | Square |
| Example 29a | R-29 | 18.8 | 18.5 | Square |
| Example 30a | R-30 | 18.6 | 18.6 | Square |
| Example 31a | R-31 | 18.8 | 18.5 | Square |
| Example 32a | R-32 | 18.5 | 18.7 | Square |
| Example 33a | R-33 | 19.0 | 19.5 | Square |
| Example 34a | R-34 | 18.9 | 18.6 | Square |
| Example 35a | R-35 | 18.7 | 18.6 | Square |
| Example 36a | R-36 | 18.8 | 18.8 | Square |
| Example 37a | R-37 | 19.5 | 18.9 | Square |
| Example 38a | R-38 | 17.6 | 17.8 | Square |
| Example 39a | R-39 | 18.6 | 18.5 | Square |
| Example 40a | R-40 | 17.5 | 17.6 | Square |
| Example 41a | R-41 | 18.6 | 18.7 | Square |
| Example 42a | R-42 | 18.9 | 18.6 | Square |
| Example 43a | R-43 | 17.9 | 17.8 | Square |
| Example 44a | R-44 | 18.5 | 18.3 | Square |
| Example 45a | R-45 | 17.8 | 17.8 | Square |
| Example 46a | R-46 | 17.6 | 17.6 | Square |
| Example 47a | R-47 | 17.5 | 17.5 | Square |
| Example 48a | R-48 | 18.5 | 18.7 | Square |
| Example 49a | R-49 | 17.9 | 17.8 | Square |
| Example 50a | R-50 | 17.9 | 17.9 | Square |
| Example 51a | R-51 | 18.2 | 17.9 | Square |
| Example 52a | R-52 | 18.2 | 18.3 | Square |
| Example 53a | R-53 | 18.2 | 18.1 | Square |
| Example 54a | R-54 | 18.0 | 18.2 | Square |
| Comparative | RX-1 | 22.4 | 22.3 | Slightly |
| Example 1a | | | | reverse taper |
| Comparative | RX-2 | 30.1 | 32.3 | Reverse taper |
| Example 2a | | | | |
| Comparative | RX-3 | 28.6 | 27.6 | Slightly |
| Example 3a | | | | reverse taper |
| Comparative | RX-4 | 25.6 | 28.8 | Square |
| Example 4a | | | | |
| Comparative | RX-5 | Failed to form the pattern | | |
| Example 5a | | | | |
| Comparative | RX-6 | 27.4 | 26.5 | Reverse taper |
| Example 6a | | | | |

The results described in Table 3 have demonstrated the following: the composition of the present invention has high resolution and can provide an excellent pattern profile in the formation of an ultrafine pattern (having, in particular, a line width or a space width of 20 nm or less).

### Extreme Ultraviolet (EUV) Exposure

### (4) Preparation of Resist Pattern

The wafer coated with the resist film obtained in (3) above was subjected to pattern exposure using an EUV exposure apparatus (Micro Exposure Tool manufactured by Exitech Ltd., NA (numerical aperture): 0.3, Quadrupole, outer sigma: 0.68, inner sigma: 0.36) and an exposure mask (line/space=1/1). After the exposure, heating on a hot plate was performed at 100° C. for 90 seconds; subsequently, immersion in a 2.38 mass % aqueous solution of tetramethylammonium hydroxide (TMAH) for 60 seconds was performed, and subsequently rinsing with water for 30 seconds was performed. Subsequently, the wafer was rotated at a number of rotations of 4000 rpm for 30 seconds, and subsequently baked at 95° C. for 60 seconds for drying.

### Evaluations

### (5) Evaluation of Resist Pattern

The obtained pattern was evaluated for resolution and pattern profile by the following methods. The results will be described later in Table 4.

The irradiation energy for resolving a 1:1 line-and-space pattern having a line width of 50 nm was defined as sensitivity (Eop).

### L/S Resolution

The limiting resolving power (minimum line width at which a line and a space (line:space=1:1) are separated and resolved) at the exposure dose providing the above-described sensitivity (Eop) was defined as the resolving power (nm).

### Isolated Space Pattern (IS) Resolution

The limiting resolving power of an isolated space (line:space=100:1) provided at (Eop) above (minimum space width at which a line and a space are resolved) was determined. This value was defined as the “isolated space pattern resolving power (nm)”.

### Pattern Profile

Profiles of 1:1 line-and-space patterns having a line width of 50 nm and formed at an irradiation dose providing the above-described sensitivity were observed using a scanning electron microscope (S-4800 manufactured by Hitachi, Ltd.) and evaluated: a profile of a line pattern in which a ratio represented by [line width at top portion (surface portion) of line pattern/line width at middle portion (at height position corresponding to half of height of line pattern) of line pattern] was 1.1 or more, was evaluated as “Reverse taper”; a profile of a line pattern in which the ratio was 1.03 or more and less than 1.1 was evaluated as “Slightly reverse taper”; and a profile of a line pattern in which the ratio was less than 1.03 was evaluated as “Square”.

TABLE 4

| | | L/S | IS | |
|---|---|---|---|---|
| | Resist | resolution | resolution | Pattern |
| | composition | [nm] | [nm] | profile |
| Example 1b | R-1 | 18.2 | 18.1 | Square |
| Example 2b | R-2 | 18.1 | 18.1 | Square |
| Example 3b | R-3 | 18.5 | 18.8 | Square |
| Example 4b | R-4 | 19.3 | 19.4 | Square |
| Example 5b | R-5 | 19.0 | 19.2 | Square |
| Example 6b | R-6 | 19.3 | 19.2 | Square |
| Example 7b | R-7 | 18.4 | 18.8 | Square |
| Example 8b | R-8 | 18.7 | 18.9 | Square |
| Example 9b | R-9 | 18.7 | 18.7 | Square |
| Example 10b | R-10 | 19.0 | 19.2 | Square |
| Example 11b | R-11 | 18.9 | 18.9 | Square |
| Example 12b | R-12 | 19.0 | 19.1 | Square |
| Example 13b | R-13 | 18.6 | 18.8 | Square |
| Example 14b | R-14 | 18.9 | 18.7 | Square |
| Example 15b | R-15 | 18.5 | 18.8 | Square |
| Example 16b | R-16 | 19.0 | 18.9 | Square |
| Example 17b | R-17 | 19.1 | 18.9 | Square |
| Example 18b | R-18 | 18.9 | 18.8 | Square |
| Example 19b | R-19 | 18.3 | 18.3 | Square |
| Example 20b | R-20 | 19.0 | 18.9 | Square |
| Example 21b | R-21 | 18.7 | 18.9 | Square |
| Example 22b | R-22 | 19.0 | 19.2 | Square |
| Example 23b | R-23 | 19.4 | 19.5 | Square |
| Example 24b | R-24 | 19.2 | 19.1 | Square |
| Example 25b | R-25 | 18.8 | 18.6 | Square |
| Example 26b | R-26 | 19.2 | 19.2 | Square |
| Example 27b | R-27 | 19.3 | 19.6 | Square |
| Example 28b | R-28 | 18.5 | 18.5 | Square |
| Example 29b | R-29 | 18.8 | 18.6 | Square |
| Example 30b | R-30 | 18.7 | 18.5 | Square |
| Example 31b | R-31 | 18.9 | 18.9 | Square |
| Example 32b | R-32 | 18.6 | 18.5 | Square |
| Example 33b | R-33 | 18.9 | 19.1 | Square |
| Example 34b | R-34 | 19.0 | 18.9 | Square |
| Example 35b | R-35 | 18.8 | 18.8 | Square |
| Example 36b | R-36 | 18.7 | 18.6 | Square |
| Example 37b | R-37 | 19.3 | 19.0 | Square |
| Example 38b | R-38 | 17.7 | 17.8 | Square |
| Example 39b | R-39 | 18.4 | 18.6 | Square |
| Example 40b | R-40 | 17.6 | 17.7 | Square |
| Example 41b | R-41 | 18.7 | 18.5 | Square |
| Example 42b | R-42 | 18.5 | 18.5 | Square |
| Example 43b | R-43 | 17.7 | 17.9 | Square |
| Example 44b | R-44 | 18.1 | 18.2 | Square |
| Example 45b | R-45 | 17.6 | 17.9 | Square |
| Example 46b | R-46 | 17.6 | 17.5 | Square |
| Example 47b | R-47 | 17.5 | 17.6 | Square |
| Example 48b | R-48 | 18.6 | 18.7 | Square |
| Example 49b | R-49 | 17.8 | 17.8 | Square |
| Example 50b | R-50 | 17.9 | 17.8 | Square |
| Example 51b | R-51 | 17.9 | 18.2 | Square |
| Example 52b | R-52 | 18.2 | 18.1 | Square |
| Example 53b | R-53 | 18.1 | 18.3 | Square |
| Example 54b | R-54 | 18.2 | 18.1 | Square |
| Comparative | RX-1 | 23.5 | 23.0 | Slightly |
| Example 1b | | | | reverse taper |
| Comparative | RX-2 | 32.0 | 31.9 | Reverse taper |
| Example 2b | | | | |
| Comparative | RX-3 | 29.1 | 28.4 | Slightly |
| Example 3b | | | | reverse taper |
| Comparative | RX-4 | 24.6 | 27.9 | Square |
| Example 4b | | | | |
| Comparative | RX-5 | Failed to form the pattern | | |
| Example 5b | | | | |
| Comparative | RX-6 | 25.6 | 27.8 | Reverse taper |
| Example 6b | | | | |

The results described in Table 4 have demonstrated the following: the composition of the present invention has high resolution and can provide an excellent pattern profile in the formation of an ultrafine pattern (having, in particular, a line width or a space width of 20 nm or less).

The present invention can provide an actinic ray-sensitive or radiation-sensitive resin composition that has high resolution and can provide an excellent pattern profile in the formation of an ultrafine pattern (having, in particular, a line width or a space width of 20 nm or less), and an actinic ray-sensitive or radiation-sensitive film, a pattern forming method, and a method for producing an electronic device that use the composition.

The present invention has been described in detail and with reference to specific embodiments thereof, however, it would be apparent to those skilled in the art that various changes and modifications can be made therein without departing from the spirit and scope of the present invention.

What is claimed is:

1. An actinic ray-sensitive or radiation-sensitive resin composition comprising a resin (P) having repeating units (A) and (B), and a solvent including a solvent having a boiling point of 150° C. or more,
wherein, the solvent having a boiling point of 150° C. or more is contained in 45 mass % or more with respect to a total amount of the solvent,
(A) a repeating unit having a group that is decomposed by an action of an acid to generate a carboxylic acid and represented by the following general formula (a),
(B) a repeating unit having a group that is decomposed upon irradiation with an actinic ray or a radiation to generate an acid and represented by the following general formula (b), 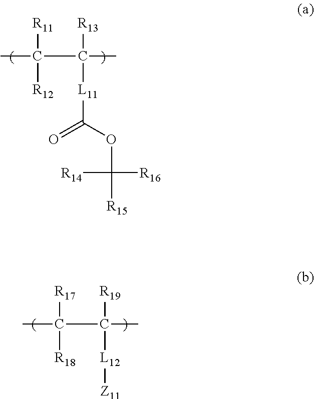
in the general formula (a),
R₁₁ to R₁₃ each independently represent a hydrogen atom, an organic group, or a halogen atom,
L₁₁ represents a divalent aromatic ring group,
R₁₄ to R₁₆ each independently represent a hydrogen atom, an alkyl group, a cycloalkyl group, an aryl group, an alkenyl group, or an alkynyl group, two among R₁₄ to R₁₆ may be linked together to form a ring,
when R₁₄ is a hydrogen atom, at least one of R₁₅ or R₁₆ represents an alkenyl group,
when R₁₄ and R₁₅ are methyl groups and two among R₁₄ to R₁₆ are not linked together,
R₁₆ represents a substituent other than a methyl group and an ethyl group,
in the general formula (b),
R₁₇ to R₁₉ each independently represent a hydrogen atom, an organic group, or a halogen atom,
L₁₂ represents a single bond, an alkylene group, an alkenylene group, an alkynylene group, a divalent aliphatic hydrocarbon ring group, a divalent aromatic ring group, or a group that is a combination of a plurality of these groups, and
Z₁ represents a moiety that is turned into a sulfonic acid group, an imidic acid group, or a methide acid group upon irradiation with an actinic ray or a radiation.

2. The actinic ray-sensitive or radiation-sensitive resin composition according to claim 1, wherein the repeating unit (B) is a repeating unit represented by any one of general formulas (b-1) to (b-4) below: 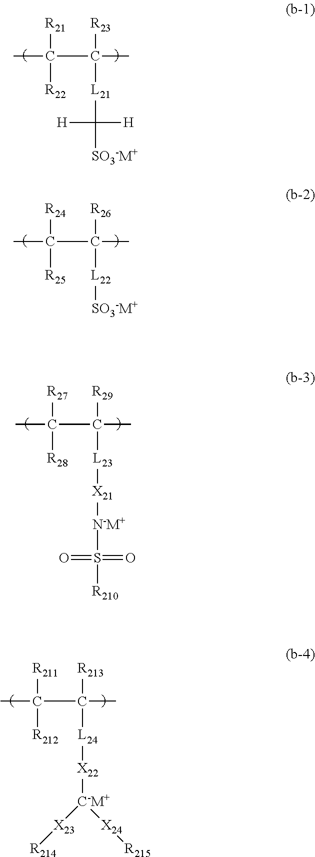
in the general formula (b-1),
R₂₁ to R₂₃ each independently represent a hydrogen atom, an alkyl group, a cycloalkyl group, a halogen atom, a cyano group, or an alkoxycarbonyl group,
L₂₁ represents a single bond, an alkylene group, an alkenylene group, an alkynylene group, a divalent aliphatic hydrocarbon ring group, a divalent aromatic ring group, or a group that is a combination of a plurality of these groups;
in the general formula (b-2),
R₂₄ to R₂₆ each independently represent a hydrogen atom, an alkyl group, a cycloalkyl group, an aryl group, an aralkyl group, or an alkenyl group,
L₂₂ represents a single bond, an alkylene group, an alkenylene group, an alkynylene group, a divalent aliphatic hydrocarbon ring group, a divalent aromatic ring group, or a group that is a combination of a plurality of these groups;
in the general formula (b-3),
R₂₇ to R₂₉ each independently represent a hydrogen atom, an alkyl group, a cycloalkyl group, an aryl group, an aralkyl group, or an alkenyl group,
L₂₃ represents a single bond, an alkylene group, an alkenylene group, an alkynylene group, a divalent aliphatic hydrocarbon ring group, a divalent aromatic ring group, or a group that is a combination of a plurality of these groups,
X₂₁ represents —CO— or —SO₂—,
R₂₁₀ represents a substituent;
in the general formula (b-4),
R₂₁₁ to R₂₁₃ each independently represent a hydrogen atom, an alkyl group, a cycloalkyl group, an aryl group, an aralkyl group, or an alkenyl group,
L₂₄ represents a single bond, an alkylene group, an alkenylene group, an alkynylene group, a divalent aliphatic hydrocarbon ring group, a divalent aromatic ring group, or a group that is a combination of a plurality of these,
X₂₂ to X₂₄ each independently represent —CO— or —SO₂—,
R₂₁₄ and R₂₁₅ each independently represent a substituent; and
M⁺ represents an organic onium ion.

3. The actinic ray-sensitive or radiation-sensitive resin composition according to claim 2, wherein L₂₁ to L₂₄ in the general formulas (b-1) to (b-4) each independently represent a single bond or a divalent aromatic ring group.

4. The actinic ray-sensitive or radiation-sensitive resin composition according to claim 2, wherein the repeating unit (B) is a repeating unit represented by the general formula (b-2).

5. The actinic ray-sensitive or radiation-sensitive resin composition according to claim 4, wherein L₂₂ in the general formula (b-2) is a phenylene group.

6. The actinic ray-sensitive or radiation-sensitive resin composition according to claim 1, wherein L₁₁ in the repeating unit (A) is a phenylene group.

7. The actinic ray-sensitive or radiation-sensitive resin composition according to claim 1, wherein a total number of carbon atoms included in R₁₄ to R₁₆ in the repeating unit (A) is 5 to 9.

8. The actinic ray-sensitive or radiation-sensitive resin composition according to claim 1, wherein R₁₄ to R₁₆ in the repeating unit (A) each independently represent an alkyl group or an alkenyl group, two among R₁₄ to R₁₆ may be linked together to form a ring, and in a case where R₁₄ and R₁₅ are methyl groups and two among R₁₄ to R₁₆ are not linked together, R₁₆ represents a substituent other than a methyl group and an ethyl group.

9. The actinic ray-sensitive or radiation-sensitive resin composition according to claim 1, wherein a content of the repeating unit (A) is 25 mol % to 55 mol % relative to all repeating units of the resin (P).

10. The actinic ray-sensitive or radiation-sensitive resin composition according to claim 1, wherein the resin (P) further includes a repeating unit (C) represented by a general formula (c) below: 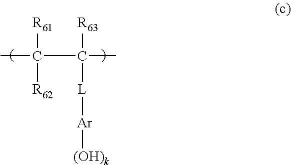
in the general formula (c),
R₆₁ to R₆₃ each independently represent a hydrogen atom, an organic group, or a halogen atom, with the proviso that R₆₂ may be bonded to Ar to form a ring, and in a case where R₆₂ is bonded to Ar to form a ring, R₆₂ represents a single bond or an alkylene group,
L represents a single bond or a divalent linking group,
Ar represents a (k+1) valent aromatic ring group, and in a case where Ar is bonded to R₆₂ to form a ring, Ar represents a (k+2) valent aromatic ring group, and
k represents an integer of 1 to 5.

11. The actinic ray-sensitive or radiation-sensitive resin composition according to claim 1, wherein, relative to the total amount of the solvent, the content of the solvent having a boiling point of 150° C. or more is 90 mass % or more.

12. The actinic ray-sensitive or radiation-sensitive resin composition according to claim 1, wherein, the solvent consists of the solvent having a boiling point of 150° C. or more.

13. The actinic ray-sensitive or radiation-sensitive resin composition according to claim 1, wherein the solvent having a boiling point of 150° C. or more contains a solvent having a hydroxyl group.

14. An actinic ray-sensitive or radiation-sensitive film formed from the actinic ray-sensitive or radiation-sensitive resin composition according to claim 1.

15. A pattern forming method comprising:
forming an actinic ray-sensitive or radiation-sensitive film from the actinic ray-sensitive or radiation-sensitive resin composition according to claim 1;
exposing the actinic ray-sensitive or radiation-sensitive film; and
developing the exposed actinic ray-sensitive or radiation-sensitive film with a developer.

16. A method for producing an electronic device, the method comprising the pattern forming method according to claim 15.
